(19) United States
(12) Patent Application Publication
(10) Pub. No.: US 2025/0056908 A1
(43) Pub. Date: Feb. 13, 2025

(54) SOLID-STATE IMAGING DEVICE

(71) Applicant: SONY SEMICONDUCTOR SOLUTIONS CORPORATION, KANAGAWA (JP)

(72) Inventors: YUYA MAEDA, KANAGAWA (JP); MICHIKO SAKAMOTO, KANAGAWA (JP); KOJI MIYATA, KANAGAWA (JP)

(21) Appl. No.: 18/719,166

(22) PCT Filed: Oct. 27, 2022
(86) PCT No.: PCT/JP2022/040059

§ 371 Date: Jun. 12, 2024

(30) Foreign Application Priority Data
Dec. 22, 2021 (JP) 2021-207979

(51) Int. Cl. H01L 27/146

(52) U.S. Cl. CPC H01L 27/14621; H01L 27/14623; H01L 27/14625

(57) ABSTRACT

A solid-state imaging device includes: a plurality of light-receiving pixels arranged in a first direction and a second direction intersecting with the first direction; a first color filter that is disposed over a plurality of the light-receiving pixels arranged in the first direction and has a first color; a second color filter that is disposed over a plurality of the light-receiving pixels arranged in the first direction, and has a second color different from the first color, a first inter-waveguide light-shielding wall that is disposed between the first color filters adjacent in the first direction, and has a light-shielding property; and a second inter-waveguide light-shielding wall that is disposed between the first color filter and the second color filter adjacent in the first direction, has a light-shielding property, and has a length in the first direction that is longer than a length in same direction of the first inter-waveguide light-shielding wall.

### TECHNICAL FIELD

The present disclosure relates to a solid-state imaging device.

### BACKGROUND ART

PTL 1 discloses a solid-state imaging element, a solid-state imaging device, and an electronic apparatus. The solid-state imaging element includes a white pixel, and a red pixel, a green pixel, and a blue pixel other than the white pixel. A light-shielding film that is thicker than the white pixel is formed at a position where the white pixel and each of the red pixel, the green pixel, and the blue pixel are adjacent to each other.

In the solid-state imaging element configured in such a manner, light having passed through a color filter of the white pixel is shielded by the light-shielding film, which makes it possible to suppress entry of light into pixels other than the white pixel. This makes it possible to reduce color mixture while suppressing a decrease in sensitivity of the white pixel.

### CITATION LIST

### Patent Literature

PTL 1: Japanese Unexamined Patent Application Publication No. 2016-54227

### SUMMARY OF THE INVENTION

A solid-state imaging device is desired to effectively suppress or prevent color mixture between adjacent light-receiving pixels provided with color filters having different colors.

A solid-state imaging device according to a first embodiment of the present disclosure includes: a plurality of light-receiving pixels arranged in a first direction and a second direction intersecting with the first direction; a first color filter that is disposed over a plurality of the light-receiving pixels arranged in the first direction, and has a first color: a second color filter that is disposed over a plurality of the light-receiving pixels arranged in the first direction, and has a second color different from the first color; a first inter-waveguide light-shielding wall that is disposed between the first color filters adjacent in the first direction, and has a light-shielding property; and a second inter-waveguide light-shielding wall that is disposed between the first color filter and the second color filter adjacent in the first direction, has a light-shielding property, and has a length in the first direction that is longer than a length in same direction of the first inter-waveguide light-shielding wall.

A solid-state imaging device according to a second embodiment of the present disclosure includes: a plurality of light-receiving pixels arranged in a first direction and a second direction intersecting with the first direction; a first color filter that is disposed over a plurality of the light-receiving pixels arranged in the first direction, and has a first color; a second color filter that is disposed over a plurality of the light-receiving pixels arranged in the first direction, and has a second color different from the first color: a fourth inter-waveguide light-shielding wall that is disposed between the first color filters adjacent in the second direction, and has a light-shielding property; a fifth inter-waveguide light-shielding wall that is disposed between the first color filter and the second color filter adjacent in the second direction, and has a light-shielding property; and at least one of a first inter-waveguide light-shielding wall that is disposed between the first color filters adjacent in the first direction and has a length in the first direction that is longer than a length in the second direction of the fourth inter-waveguide light-shielding wall or the fifth inter-waveguide light-shielding wall, or a second inter-waveguide light-shielding wall that is disposed between the first color filter and the second color filter adjacent in the first direction, has a light-shielding property, and has a length in the first direction that is longer than the length in the second direction of the fourth inter-waveguide light-shielding wall or the fifth inter-waveguide light-shielding wall.

A solid-state imaging device according to a third embodiment of the present disclosure includes: a plurality of light-receiving pixels arranged in a first direction and a second direction intersecting with the first direction: a first color filter that is disposed over a plurality of the light-receiving pixels arranged in the first direction, and has a first color; a second color filter that is disposed over a plurality of the light-receiving pixels arranged in the first direction, and has a second color different from the first color; a lens that is disposed on each of the first color filter and the second color filter, has a small aspect ratio in the second direction to the first direction, and protrudes and curves on side opposite to the light-receiving pixel; a sixth inter-waveguide light-shielding wall that is disposed each between the first color filters adjacent in the first direction and between the first color filter and the second color filter adjacent in the first direction, and has a light-shielding property; and a seventh inter-waveguide light-shielding wall that is disposed at least one of between the first color filters adjacent in the second direction or between the first color filter and the second color filter adjacent in the second direction, and has a light-shielding property higher than the light-shielding property of the sixth inter-waveguide light-shielding wall.

A solid-state imaging device according to a fourth embodiment of the present disclosure includes: a plurality of light-receiving pixels arranged in a first direction and a second direction intersecting with the first direction; a color filter that is disposed on each of the light-receiving pixels: a first inter-pixel light-shielding wall that is disposed between the light-receiving pixels corresponding to between the color filters having a same color adjacent in the first direction or the second direction, and has a light-shielding property; and a second inter-pixel light-shielding wall that is disposed between the light-receiving pixels corresponding to between the color filters having different colors adjacent in the first direction or the second direction, and has a light-shielding property higher than the light-shielding property of the first inter-pixel light-shielding wall.

### BRIEF DESCRIPTION OF THE DRAWINGS

FIG. 1 is a cross-sectional view of a main part of a solid-state imaging device according to a 1-1st embodiment of the present disclosure.

FIG. 2 is an enlarged cross-sectional view of a main part of the solid-state imaging device illustrated in FIG. 1.

FIG. 3 is a plan view of a main part for describing an arrangement configuration of light-receiving pixels, an arrangement configuration of color filters, and a layout configuration of inter-waveguide light-shielding walls in the solid-state imaging device illustrated in FIGS. 1 and 2.

FIG. 4 is an enlarged cross-sectional view of the inter-waveguide light-shielding wall disposed between the color filters of the solid-state imaging device illustrated in FIGS. 1 to 3.

FIG. 5 is an enlarged plan view of a lens of the solid-state imaging device illustrated in FIGS. 1 to 3.

FIG. 6 is an enlarged cross-sectional view of a main part of the solid-state imaging device taken along a line A-A illustrated in FIG. 3.

FIG. 7A is a plan view of a main part corresponding to FIG. 3 for describing workings and effects of the solid-state imaging device according to the 1-1st embodiment.

FIG. 7B is a plan view of a main part of the light-receiving pixels that are pixel output measurement targets of the light-receiving pixels illustrated in FIG. 7A.

FIG. 7C is a graph for describing pixel outputs of the light-receiving pixels illustrated in FIG. 7B.

FIG. 8A is a plan view of a main part corresponding to FIG. 7A of a solid-state imaging device according to a comparative example.

FIG. 8B is a plan view of a main part of light-receiving pixels that are pixel output measurement targets of light-receiving pixels illustrated in FIG. 8A.

FIG. 8C is a graph for describing pixel outputs of the light-receiving pixels illustrated in FIG. 8B.

FIG. 9 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 1-2nd embodiment of the present disclosure.

FIG. 10 is an enlarged plan view of a main part for describing a positional relationship of the light-receiving pixels, the color filters, and the inter-waveguide light-shielding walls in the solid-state imaging device illustrated in FIG. 9.

FIG. 11 is an enlarged cross-sectional view of a main part corresponding to FIG. 6 taken along a line B-B illustrated in FIG. 10.

FIG. 12 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 1-3rd embodiment of the present disclosure.

FIG. 13 is an enlarged cross-sectional view of a main part corresponding to FIG. 6 taken along a line B1-B1 illustrated in FIG. 12.

FIG. 14 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 1-4th embodiment of the present disclosure.

FIG. 15 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 1-5th embodiment of the present disclosure.

FIG. 16 is a schematic plan view of a configuration of an effective pixel region of a solid-state imaging device according to a 1-6th embodiment of the present disclosure.

FIG. 17 is a plan view of a main part corresponding to FIG. 3 for describing an arrangement configuration of light-receiving pixels, an arrangement configuration of color filters, and a layout configuration of inter-waveguide light-shielding walls in an image height center region of the effective pixel region illustrated in FIG. 16.

FIG. 18 is a plan view of a main part corresponding to FIG. 3 for describing an arrangement configuration of light-receiving pixels, an arrangement configuration of color filters, and a layout configuration of inter-waveguide light-shielding walls in an image height end region of the effective pixel region illustrated in FIG. 16.

FIG. 19 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 1-7th embodiment of the present disclosure.

FIG. 20 is an enlarged plan view of a main part corresponding to FIG. 10 for describing a positional relationship of the light-receiving pixels, the color filters, and the inter-waveguide light-shielding walls in the solid-state imaging device illustrated in FIG. 19.

FIG. 21 is an enlarged cross-sectional view corresponding to FIG. 4 of an inter-waveguide light-shielding wall disposed between color filters of a solid-state imaging device according to a 1-8th embodiment of the present disclosure.

FIG. 22 is an enlarged cross-sectional view corresponding to FIG. 4 of an inter-waveguide light-shielding wall disposed between color filters of a solid-state imaging device according to a 1-9th embodiment of the present disclosure.

FIG. 23 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 1-10th embodiment of the present disclosure.

FIG. 24 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 1-11th embodiment of the present disclosure.

FIG. 25 is a plan view of a main part corresponding to FIG. 3 for describing an arrangement configuration of light-receiving pixels, an arrangement configuration of color filters, and a layout configuration of inter-waveguide light-shielding walls in a solid-state imaging device according to a 2-1st embodiment of the present disclosure.

FIG. 26 is an enlarged cross-sectional view of a main part of the solid-state imaging device taken along a line C-C illustrated in FIG. 25.

FIG. 27 is an enlarged cross-sectional view of a main part of the solid-state imaging device taken along a line D-D illustrated in FIG. 25.

FIG. 28 is an enlarged cross-sectional view of a main part corresponding to FIG. 27 of a solid-state imaging device according to a 2-2nd embodiment of the present disclosure.

FIG. 29 is an enlarged cross-sectional view of a main part corresponding to FIG. 27 of a solid-state imaging device according to a 2-3rd embodiment of the present disclosure.

FIG. 30 is an enlarged cross-sectional view of a main part corresponding to FIG. 27 of a solid-state imaging device according to a 2-4th embodiment of the present disclosure.

FIG. 31 is a plan view of a main part corresponding to FIG. 25 for describing an arrangement configuration of light-receiving pixels, an arrangement configuration of color filters, and a layout configuration of inter-waveguide light-shielding walls in a solid-state imaging device according to a 2-5th embodiment of the present disclosure.

FIG. 32 is an enlarged cross-sectional view of a main part of the solid-state imaging device taken along a line E-E illustrated in FIG. 31.

FIG. 33 is an enlarged cross-sectional view of a main part of the solid-state imaging device taken along a line F-F illustrated in FIG. 31.

FIG. 34 is a plan view of a main part corresponding to FIG. 25 for describing an arrangement configuration of light-receiving pixels, an arrangement configuration of color filters, and a layout configuration of inter-waveguide light-shielding walls in a solid-state imaging device according to a 2-6th embodiment of the present disclosure.

FIG. 35 is a plan view of a main part corresponding to FIG. 25 for describing an arrangement configuration of light-receiving pixels, an arrangement configuration of color filters, and a layout configuration of inter-waveguide light-shielding walls in a solid-state imaging device according to a 2-7th embodiment of the present disclosure.

FIG. 36 is an enlarged cross-sectional view of a main part of the solid-state imaging device taken along a line G-G illustrated in FIG. 35.

FIG. 37 is an enlarged cross-sectional view of a main part of the solid-state imaging device taken along a line H-H illustrated in FIG. 35.

FIG. 38 is a graph illustrating a relationship between a wavelength of incident light and refractive indices of color filters in a solid-state imaging device according to a 2-7th embodiment.

FIG. 39 is a schematic plan view of a configuration of an effective pixel region of a solid-state imaging device according to 2-8th embodiment of the present disclosure.

FIG. 40 is an enlarged cross-sectional view of a main part corresponding to FIG. 26 of the solid-state imaging device taken along a line I-I in an image height center region of the effective pixel region illustrated in FIG. 39.

FIG. 41 is an enlarged cross-sectional view of a main part corresponding to FIG. 26 of the solid-state imaging device taken along a line J-J in the image height center region of the effective pixel region illustrated in FIG. 39.

FIG. 42 is an enlarged cross-sectional view of a main part corresponding to FIG. 41 of the solid-state imaging device taken along a line K-K in a high image height region of the effective pixel region illustrated in FIG. 39.

FIG. 43 is a plan view of a main part corresponding to FIG. 25 for describing an arrangement configuration of light-receiving pixels, an arrangement configuration of color filters, and a layout configuration of inter-waveguide light-shielding walls in an image height center region of an effective pixel region of a solid-state imaging device according to a 2-9th embodiment of the present disclosure.

FIG. 44 is an enlarged cross-sectional view of a main part corresponding to FIG. 40 of the solid-state imaging device taken along a line L-L in the image height center region of the effective pixel region illustrated in FIG. 43.

FIG. 45 is an enlarged cross-sectional view of a main part corresponding to FIG. 41 of the solid-state imaging device taken along a line M-M in the image height center region of the effective pixel region illustrated in FIG. 43.

FIG. 46 is a plan view of a main part corresponding to FIG. 25 for describing an arrangement configuration of light-receiving pixels, an arrangement configuration of color filters, and a layout configuration of inter-waveguide light-shielding walls in a high image height region of the effective pixel region of the solid-state imaging device according to the 2-9th embodiment of the present disclosure.

FIG. 47 is an enlarged cross-sectional view of a main part corresponding to FIG. 40 of the solid-state imaging device taken along a line N-N in the high image height region of the effective pixel region illustrated in FIG. 46.

FIG. 48 is an enlarged cross-sectional view of a main part corresponding to FIG. 42 of the solid-state imaging device taken along a line O-O in the high image height region of the effective pixel region illustrated in FIG. 46.

FIG. 49 is a plan view of a main part corresponding to FIG. 25 for describing an arrangement configuration of light-receiving pixels, an arrangement configuration of color filters, and a layout configuration of inter-waveguide light-shielding walls in a solid-state imaging device according to a 2-10th embodiment of the present disclosure.

FIG. 50 is an enlarged cross-sectional view of a main part corresponding to FIG. 26 of the solid-state imaging device taken along a line P-P illustrated in FIG. 49.

FIG. 51 is an enlarged cross-sectional view of a main part corresponding to FIG. 27 of the solid-state imaging device taken along a line Q-Q illustrated in FIG. 49.

FIG. 52 is a plan view of a main part corresponding to FIG. 3 for describing an arrangement configuration of light-receiving pixels, an arrangement configuration of color filters, and a layout configuration of inter-pixel light-shielding walls in a solid-state imaging device according to a 3-1st embodiment of the present disclosure.

FIG. 53 is an enlarged cross-sectional view of a main part corresponding to FIG. 26 of the solid-state imaging device taken along a line Aa-Aa illustrated in FIG. 52.

FIG. 54 is an enlarged cross-sectional view of a main part corresponding to FIG. 27 of the solid-state imaging device taken along a line Bb-Bb illustrated in FIG. 52.

FIG. 55 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-2nd embodiment of the present disclosure.

FIG. 56 is an enlarged cross-sectional view of a main part corresponding to FIG. 53 of the solid-state imaging device taken along a line Cc-Cc illustrated in FIG. 55.

FIG. 57 is an enlarged cross-sectional view of a main part corresponding to FIG. 54 of the solid-state imaging device taken along a line Dd-Dd illustrated in FIG. 55.

FIG. 58 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-3rd embodiment of the present disclosure.

FIG. 59 is an enlarged cross-sectional view of a main part corresponding to FIG. 53 of the solid-state imaging device taken along a line Ee-Ee illustrated in FIG. 58.

FIG. 60 is an enlarged cross-sectional view of a main part corresponding to FIG. 54 of the solid-state imaging device taken along a line Ff-Ff illustrated in FIG. 58.

FIG. 61 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-4th embodiment of the present disclosure.

FIG. 62 is an enlarged cross-sectional view of a main part corresponding to FIG. 53 of the solid-state imaging device taken along a line Gg-Gg illustrated in FIG. 62.

FIG. 63 is an enlarged cross-sectional view of a main part corresponding to FIG. 54 of the solid-state imaging device taken along a line Hh-Hh illustrated in FIG. 62.

FIG. 64 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-5th embodiment of the present disclosure.

FIG. 65 is an enlarged cross-sectional view of a main part corresponding to FIG. 53 of the solid-state imaging device taken along a line Ii-Ii illustrated in FIG. 64.

FIG. 66 is an enlarged cross-sectional view of a main part corresponding to FIG. 54 of the solid-state imaging device taken along a line Jj-Jj illustrated in FIG. 64.

FIG. 67 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-6th embodiment of the present disclosure.

FIG. 68 is an enlarged cross-sectional view of a main part corresponding to FIG. 53 of the solid-state imaging device taken along a line Kk-Kk illustrated in FIG. 67.

FIG. 69 is an enlarged cross-sectional view of a main part corresponding to FIG. 54 of the solid-state imaging device taken along a line Ll-Ll illustrated in FIG. 67.

FIG. 70 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-7th embodiment of the present disclosure.

FIG. 71 is an enlarged cross-sectional view of a main part corresponding to FIG. 53 of the solid-state imaging device taken along a line Mm-Mm illustrated in FIG.

FIG. 72 is an enlarged cross-sectional view of a main part corresponding to FIG. 54 of the solid-state imaging device taken along a line Nn-Nn illustrated in FIG. 70.

FIG. 73 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-8th embodiment of the present disclosure.

FIG. 74 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-9th embodiment of the present disclosure.

FIG. 75 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-10th embodiment of the present disclosure.

FIG. 76 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-11th embodiment of the present disclosure.

FIG. 77 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-12th embodiment of the present disclosure.

FIG. 78 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-13th embodiment of the present disclosure.

FIG. 79 is a plan view of a main part corresponding to FIG. 52 for describing an arrangement configuration of light-receiving pixels, an arrangement configuration of color filters, and a layout configuration of inter-pixel light-shielding walls in a solid-state imaging device according to a 3-14th embodiment of the present disclosure.

FIG. 80 is a block diagram depicting an example of schematic configuration of a vehicle control system that is a first application example according to an embodiment of the present disclosure.

FIG. 81 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. It is to be noted that description is given in the following order.

### 1. 1-1st Embodiment

A 1-1st embodiment describes an example in which the present technology is applied to a solid-state imaging device. Herein, description is given of a cross-sectional configuration of a main part of the solid-state imaging device and a planar configuration including an arrangement configuration of light-receiving pixels. In particular, detailed description is given of a configuration of an inter-waveguide light-shielding wall between color filters disposed on the light-receiving pixels.

### 2. 1-2nd Embodiment

A 1-2nd embodiment describes a first example in which the configuration of the inter-waveguide light-shielding wall in the solid-state imaging device according to the 1-1st embodiment is changed.

### 3. 1-3rd Embodiment

A 1-3rd embodiment describes a second example in which the configuration of the inter-waveguide light-shielding wall in the solid-state imaging device according to the 1-1st embodiment is changed.

### 4. 1-4th Embodiment

A 1-4th embodiment describes a third example in which the configuration of the inter-waveguide light-shielding wall in the solid-state imaging device according to the 1-1st embodiment is changed.

### 5. 1-5th Embodiment

A 1-5th embodiment describes a fourth example in which the configuration of the inter-waveguide light-shielding wall in the solid-state imaging device according to the 1-1st embodiment is changed.

### 6. 1-6th Embodiment

A 1-6th embodiment describes a fifth example in which the configuration of the inter-waveguide light-shielding wall in each of an image height center region and an image height end region of an effective pixel region in the solid-state imaging device according to the 1-1st embodiment is changed.

### 7. 1-7th Embodiment

A 1-7th embodiment describes a sixth example in which the configuration of the inter-waveguide light-shielding wall in the solid-state imaging device according to the 1-1st embodiment is changed.

### 8. 1-8th Embodiment

A 1-8th embodiment describes a seventh example in which the configuration of the inter-waveguide light-shielding wall in the solid-state imaging device according to the 1-1st embodiment is changed.

### 9. 1-9th Embodiment

A 1-9th embodiment describes an eighth example in which the configuration of the inter-waveguide light-shielding wall in the solid-state imaging device according to the 1-1st embodiment is changed.

### 10. 1-10th Embodiment

A 1-10th embodiment describes a first example in which an arrangement configuration of color filters in the solid-state imaging device according to the 1-1st embodiment is changed.

### 11. 1-11th Embodiment

A 1-11th embodiment describes a second example in which the arrangement configuration of the color filters in the solid-state imaging device according to the 1-1st embodiment is changed.

### 12. 2-1st Embodiment

A 2-1st embodiment describes an example in which the present technology is applied to a solid-state imaging device. Herein, description is given of a cross-sectional configuration of a main part of the solid-state imaging device and a planar configuration including an arrangement configuration of light-receiving pixels. In particular, detailed description is given of a configuration of an inter-waveguide light-shielding wall between color filters disposed on the light-receiving pixels.

### 13. 2-2nd Embodiment

A 2-2nd embodiment describes a first example in which the configuration of the inter-waveguide light-shielding wall in the solid-state imaging device according to the 2-1st embodiment is changed.

### 14. 2-3rd Embodiment

A 2-3rd embodiment describes a second example in which the configuration of the inter-waveguide light-shielding wall in the solid-state imaging device according to the 2-1st embodiment is changed.

### 15. 2-4th Embodiment

A 2-4th embodiment describes a third example in which the configuration of the inter-waveguide light-shielding wall in the solid-state imaging device according to the 2-1st embodiment is changed.

### 16. 2-5th Embodiment

A 2-5th embodiment describes a fourth example in which the configuration of the inter-waveguide light-shielding wall in the solid-state imaging device according to the 2-1st embodiment is changed.

### 17. 2-6th Embodiment

A 2-6th embodiment describes a fifth example in which the configuration of the inter-waveguide light-shielding wall in the solid-state imaging device according to the 2-1st embodiment is changed.

### 18. 2-7th Embodiment

A 2-7th embodiment describes a sixth example in which the configuration of the inter-waveguide light-shielding wall in the solid-state imaging device according to the 2-1st embodiment is changed.

### 19. 2-8th Embodiment

A 2-8th embodiment describes a seventh example in which the configuration of the inter-waveguide light-shielding wall in each of an image height center region and a high image height region of an effective pixel region in the solid-state imaging device according to the 2-1st embodiment is changed.

### 20. 2-9th Embodiment

A 2-9th embodiment describes an eighth example in which the configuration of the inter-waveguide light-shielding wall in each of the image height center region and the high image height region of the effective pixel region in the solid-state imaging device according to the 2-1st embodiment is changed.

### 21. 2-10th Embodiment

A 2-10th embodiment describes a ninth example in which the configuration of the inter-waveguide light-shielding wall in the solid-state imaging device according to the 2-1st embodiment is changed.

### 22. 3-1st Embodiment

A 3-1st embodiment describes an example in which the present technology is applied to a solid-state imaging device. Herein, description is given of a cross-sectional configuration of a main part of the solid-state imaging device and a planar configuration including an arrangement configuration of light-receiving pixels. In particular, detailed description is given of a configuration of an inter-pixel light-shielding wall disposed between the light-receiving pixels.

### 23. 3-2nd Embodiment

A 3-2nd embodiment describes a first example in which the configuration of the inter-pixel light-shielding wall in the solid-state imaging device according to the 3-1st embodiment is changed.

### 24. 3-3rd Embodiment

A 3-3rd embodiment describes a second example in which the configuration of the inter-pixel light-shielding wall in the solid-state imaging device according to the 3-1st embodiment is changed.

### 25. 3-4th Embodiment

A 3-4th embodiment describes a third example in which the configuration of the inter-pixel light-shielding wall in the solid-state imaging device according to the 3-1st embodiment is changed.

### 26. 3-5th Embodiment

A 3-5th embodiment describes a fourth example in which the configuration of the inter-pixel light-shielding wall in the solid-state imaging device according to the 3-1st embodiment is changed.

### 27. 3-6th Embodiment

A 3-6th embodiment describes a fifth example in which the configuration of the inter-pixel light-shielding wall in the solid-state imaging device according to the 3-1st embodiment is changed.

### 28. 3-7th Embodiment

A 3-7th embodiment describes a sixth example in which the configuration of the inter-pixel light-shielding wall in the solid-state imaging device according to the 3-1st embodiment is changed.

### 29. 3-8th Embodiment

A 3-8th embodiment describes a first example in which the arrangement configuration of the light-receiving pixels and the configuration of the inter-pixel light-shielding wall in the solid-state imaging device according to the 3-1st embodiment are changed.

### 30. 3-9th Embodiment

A 3-9th embodiment describes a second example in which the configuration of the inter-pixel light-shielding wall in the solid-state imaging device according to the 3-8th embodiment is changed.

### 31. 3-10th Embodiment

A 3-10th embodiment describes a second example in which the configuration of the inter-pixel light-shielding wall in the solid-state imaging device according to the 3-8th embodiment is changed.

### 32. 3-11th Embodiment

A 3-11th embodiment describes a third example in which the configuration of the inter-pixel light-shielding wall in the solid-state imaging device according to the 3-8th embodiment is changed.

### 33. 3-12th Embodiment

A 3-12th embodiment describes a fourth example in which the configuration of the inter-pixel light-shielding wall in the solid-state imaging device according to the 3-8th embodiment is changed.

### 34. 3-13th Embodiment

A 3-13th embodiment describes a first example in which the arrangement configuration of the light-receiving pixels and the configuration of the inter-pixel light-shielding wall in the solid-state imaging device according to the 3-1st embodiment are changed.

### 35. 3-14th Embodiment

A 3-14th embodiment describes a second example in which the arrangement configuration of the light-receiving pixels and the configuration of the inter-pixel light-shielding wall in the solid-state imaging device according to the 3-1st embodiment are changed.

### 36. Application Example to Mobile Body

Description is given of an example in which the present technology is applied to a vehicle control system that is an example of a mobile body control system.

### 37. Other Embodiments

### 1. 1-1st Embodiment

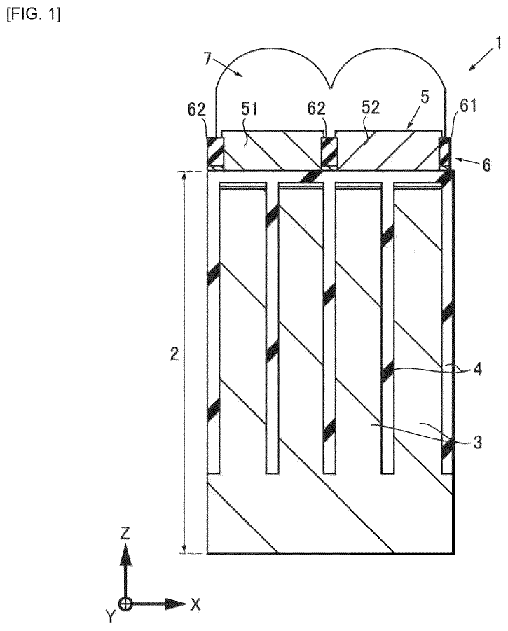

Description is given of the solid-state imaging device 1 according to the 1-1st embodiment of the present disclosure with reference to FIGS. 1 to 6, FIGS. 7A to 7C, and FIGS. 8A to 8C.

Here, an arrow-X direction illustrated as appropriate in the drawings indicates one planar direction of the solid-state imaging device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that each of these directions is indicated for easy understanding of description and does not limit directions of the present technology.

### [Configuration of Solid-state Imaging Device 1]

### (1) Schematic Overall Configuration of Solid-state Imaging Device 1

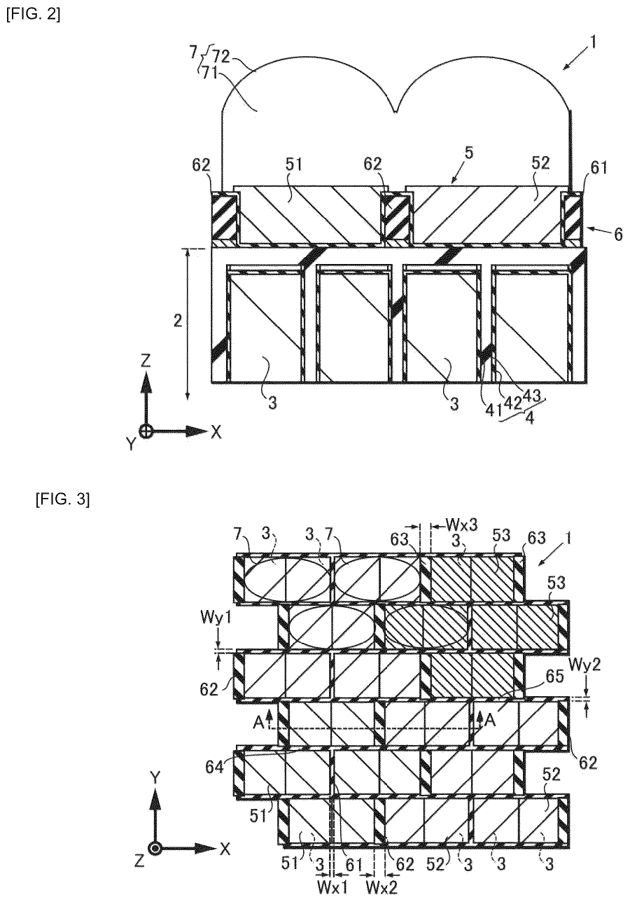

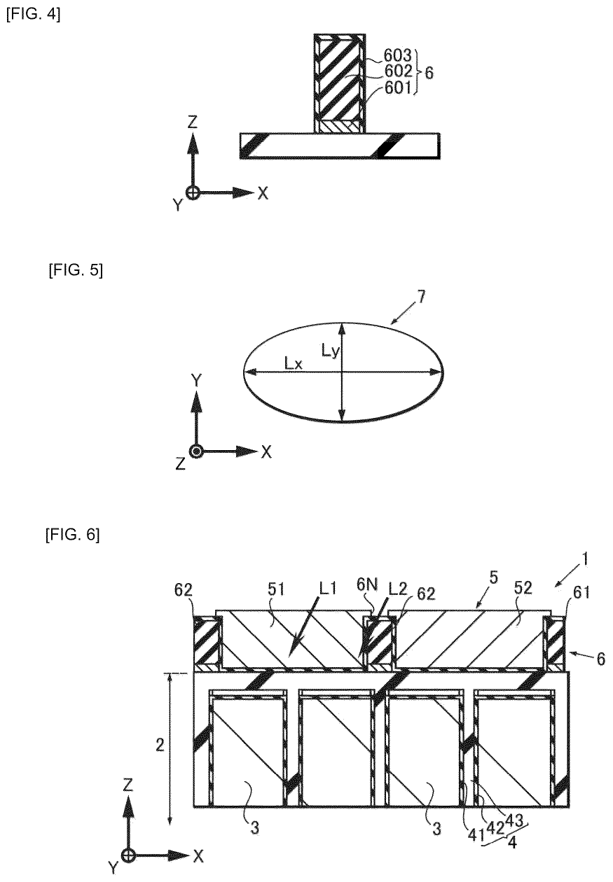

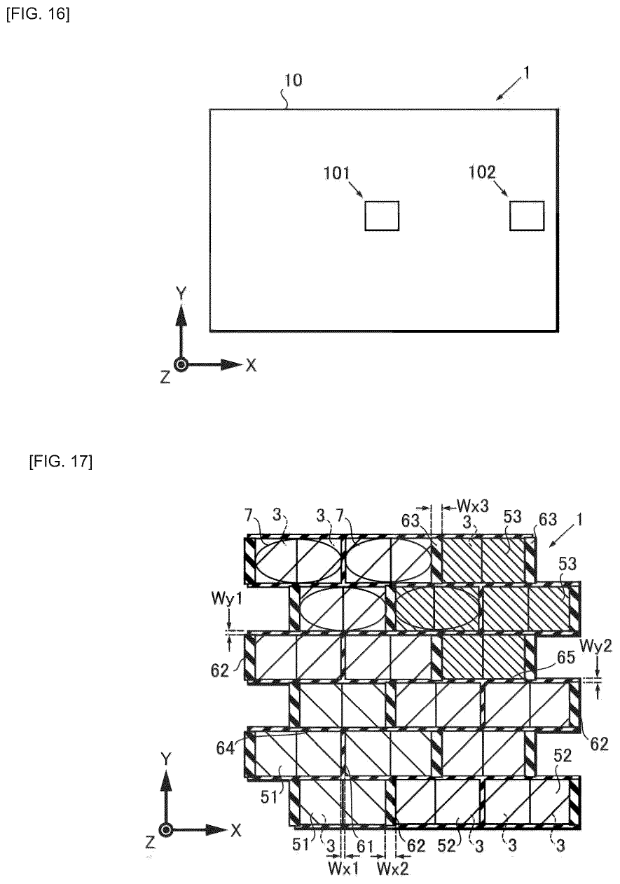

FIG. 1 illustrates an example of a cross-sectional configuration of a main part of an effective pixel region 10 (see FIG. 16, the same applies hereinafter) in the solid-state imaging device 1. FIG. 2 illustrates an example of an enlarged cross-sectional configuration of a further main part in FIG. 1. FIG. 3 illustrates an example of an arrangement configuration of light-receiving pixels 3 and an arrangement configuration of color filters 5 in the effective pixel region 10. FIG. 4 illustrates an example of a cross-sectional configuration of an inter-waveguide light-shielding wall 6 disposed between the color filters 5. FIG. 5 illustrates an example of a planar configuration of a lens 7 disposed on the color filter 5. Furthermore, FIG. 6 illustrates an example of a cross-sectional configuration of an main part in FIG. 2.

As illustrated in FIGS. 1 to 3, the solid-state imaging device 1 includes the light-receiving pixels 3, a first color filter 51, a second color filter 52, a first inter-waveguide light-shielding wall 61, and a second inter-waveguide light-shielding wall 62 as main components. The solid-state imaging device 1 further includes a third color filter 53.

### (2) Configuration of Light-Receiving Pixel 3

As illustrated in FIGS. 1 and 2, the light-receiving pixels 3 are disposed in a base 2. Here, the base 2 includes a semiconductor layer including silicon (Si). A thickness in the arrow-Z direction of the base is, for example, greater than or equal to 2 μm and less than or equal to 6 μm, as viewed in the arrow-Y direction (hereinafter, simply referred to as “in a side view”).

The light-receiving pixel 3 includes a photodiode (Photo Diode) formed in an unillustrated pn junction section of a p-type semiconductor region and an n-type semiconductor region. The light-receiving pixel 3 is formed in a rectangular shape having one side coinciding with the arrow-X direction and another side adjacent to the one side coinciding with the arrow-Y direction, as viewed in the arrow-Z direction (hereinafter, simply referred to as “in a plan view”). Here, the light-receiving pixel 3 has a planar shape formed in a square shape. A length of one side of the light-receiving pixel 3 is, for example, greater than or equal to 0.4 μm and less than or equal to 1.3 μm.

A plurality of light-receiving pixels 3 is arranged in the arrow-X direction and the arrow-Y direction, and configures an effective pixel region (see reference numeral 30 illustrated in FIG. 16). Here, the arrow-X direction corresponds to a “first direction” in the present disclosure. In addition, the arrow-Y direction corresponds to a “second direction” in the present disclosure.

Inter-pixel light-shielding walls 4 are disposed between a plurality of light-receiving pixels 3 arranged in the arrow-X direction and between a plurality of light-receiving pixels 3 arranged in the arrow-Y direction. The inter-pixel light-shielding walls 4 each include a groove 41, an inner-wall insulator 42, and a separation material 43.

The groove 41 is formed in the base 2 in the arrow-Z direction along a side surface of the light-receiving pixel 3. Here, in the inter-pixel light-shielding wall 4 disposed between the light-receiving pixels 3 arranged in the arrow-X direction, a width (length) in the same direction of the groove 41 is, for example, greater than or equal to 50 nm and less than or equal to 120 nm. In addition, a depth of the groove 41 is, for example, greater than or equal to 2 μm and less than or equal to 6 μm. In the inter-pixel light-shielding wall 4 disposed between the light-receiving pixels 3 arranged in the arrow-Y direction, a width in the same direction of the groove 41 is equal to the width of the groove 41 of the inter-pixel light-shielding wall 4 disposed between the light-receiving pixels 3 arranged in the arrow-X direction. In addition, a depth of the groove 41 is the same.

Furthermore, here, the inner-wall insulator 42 includes, for example, aluminum oxide (AlO₂). In addition, the separation material 43 includes, for example, silicon oxide (SiO₂).

Unillustrated wiring lines, circuits, and the like are disposed below the light-receiving pixels 3 in the base 2. More specifically, as the circuits, for example, a drive circuit that drives the light-receiving pixels 3, a readout circuit that reads signals from the light-receiving pixels 3, a signal processing circuit that processes a signal, a control circuit that controls various circuits, and the like are disposed. These circuits are coupled by wiring lines.

### (3) Configuration of Color Filter 5

The color filters 5 are disposed above the base 2, that is, on the light-receiving pixels 3. In the 1-1st embodiment, the color filters 5 include the first color filter 51, the second color filter 52, and the third color filter 53.

Here, the first color filter 51 is a color filter having, for example, blue as a first color. The second color filter 52 is a color filter having, for example, green as a second color different from the first color. Furthermore, as illustrated in FIG. 3, the third color filter 53 is a color filter having, for example, red as a third color different from the first color and the second color. That is, the color filters 5 are RGB color filters.

A thickness of the color filter 5 is, for example, greater than or equal to 400 nm and less than or equal to 600 nm.

Returning to FIGS. 1 and 2, the first color filter 51 is disposed over a plurality of light-receiving pixels 3 arranged in the arrow-X direction. In the 1-1st embodiment, one first color filter 51 is disposed over two light-receiving pixels 3. That is, the first color filter 51 has a length corresponding to two light-receiving pixels 3 in the arrow-X direction, has a length corresponding to one light-receiving pixel 3 in the arrow-Y direction, and is formed in a rectangular shape being long in the arrow-X direction in a plan view.

As with the first color filter 51, one second color filter 52 is disposed over a plurality of light-receiving pixels 3 arranged in the arrow-X direction. That is, the second color filter 52 is formed in the same rectangular shape as that of the first color filter 51 in a plan view.

As with the first color filter 51, one third color filter 53 illustrated in FIG. 3 is disposed over a plurality of light-receiving pixels 3 arranged in the arrow-X direction. The third color filter 53 is formed in the same rectangular shape as that of the first color filter 51 in a plan view.

Furthermore, another first color filter 51 having the same color adjacent in the arrow-Y direction to the first color filter 51 is disposed to be displaced in the arrow-X direction by an arrangement interval of the light-receiving pixels 3. In addition, the second color filter 52 having a different color adjacent in the arrow-Y direction to the first color filter 51 is disposed to be displaced in the arrow-X direction by the arrangement interval of the light-receiving pixels 3.

Likewise, another second color filter 52 having the same color adjacent in the arrow-Y direction to the second color filter 52 is disposed to be displaced in the arrow-X direction by the arrangement interval of the light-receiving pixels 3. In addition, the third color filter 53 having a different color adjacent in the arrow-Y direction to the second color filter 52 is disposed to be displaced in the arrow-X direction by the arrangement interval of the light-receiving pixels 3. Furthermore, another third color filter 53 having the same color adjacent in the arrow-Y direction to the third color filter 53 is disposed to be displaced in the arrow-X direction by the arrangement interval of the light-receiving pixels 3.

As illustrated in FIG. 3, in the solid-state imaging device 1 according to the 1-1st embodiment, two kinds of pixel blocks, which are not specifically denoted by reference numerals, are alternately arranged in each of the arrow-X direction and the arrow-Y direction. Here, a blue pixel block and a red pixel block are one kind of the two kinds of pixel blocks. A green pixel block is the other kind of the two kinds of pixel blocks.

The one kind of pixel block includes one first color filter 51, two first color filters 51 adjacent in the arrow-X direction, and one first color filter 51 that are sequentially arranged in the arrow-Y direction. That is, the pixel block includes a total of four first color filters 51, and is formed in the shape of a cross in a plan view. In addition, in a similar manner, the one kind of pixel block includes one third color filter 53, two third color filters 53 adjacent in the arrow-X direction, and one third color filter 53 that are sequentially arranged in the arrow-Y direction. That is, the pixel block includes a total of four third color filters 53, and is formed in the shape of a cross in a plan view.

The other kind of pixel block includes two second color filters 52 adjacent in the arrow-X direction, one second color filter 52, and two second color filters 52 adjacent in the arrow-X direction that are sequentially arranged in the arrow-Y direction. That is, the pixel block includes a total of five second color filters 52, and is formed in the shape of a letter “H” in a plan view.

### (4) Configuration of Lens 7

As illustrated in FIGS. 1, 2, and 5, the lens 7 is disposed on side of the color filter 5 opposite to the light-receiving pixel 3. The lens 7 includes a lens body 71, and an antireflective film 72 formed on a surface of the lens body 71. The lens 7 is integrally formed on a plurality of light-receiving pixels 3 in an effective pixel region, and is configured as an on-chip lens disposed on the color filter 5.

The lenses 7 are disposed for each first color filter 51, each second color filter 52, and each third color filter 53. As illustrated in FIG. 5, for example, the lens 7 disposed on the first color filter 51 has a major axis Lx in the arrow-X direction and a minor axis Ly in the arrow-Y direction. A length of the major axis Lx corresponds to two light-receiving pixels 3, and a length of the minor axis Ly corresponds to one light-receiving pixel 3. That is, an aspect ratio of the lens 7 in the arrow-Y direction to the arrow-X direction is small. Here, the aspect ratio is set to 2:1.

Furthermore, as illustrated in FIGS. 1 and 2, the lens 7 is formed in a shape that protrudes and curves on side opposite to the light-receiving pixel 3 in a side view. This causes the lens 7 to condense light incident from the arrow-Z direction to the light-receiving pixel 3.

The lens 7 disposed on each of the second color filter 52 and the third color filter 53 has the same configuration as that of the lens 7 disposed on the first color filter 51.

### (5) Configuration of Inter-Waveguide Light-Shielding Wall 6

As illustrated in FIGS. 1, 2, and 4, the inter-waveguide light-shielding walls 6 are disposed between the color filters 5. The inter-waveguide light-shielding walls 6 each have lower light transmittance than the color filter 5 and the lens 7, and have a light-shielding property.

As illustrated in detail in FIG. 4, in the 1-1st embodiment, the inter-waveguide light-shielding walls 6 each include a barrier metal 601, a light-shielding wall body 602, and a protective film 603 in a side view. The barrier metal 601 includes a material that enhances adhesion between a base and the light-shielding wall body 602 and has a light-shielding property.

The barrier metal 601 includes, for example, one or more materials selected from titanium (Ti), titanium nitride (TIN), tantalum (Ta), and tantalum nitride (TaN). Here, for example, Ti is used as the barrier metal 601. In addition, the barrier metal 601 may include a composite film in which Ti is stacked on TIN, or a composite film in which TIN is stacked on Ti. A thickness of the barrier metal 601 is, for example, greater than or equal to 10 nm and less than or equal to 100 nm.

The light-shielding wall body 602 is stacked on the barrier metal 601. The light-shielding wall body 602 is formed using, for example. SiO₂ having a higher light-shielding property than that of the color filter 5. In addition, the light-shielding wall body 602 may include, for example, a material having a lower refractive index than that of SiO₂, for example, a silica porous material. A thickness of the light-shielding wall body 602 is, for example, greater than or equal to 200 nm and less than or equal to 585 nm.

The protective film 603 is stacked on the light-shielding wall body 602. The protective film 603 improves environmental tolerance of each of the barrier metal 601 and the light-shielding wall body 602, and is formed using, for example, SiO₂. A thickness of the protective film 603 is, for example, greater than or equal to 5 nm and less than or equal to 50 nm.

As illustrated in FIGS. 1, 2, and 6, the inter-waveguide light-shielding wall 6 is formed to have a height in the arrow-Z direction smaller than a thickness in the same direction of the color filter 5. Here, the height of the inter-waveguide light-shielding wall 6 is, for example, greater than or equal to 300 nm and less than or equal to 600 nm.

Furthermore, in the 1-1st embodiment, as illustrated in FIGS. 1 to 3 and 6, the inter-waveguide light-shielding walls 6 include the first inter-waveguide light-shielding wall 61, the second inter-waveguide light-shielding wall 62, and a third inter-waveguide light-shielding wall 63 in the arrow-X direction. The inter-waveguide light-shielding walls 6 further include a fourth inter-waveguide light-shielding wall 64 and a fifth inter-waveguide light-shielding wall 65 in the arrow-Y direction.

The first inter-waveguide light-shielding wall 61 is disposed between the first color filters 51 having the same color adjacent in the arrow-X direction. A length (width dimension) Wx1 in the arrow-X direction of the first inter-waveguide light-shielding wall 61 is, for example, greater than or equal to 50 nm and less than 150 nm. The first inter-waveguide light-shielding wall 61 is also disposed each between the second color filters 52 having the same color adjacent in the arrow-X direction, and between the third color filters 53 having the same color adjacent in the arrow-X direction.

Meanwhile, the second inter-waveguide light-shielding wall 62 is disposed between the first color filter 51 and the second color filter 52 having different colors adjacent in the arrow-X direction. Here, the first color filter 51 has blue, and the second color filter 52 has green. Likewise, the third inter-waveguide light-shielding wall 63 is disposed between the second color filter 52 and the third color filter 53 adjacent in the arrow-X direction. Here, the second color filter 52 has green, and the third color filter 53 has red.

A length (width dimension) Wx2 in the arrow-X direction of the second inter-waveguide light-shielding wall 62 is longer than the length in the same direction of the first inter-waveguide light-shielding wall 61, and is, for example, greater than or equal to 150 nm and less than or equal to 300 nm. The third inter-waveguide light-shielding wall 63 is formed to have a length (width dimension) Wx3 in the arrow-X direction that is equal to the length Wx2 of the second inter-waveguide light-shielding wall 62.

The fourth inter-waveguide light-shielding wall 64 is disposed each between the first color filters 51 having the same color adjacent in the arrow-Y direction, between the second color filters 52 having the same color adjacent in the arrow-Y direction, and between the third color filters 53 having the same color adjacent in the arrow-Y direction.

The fourth inter-waveguide light-shielding wall 64 is formed to have a length (width dimension) Wy1 in the arrow-Y direction that is equal to the length Wx1 of the first inter-waveguide light-shielding wall 61.

Furthermore, the fifth inter-waveguide light-shielding wall 65 is disposed each between the first color filter 51 and the second color filter 52 having different colors adjacent in the arrow-Y direction, and between the second color filter 52 and the third color filter 53 having different colors adjacent in the arrow-Y direction. The fifth inter-waveguide light-shielding wall 65 is formed to have a length (width dimension) Wy2 in the arrow-Y direction that is equal to the length Wx1 of the first inter-waveguide light-shielding wall 61.

### [Output Characteristics of Light-Receiving Pixel 3 of Solid-State Imaging Device 1]

### (1) Output Characteristics of Light-receiving Pixel 3C According to Comparative Example

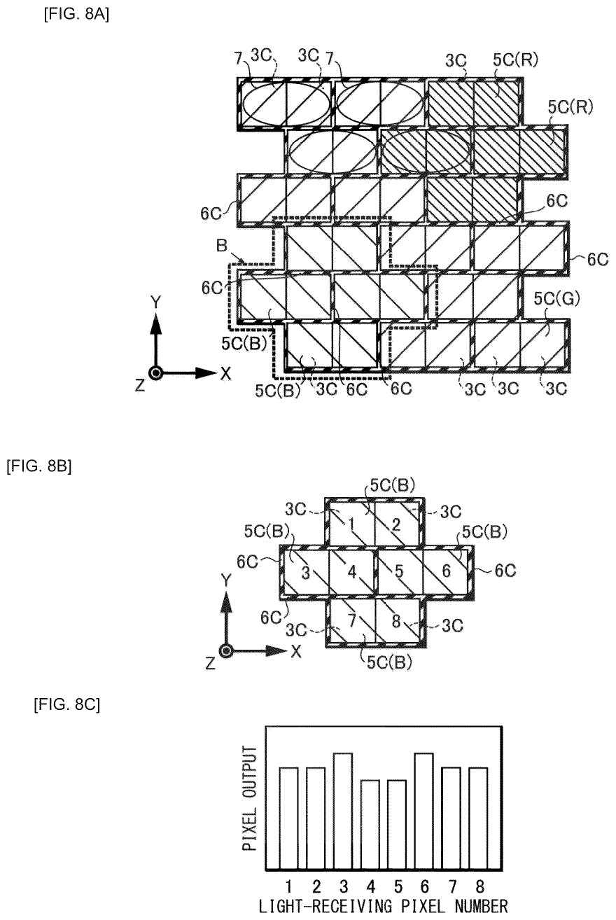

FIG. 8A illustrates an example of an arrangement configuration of light-receiving pixels 3C of a solid-state imaging device according to a comparative example. FIG. 8B illustrates an example of the arrangement configuration of the light-receiving pixels 3C, an arrangement configuration of color filters 5C, and a layout configuration of inter-waveguide light-shielding walls 6C indicated by a broken line with a reference numeral B in FIG. 8A. FIG. 8C illustrates a relationship between the light-receiving pixels 3C illustrated in FIG. 8B and outputs.

As illustrated in FIG. 8B, of a plurality of light-receiving pixels 3C illustrated in FIG. 8A, two light-receiving pixels 3C adjacent in the arrow-X direction, four light-receiving pixels 3C adjacent in the arrow-Y direction and the arrow-X direction, and two light-receiving pixels 3C adjacent in the arrow-Y direction and the arrow-X direction, that is, a total of eight light-receiving pixels 3C are selected. The color filters 5C having blue that is the same color are disposed on the selected eight light-receiving pixels 3C.

The inter-waveguide light-shielding walls 6C having the same length (width dimension) in the arrow-X direction are disposed between the color filters 5C arranged in the arrow-X direction irrespective of whether the color filters 5C have the same color or different colors. In addition, the inter-waveguide light-shielding walls 6C having the same length (width dimension) in the arrow-Y direction are disposed between the color filters 5C arranged in the arrow-Y direction irrespective of whether the color filters 5C have the same color or different colors.

In FIG. 8B, for convenience, the light-receiving pixels 3C are numbered from 1 to 8 from left side to right side and from top side to bottom side in the drawing.

FIG. 8C illustrates respective pixel outputs of the light-receiving pixels 3C numbered from 1 to 8.

The light-receiving pixels 3C numbered 4 and 5 on which the color filters 5C having the same color are adjacent in the arrow-X direction have the lowest pixel output.

In contrast, relative to the light-receiving pixels 3C numbered 1 and 2, the color filter 5C having a different color (green) is adjacent in the arrow-X direction, and the color filters 5C having the same color (blue) and a different color (green) are adjacent in the arrow-Y direction. The light-receiving pixels 3C numbered 1 and 2 each have a pixel output larger than the pixel outputs of the light-receiving pixels 3C numbered 4 and 5. The light-receiving pixels 3C numbered 7 and 8 each have a pixel output that is the same as the pixel outputs of the light-receiving pixel 3C numbered 1 and 2.

Furthermore, relative to the light-receiving pixels 3C numbered 3 and 6, the color filters 5C having a different color (green) are adjacent in the arrow-X direction, and the color filters 5C having a different color (green) are adjacent also in the arrow-Y direction. The light-receiving pixels 3C numbered 3 and 6 each have a pixel output larger than the pixel outputs of the light-receiving pixels 3C numbered 1, 2, 7, and 8.

That is, as the number of color filters 5C having different colors adjacent in the arrow-X direction and the arrow-Y direction to the color filter 5C disposed on the light-receiving pixel 3C increases, the pixel output of the light-receiving pixel 3C increases. In other words, variations in a sensitivity difference occur among the light-receiving pixels 3C numbered 1 to 8 on which the color filters 5C having the same color are disposed.

### (2) Output Characteristics of Light-Receiving Pixel 3 According to 1-1st Embodiment

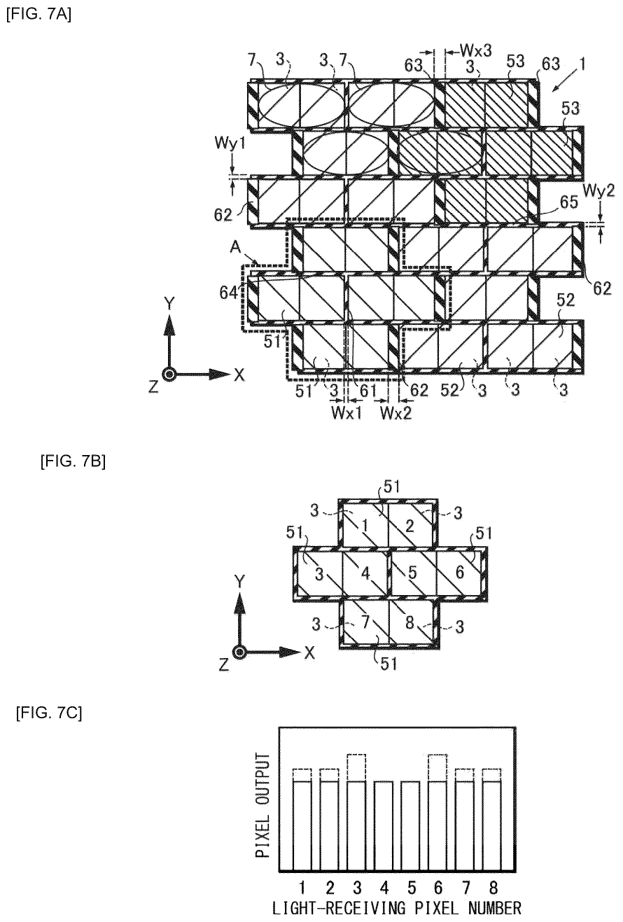

FIG. 7A illustrates an example of the arrangement configuration of the light-receiving pixels 3 in the solid-state imaging device 1 according to the 1-1st embodiment. FIG. 7B illustrates an example of the arrangement configuration of the light-receiving pixels 3, the arrangement configuration of the color filters 5, and a layout configuration of the inter-waveguide light-shielding walls 6 indicated by a broken line with a reference numeral A in FIG. 7A. FIG. 7C illustrates a relationship between the light-receiving pixels 3 illustrated in FIG. 7B and outputs.

As with the light-receiving pixels 3C according to the comparative example illustrated in FIGS. 8A and 8B, as illustrated in FIG. 7B, of a plurality of light-receiving pixels 3 illustrated in FIG. 7A, a total of eight light-receiving pixels 3 are selected. The first color filters 51 having blue that is the same color are disposed on the selected eight light-receiving pixels 3.

As described above, the first inter-waveguide light-shielding wall 61 is disposed between the first color filters 51 having the same color adjacent in the arrow-X direction. The second inter-waveguide light-shielding wall 62 is disposed between the first color filter 51 and the second color filter 52 having different colors adjacent in the arrow-X direction. The length Wx2 of the second inter-waveguide light-shielding wall 62 is longer than the length Wx1 of the first inter-waveguide light-shielding wall 61.

The fourth inter-waveguide light-shielding wall 64 is disposed between the first color filters 51 having the same color adjacent in the arrow-Y direction. The fifth inter-waveguide light-shielding wall 65 is disposed between the first color filter 51 and the second color filter 52 having different colors adjacent in the arrow-Y direction. The length Wy1 of the fourth inter-waveguide light-shielding wall 64 and the length Wy2 of the fifth inter-waveguide light-shielding wall Wy2 are equal to the length Wx1 of the first inter-waveguide light-shielding wall 61, and are shorter than the length Wx2 of the second inter-waveguide light-shielding wall 62.

As with the light-receiving pixels 3C illustrated in FIG. 8B, the light-receiving pixels 3 illustrated in FIG. 7B are numbered 1 to 8.

FIG. 7C illustrates respective pixel outputs of the light-receiving pixels 3 numbed 1 to 8.

As illustrated in FIG. 7C, the pixel outputs of the light-receiving pixels 3 numbered 1 to 3 and 6 to 8 are the same as the pixel outputs of the light-receiving pixels 3 numbered 4 and 5. That is, the pixel outputs of the light-receiving pixels 3 are the same irrespective of whether the first color filter 51 having the same color or the second color filter 52 having a different color is adjacent in the arrow-X direction to the first color filter 51 and irrespective of whether the first color filter 51 having the same color or the second color filter 52 having a different color is adjacent in the arrow-Y direction to the first color filter 51. That is, variations in a sensitivity difference do not occur among the light-receiving pixels 3 numbered from 1 to 8.

As illustrated in FIG. 6, the second inter-waveguide light-shielding wall 62 is formed between the first color filter 51 and the second color filter 52 having different colors adjacent in the arrow-X direction to have a height smaller than the thicknesses of the first color filter 51 and the second color filter 52.

Accordingly, a recess 6N where the color filter 5 is not provided is formed between the first color filter 51 and the second color filter 52. The recess 6N serves as a color mixture path. A light amount of incident light L2 passing through the recess 6N increases relative to incident light L1 passing through each of the first color filter 51 and second color filter 52. In other words, sensitivity increases with an increase in the number of recesses 6N around the light-receiving pixel 3 as a center.

That is, in the 1-1st embodiment, the second inter-waveguide light-shielding wall 62 at a position where the recess 6N is formed is formed to have a length Wx2 longer than the length Wx1 of the first inter-waveguide light-shielding wall 61 at a position where the recess 6N is not formed, which limits a light amount relative to the incident light L2. The same applies to the third inter-waveguide light-shielding wall 63.

### Workings and Effects

The solid-state imaging device 1 according to the 1-1st embodiment includes the light-receiving pixels 3, the first color filters 51, the second color filters 52, the first inter-waveguide light-shielding walls 61, and the second inter-waveguide light-shielding walls 62, as illustrated in FIGS. 1 to 3 and 6. A plurality of light-receiving pixels 3 is arranged in the arrow-X direction and the arrow-Y direction intersecting with the arrow-X direction. The first color filter 51 has a first color that is disposed over a plurality of light-receiving pixels 3 arranged in the arrow-X direction. The second color filter 52 is disposed over a plurality of light-receiving pixels 3 arranged in the arrow-X direction, and has a second color different from the first color.

Here, the first inter-waveguide light-shielding wall 61 is disposed between the first color filters adjacent in the arrow-X direction, and has a light-shielding property. Furthermore, the second inter-waveguide light-shielding wall 62 is disposed between the first color filter 51 and the second color filter 52 adjacent in the arrow-X direction, has a light-shielding property, and has the length Wx2 in the arrow-X direction that is longer than the length Wx1 in the same direction of the first inter-waveguide light-shielding wall 61.

Accordingly, it is possible to effectively reduce or prevent the incident light L2 that enters a color mixture path between the first color filter 51 and the second color filter 52 having different colors by the second inter-waveguide light-shielding wall 62. This makes it possible to effectively suppress or prevent variations among the pixel outputs of the light-receiving pixels 3, to reduce or prevent a sensitivity difference between the color filters 5 having different colors, and to effectively suppress or prevent color mixture.

In addition, in the solid-state imaging device 1, as illustrated in FIG. 3, another first color filter 51 adjacent in the arrow-Y direction to the first color filter 51, or another second color filter 52 adjacent in the arrow-Y direction to the first color filter 51 is disposed to be displaced in the arrow-X direction by the arrangement interval of the light-receiving pixels 3. In such a pixel arrangement, with respect to the first color filter 51 disposed on one light-receiving pixel 3 as a center, the number of first color filters 51 having the same color and the number of second color filters 52 having a different color adjacent in the arrow-X direction and the arrow-Y direction change.

Here, the second inter-waveguide light-shielding wall 62 is disposed between the first color filter 51 and the second color filter 52 having different colors, and makes it possible to effectively reduce or prevent the incident light L2 that enters the color mixture path. This makes it possible to reduce or prevent a sensitivity difference between the color filters 5 having different colors and to effectively suppress or prevent color mixture.

In addition, as illustrated in FIG. 3, the solid-state imaging device 1 includes the third color filter 53 and the third inter-waveguide light-shielding wall 63. The third color filter 53 is disposed over a plurality of light-receiving pixels 3 arranged in the arrow-X direction, and has the third color different from the first color and the second color. The third inter-waveguide light-shielding wall 63 is disposed between the second color filter 52 and the third color filter 53 adjacent in the arrow-X direction, has a light-shielding property, and has the length Wx3 in the arrow-X direction that is longer than the length Wx1 in the same direction of the first inter-waveguide light-shielding wall 61.

Accordingly, in the third inter-waveguide light-shielding wall 63, it is possible to achieve workings and effects similar to workings and effects achieved by the second inter-waveguide light-shielding wall 62.

In addition, as illustrated in FIG. 3, the solid-state imaging device 1 includes the fourth inter-waveguide light-shielding wall 64 and the fifth inter-waveguide light-shielding wall 65. The fourth inter-waveguide light-shielding wall 64 is disposed between the first color filters 51 adjacent in the arrow-Y direction, has a light-shielding property, and has the length Wy1 in the arrow-Y direction that is equal to the length Wx1 in the arrow-X direction of the first inter-waveguide light-shielding wall 61. The fifth inter-waveguide light-shielding wall 65 is disposed between the first color filter 51 and the second color filter 52 adjacent in the arrow-Y direction, has a light-shielding property, and has the length Wy2 in the arrow-Y direction that is equal to the length Wx1 in the arrow-X direction of the first inter-waveguide light-shielding wall 61.

Accordingly, the length Wy1 of the fourth inter-waveguide light-shielding wall 64 and the length Wy2 of the fifth inter-waveguide light-shielding wall 65 are formed to be equal to the length Wx1 of the first inter-waveguide light-shielding wall 61, which makes it possible to simplify the configurations and manufacturing process of the inter-waveguide light-shielding walls 6.

In addition, in the solid-state imaging device 1, as illustrated in FIGS. 1, 2, and 4, the first inter-waveguide light-shielding wall 61 to the fifth inter-waveguide light-shielding wall 65 each include the barrier metal 601, and the light-shielding wall body 602 stacked on the barrier metal 601. Here, W that is a high-melting-point metal is used as the light-shielding wall body 602.

Accordingly, it is possible to form the first inter-waveguide light-shielding wall 61 to the fifth inter-waveguide light-shielding wall 65 with a simple configuration, and it is possible to effectively achieve suppression or prevention of color mixture.

### 2. 1-2nd Embodiment

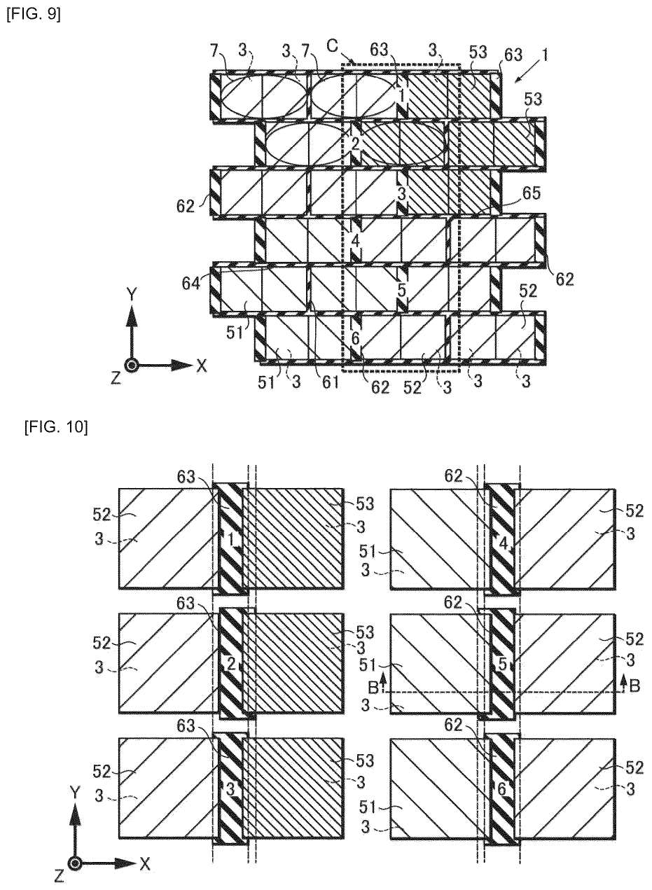

Description is given of the solid-state imaging device 1 according to the 1-2nd embodiment of the present disclosure with reference to FIGS. 9 to 11. It is noted that in the 1-2nd embodiment and subsequent embodiments, the same components or substantially the same components as those of the solid-state imaging device 1 according to the 1-1st embodiment are denoted by the same reference numerals, and redundant descriptions thereof are omitted.

### [Configuration of Solid-State Imaging Device 1]

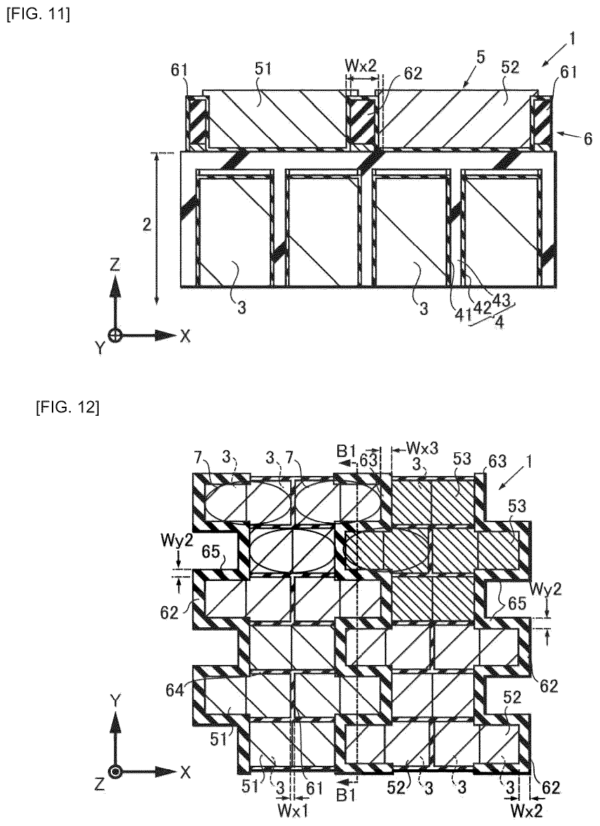

FIG. 9 illustrates an example of the arrangement configuration of the light-receiving pixels 3 in the effective pixel region 10 in the solid-state imaging device 1. FIG. 10 illustrates an example of the arrangement configuration of the light-receiving pixels 3, the arrangement configuration of the color filters 5, and the layout configuration of the inter-waveguide light-shielding walls 6 in a main part. FIG. 11 illustrates an example of a cross-sectional configuration of the main part in FIG. 10.

As illustrated in FIGS. 9 to 11, as with the solid-state imaging device 1 according to the 1-1st embodiment, the solid-state imaging device 1 according to the 1-2nd embodiment incudes the light-receiving pixels 3, the first color filter 51 to the third color filter 53, and the first inter-waveguide light-shielding walls 61 to the fifth inter-waveguide light-shielding walls 65.

Here, description is given of the light-receiving pixels 3, the color filters 5, and the inter-waveguide light-shielding walls 6 in a region encircled with a broken line with a reference number C in FIG. 9. For convenience, the third inter-waveguide light-shielding walls 63 disposed between the second color filters 52 and the third color filters 53 are numbered 1 to 3 from top side to bottom side. Furthermore, the second inter-waveguide light-shielding walls 62 disposed between the first color filters 51 and the second color filters 52 are numbered 4 to 6 from top side to bottom side.

First, the first color filter 51 having blue that is the first color is disposed on the light-receiving pixel 3 on left side in the drawing of the second inter-waveguide light-shielding wall 62 numbered 5 illustrated in FIG. 9. Relative to this light-receiving pixel 3 as a center, the second color filters 52 having green that is the second color are disposed on the light-receiving pixel 3 adjacent on right side in the drawing in the arrow-X direction and the light-receiving pixels 3 adjacent on top side and bottom side in the drawing in the arrow-Y direction. That is, three light-receiving pixels 3 on which the second color filters 52 having a different color are disposed are adjacent to one light-receiving pixel 3 on which the first color filter 51 is disposed.

Meanwhile, the second color filter 52 having green that is the second color is disposed on the light-receiving pixel 3 on right side in the drawing of the same second inter-waveguide light-shielding wall 62. Relative to this light-receiving pixel 3 as a center, one light-receiving pixel 3 on which the first color filter 51 having a different color is disposed is adjacent to the light-receiving pixel 3 adjacent on right side in the drawing in the arrow-X direction. The second color filters 52 having the same color are disposed on the light-receiving pixels 3 adjacent on top side and bottom side in the drawing in the arrow-Y direction. That is, one light-receiving pixel 3 on which the first color filter 51 having a different color is disposed is adjacent to one light-receiving pixel 3 on which the second color filter 52 is disposed.

In this case, the light-receiving pixel 3 on left side in the drawing of the second inter-waveguide light-shielding wall 62 has a pixel output higher than the pixel output of the light-receiving pixel 3 on right side in the drawing, and sensitivity is floated. Accordingly, as illustrated in FIG. 11, a center position of the second inter-waveguide light-shielding wall 62 is shifted toward the light-receiving pixel 3 on which the first color filter 51 is disposed. That is, the light amount of the incident light L2 (see FIG. 6) is limited.

In addition, the second color filter 52 having green that is the second color is disposed on the light-receiving pixel 3 on left side in the drawing of the third inter-waveguide light-shielding wall 63 numbered 2 illustrated in FIG. 9. Relative to this light-receiving pixel 3 as a center, one light-receiving pixel 3 on which the third color filter 53 having a different color red that is the second color is disposed is adjacent to the light-receiving pixel 3 adjacent on right side in the drawing in the arrow-X direction. The second color filter 52 having the same color is disposed on the light-receiving pixels 3 adjacent on top side and bottom side in the drawing in the arrow-Y direction. That is, one light-receiving pixel 3 on which the third color filter 53 having a different color is disposed is adjacent to one light-receiving pixel 3 on which the second color filter 52 is disposed.

Meanwhile, the third color filter 53 is disposed on the light-receiving pixel 3 on right side in the drawing of the same third inter-waveguide light-shielding wall 63. Relative to this light-receiving pixel 3 as a center, one light-receiving pixel 3 on which the second color filter 52 having a different color is disposed is disposed for the light-receiving pixel 3 adjacent on left side in the drawing in the arrow-X direction, and two light-receiving pixels 3 on which the second color filters 52 having a different color are disposed are disposed for the light-receiving pixels 3 adjacent on top side and bottom side in the drawing in the arrow-Y direction. That is, three light-receiving pixels 3 on which second color filters 52 having the different color are disposed are adjacent to one light-receiving pixel 3 on which third color filter 53 is disposed.

In this case, the light-receiving pixel 3 on right side in the drawing of the third inter-waveguide light-shielding wall 63 has a pixel output higher than the pixel output of the light-receiving pixel 3 on left side in the drawing, and sensitivity is floated. Accordingly, as with the second inter-waveguide light-shielding wall 62 illustrated in FIG. 11, a center position of the third inter-waveguide light-shielding wall 63 is shifted toward the light-receiving pixel 3 on which the third color filter 53 is disposed. That is, the light amount of the incident light L2 (see FIG. 6) is limited.

Center positions in the arrow-X direction of the third inter-waveguide light-shielding walls 63 numbered 1 and 3 each coincide with a center position of the light-receiving pixel 3 on which the second color filter 52 is disposed and the light-receiving pixel 3 on which the third color filter 53 is disposed. Likewise, center positions in the arrow-X direction of the second inter-waveguide light-shielding walls 62 numbered 4 and 6 each coincide with a center position of the light-receiving pixel 3 on which the first color filter 51 is disposed and the light-receiving pixel 3 on which the second color filter 52 is disposed.

Components other than the above-described components are the same or substantially the same as the components of the solid-state imaging device 1 according to the 1-1st embodiment described above.

### Workings and Effects

In the solid-state imaging device 1 according to the 1-2nd embodiment, it is possible to achieve workings and effects similar to the workings and effects achieved by the solid-state imaging device 1 according to the 1-1st embodiment.

In addition, in the solid-state imaging device 1, as illustrated in FIGS. 9 to 11, the center positions of the second inter-waveguide light-shielding wall 62 and the third inter-waveguide light-shielding wall 63 are each shifted in accordance with the number of color filters 5 having different colors disposed on the light-receiving pixels 3 adjacent in the arrow-X direction and the arrow-Y direction to the light-receiving pixel 3 as a center on which the color filter 5 is disposed.

Accordingly, it is possible to correct the light amount of the incident light L2 by each of the second inter-waveguide light-shielding wall 62 and the third inter-waveguide light-shielding wall 63 in accordance with the number of color filters 5 having different colors, which makes it possible to effectively reduce or prevent a sensitivity difference between the color filters 5 having different colors. Thus, it is possible to effectively suppress or prevent color mixture.

### 3. 1-3rd Embodiment

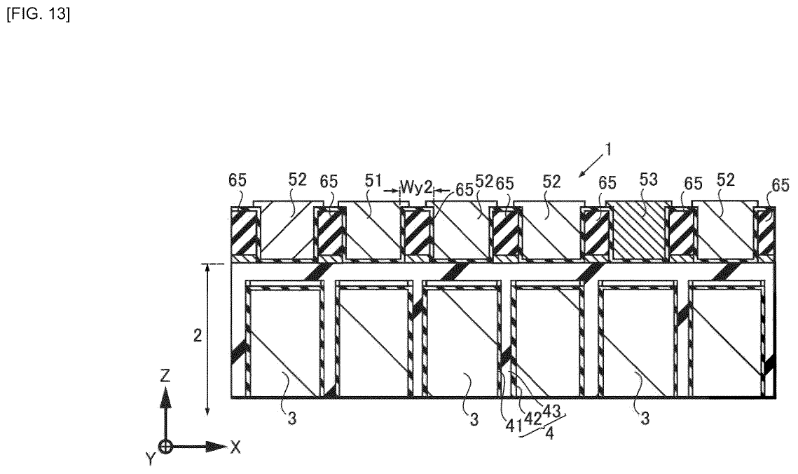

Description is given of the solid-state imaging device 1 according to the 1-3rd embodiment of the present disclosure with respect to FIGS. 12 and 13.

### [Configuration of Solid-State Imaging Device 1]

FIG. 12 illustrates an example of the arrangement configuration of the light-receiving pixels 3 in the effective pixel region 10 in the solid-state imaging device 1. FIG. 13 illustrates an example of a cross-sectional configuration of the light-receiving pixels 3, the color filters 5, and the inter-waveguide light-shielding walls 6 in a main part.

As illustrated in FIGS. 12 and 13, the solid-state imaging device 1 according to the 1-3rd embodiment includes the fourth inter-waveguide light-shielding wall 64 and the fifth inter-waveguide light-shielding wall 65.

The fourth inter-waveguide light-shielding wall 64 is disposed between the first color filters 51 having the same color adjacent in the arrow-Y direction. The fourth inter-waveguide light-shielding wall 64 is formed to have the length Wy1 in the arrow-Y direction that is equal to the length Wx1 of the first inter-waveguide light-shielding wall 61.

In addition, the fourth inter-waveguide light-shielding walls 64 are also disposed between the first color filter 51 and the second color filter 52 having different colors adjacent in the arrow-Y direction and between the second color filter 52 and the third color filter 53 having different colors adjacent in the arrow-Y direction.

Meanwhile, the fifth inter-waveguide light-shielding wall 65 is disposed between the first color filter 51 and the second color filter 52 adjacent in the arrow-Y direction. Furthermore, the fifth inter-waveguide light-shielding wall 65 is also disposed between the second color filter 52 and the third color filter 53 adjacent in the arrow-Y direction. The fifth inter-waveguide light-shielding wall 65 is formed to have the length Wy2 in the arrow-Y direction that is longer than the length Wx1 of the first inter-waveguide light-shielding wall 61. Here, the fifth inter-waveguide light-shielding wall 65 is formed to have the length Wy2 that is equal to the length Wx2 in the arrow-X direction of the second inter-waveguide light-shielding wall 62 and the length Wx3 in the arrow-X direction of the third inter-waveguide light-shielding wall 63.

In other words, the fifth inter-waveguide light-shielding wall 65 is formed to have the length Wy2 that is longer than the length Wx1 of the first inter-waveguide light-shielding wall 61 and the length Wy2 of the fourth inter-waveguide light-shielding wall 64, and is equal to the length Wx2 of the second inter-waveguide light-shielding wall 62 and the length Wx3 of the third inter-waveguide light-shielding wall 63.

In addition, the fifth inter-waveguide light-shielding wall 65 is formed integrally with each of the second inter-waveguide light-shielding wall 62 and the third inter-waveguide light-shielding wall 63 adjacent in the arrow-Y direction. As illustrated in FIG. 12, the fifth inter-waveguide light-shielding wall 65, the second inter-waveguide light-shielding wall 62, and the third inter-waveguide light-shielding wall 63 meander regularly and repeatedly in the arrow-X direction in a plan view, and are formed in a digital waveform shape extending in the arrow-Y direction.

Components other than the above-described components are the same or substantially the same as the components of the solid-state imaging device 1 according to the 1-1st embodiment described above.

### Workings and Effects

In the solid-state imaging device 1 according to the 1-3rd embodiment, it is possible to achieve workings and effects similar to the workings and effects achieved by the solid-state imaging device 1 according to the 1-1st embodiment.

In addition, in the solid-state imaging device 1, as illustrated in FIGS. 12 and 13, at a position where the number of color filters $ having different colors disposed on the light-receiving pixels 3 adjacent in the arrow-X direction and the arrow-Y direction to the light-receiving pixel 3 as a center on which the color filter 5 is disposed increases, the fifth inter-waveguide light shielding wall 65 is disposed in addition to the second inter-waveguide light shielding wall 62 or the third inter-waveguide light shielding wall 63. That is, the fifth inter-waveguide light-shielding wall 65 is disposed also in the arrow-Y direction between the color filters 5 having different colors.

Accordingly, it is possible to effectively limit the light amount of the incident light L2 by the fifth inter-waveguide light-shielding wall 65, which makes it possible to effectively reduce or prevent a sensitivity difference between the color filters 5 having different colors. Thus, it is possible to effectively suppress or prevent color mixture.

### 4. 1-4th Embodiment

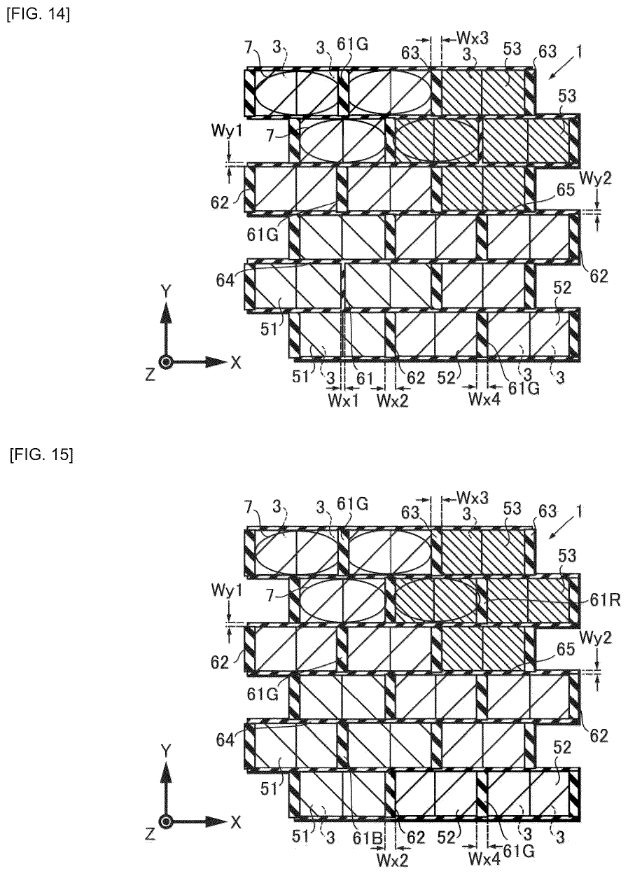

Description is given of the solid-state imaging device 1 according to the 1-4th embodiment of the present disclosure with reference to FIG. 14. The 1-4th embodiment and the next 1-5th embodiment are examples in which the configuration of the inter-waveguide light-shielding wall 6 disposed between the color filters 5 having the same color is changed.

### [Configuration of Solid-State Imaging Device 1]

FIG. 14 illustrates an example of the arrangement configuration of the light-receiving pixels 3 in the effective pixel region 10 in the solid-state imaging device 1.

As illustrated in FIG. 14, the solid-state imaging device 1 according to the 1-4th embodiment includes a first inter-waveguide light-shielding wall 61G in the solid-state imaging device 1 according to the 1-1st embodiment. The first inter-waveguide light-shielding wall 61G is disposed between the second color filters 52 having the same color green adjacent in the arrow-X direction.

As with the first inter-waveguide light-shielding wall 61, the first inter-waveguide light-shielding wall 61G has a light-shielding property. In addition, unlike the first inter-waveguide light-shielding wall 61, the first inter-waveguide light-shielding wall 61G is formed to have a length Wx4 in the arrow-X direction that is longer than the length Wy1 in the arrow-Y direction of the fourth inter-waveguide light-shielding wall 64 or the length Wy2 in the arrow-Y direction of the fifth inter-waveguide light-shielding wall 65.

Here, the length Wx4 of the first inter-waveguide light-shielding wall 61G is equal to the length Wx2 in the same direction of the second inter-waveguide light-shielding wall 62 and the length Wx3 in the same direction of the third inter-waveguide light-shielding wall 63.

Components other than the above-described components are the same or substantially the same as the components of the solid-state imaging device 1 according to the 1-1st embodiment described above.

### Workings and Effects

In the solid-state imaging device 1 according to the 1-4th embodiment, it is possible to achieve workings and effects similar to the workings and effects achieved by the solid-state imaging device 1 according to the 1-1st embodiment.

In addition, as illustrated in FIG. 14, the solid-state imaging device 1 includes the first inter-waveguide light-shielding wall 61G also between the second color filters 52 having the same color. The length Wx4 in the arrow-X direction of the first inter-waveguide light-shielding wall 61G is longer than the length Wy1 in the arrow-Y direction of the fourth inter-waveguide light-shielding wall 64 or the length Wy2 in the arrow-Y direction of the fifth inter-waveguide light-shielding wall 65.

Accordingly, it is possible to effectively limit the light amount of the incident light L2 by the first inter-waveguide light-shielding wall 61G, which makes it possible to more effectively reduce or prevent a sensitivity difference between the second color filters 52 having the same color.

### 5. 1-5th Embodiment

Description is given of the solid-state imaging device 1 according to the 1-5th embodiment of the present disclosure with reference to FIG. 15.

### [Configuration of Solid-State Imaging Device 1]

FIG. 15 illustrates an example of the arrangement configuration of the light-receiving pixels 3 in the effective pixel region 10 in the solid-state imaging device 1.

As illustrated in FIG. 15, the solid-state imaging device 1 according to the 1-5th embodiment further includes a first inter-waveguide light-shielding wall 61B and a first inter-waveguide light-shielding wall 61R in addition to the first inter-waveguide light-shielding wall 61G in the solid-state imaging device 1 according to the 1-4th embodiment.

The first inter-waveguide light-shielding wall 61B is disposed between the first color filters 51 having the same color blue adjacent in the arrow-X direction. The first inter-waveguide light-shielding wall 61R is disposed between the third color filters 53 having the same color red adjacent in the arrow-X direction.

As with the first inter-waveguide light-shielding wall 61, the first inter-waveguide light-shielding wall 61B and the first inter-waveguide light-shielding wall 61R each have a light-shielding property. In addition, unlike the first inter-waveguide light-shielding wall 61, the first inter-waveguide light-shielding wall 61B and the first inter-waveguide light-shielding wall 61R are each formed to have the length Wx4 in the arrow-X direction that is longer than the length Wy1 in the arrow-Y direction of the fourth inter-waveguide light-shielding wall 64 or the length Wy2 in the arrow-Y direction of the fifth inter-waveguide light-shielding wall 65.

Here, the length Wx4 of each of the first inter-waveguide light-shielding wall 61B and the first inter-waveguide light-shielding wall 61R is equal to the length Wx2 in the same direction of the second inter-waveguide light-shielding wall 62 and the length Wx3 in the same direction of the third inter-waveguide light-shielding wall 63. Needless to say, the length Wx4 of each of the first inter-waveguide light-shielding wall 61B and the first inter-waveguide light-shielding wall 61R is equal to the length Wx4 in the same direction of the first inter-waveguide light-shielding wall 61G.

Components other than the above-described components are the same or substantially the same as the components of the solid-state imaging device 1 according to the 1-1st embodiment described above.

### Workings and Effects

In the solid-state imaging device 1 according to the 1-5th embodiment, it is possible to achieve workings and effects similar to the workings and effects achieved by the solid-state imaging device 1 according to the 1-4th embodiment.

In addition, as illustrated in FIG. 15, the solid-state imaging device 1 includes the first inter-waveguide light-shielding wall 61B between the first color filters 51 having the same color, the first inter-waveguide light-shielding wall 61G between the second color filters 52 having the same color, and the first inter-waveguide light-shielding wall 61R between the third color filters 53 having the same color. The length Wx4 in the arrow-X direction of each of the first inter-waveguide light-shielding wall 61B, the first inter-waveguide light-shielding wall 61G, and the first inter-waveguide light-shielding wall 61R is longer than the length Wy1 in the arrow-Y direction of the fourth inter-waveguide light-shielding wall 64 or the length Wy2 in the arrow-Y direction of the fifth inter-waveguide light-shielding wall 65.

Accordingly, it is possible to effectively limit the light amount of the incident light L2 by each of the first inter-waveguide light-shielding wall 61B, the first inter-waveguide light-shielding wall 61G, and the first inter-waveguide light-shielding wall 61R, which makes it possible to more effectively reduce or prevent a sensitivity difference between the color filters 5 having the same color.

### 6. 1-6th Embodiment

Description is given of the solid-state imaging device 1 according to the 1-6th embodiment with reference to FIGS. 16 to 18. The 1-6th embodiment is an example in which the configuration of the inter-waveguide light-shielding wall 6 in each of an image height center region and an image height end region of the effective pixel region 10 is changed.

FIG. 16 illustrates an example of a planar configuration of the effective pixel region 10 of the solid-state imaging device 1. FIG. 17 illustrates an example of the arrangement configuration of the light-receiving pixels 3, the arrangement configuration of the color filters 5, and the layout configuration of the inter-waveguide light-shielding walls 6 in the image height center region of the effective pixel region 10. FIG. 18 illustrates an example of the arrangement configuration of the light-receiving pixels 3, the arrangement configuration of the color filters 5, and the layout configuration of the inter-waveguide light-shielding walls 6 in the image height end region of the effective pixel region 10.

As with the solid-state imaging device 1 according to each of the 1-1st embodiment to the 1-5th embodiment, as illustrated in FIG. 16, the solid-state imaging device 1 according to the 1-6th embodiment includes the effective pixel region 10 in which a plurality of light-receiving pixels 3 is arranged in the arrow-X direction and the arrow-Y direction. Here, the effective pixel region 10 is formed in a rectangular shape being long in the arrow-X direction with respect to the arrow-Y direction in a plan view, but the shape is not particularly limited.

Furthermore, the light-receiving pixels 3 are arranged in a middle portion as an image height center region 101 of the effective pixel region 10, and the color filters 5 and the lenses 7 (see FIGS. 1, 2, and 5) are disposed on the light-receiving pixels 3. In addition, the light-receiving pixels 3 are arranged in a peripheral portion as an image height end region 102 of the effective pixel region 10, and the color filters 5 and the lenses 7 are disposed on the light-receiving pixels 3.

As illustrated in FIG. 17, as with the solid-state imaging device 1 according to the 1-1st embodiment described above, in the image height center region 101, the first inter-waveguide light-shielding wall 61 is disposed between the first color filters 51 having the same color adjacent in the arrow-X direction. Likewise, the first inter-waveguide light-shielding wall 61 is disposed each between the second color filters 52 having the same color adjacent in the arrow-X direction and between the third color filters 53 having the same color adjacent in the arrow-X direction.

In addition, the second inter-waveguide light-shielding wall 62 is disposed between the first color filter 51 and the second color filter 52 having different colors adjacent in the arrow-X direction. The third inter-waveguide light-shielding wall 63 is disposed between the second color filter 52 and the third color filter 53 having different colors adjacent in the arrow-X direction.

As illustrated in FIG. 18, relative to the image height center region 101, in the image height end region 102, the first inter-waveguide light-shielding wall 61 is disposed each between the first color filters 51 having the same color adjacent in the arrow-X direction, between the second color filters 52 having the same color adjacent in the arrow-X direction, and between the third color filters 53 having the same color adjacent in the arrow-X direction.

Meanwhile, a second inter-waveguide light-shielding wall 62E is disposed between the first color filter 51 and the second color filter 52 having different colors adjacent in the arrow-X direction. Furthermore, a third inter-waveguide light-shielding wall 63E is disposed between the second color filter 52 and the third color filter 53 having different colors adjacent in the arrow-X direction.

The second inter-waveguide light-shielding wall 62E is formed to have a length Wx5 in the arrow-X direction that is longer than the length Wx2 in the arrow-X direction of the second inter-waveguide light-shielding wall 62 in the image height center region 101. Likewise, the third inter-waveguide light-shielding wall 63E is formed to have a length Wx6 in the arrow-X direction that is longer than the length Wx3 in the arrow-X direction of the third inter-waveguide light-shielding wall 63 in the image height center region 101. Here, the length Wx5 of the second inter-waveguide light-shielding wall 62E is equal to the length Wx6 of the third inter-waveguide light-shielding wall 63E.

Components other than the above-described components are the same or substantially the same as the components of the solid-state imaging device 1 according to the 1-1st embodiment described above.

### Workings and Effects

In the solid-state imaging device 1 according to the 1-6th embodiment, it is possible to achieve workings and effects similar to the workings and effects achieved by the solid-state imaging device 1 according to the 1-1st embodiment.

In addition, in the solid-state imaging device 1, as illustrated in FIGS. 16 to 18, the second inter-waveguide light-shielding wall 62 having the length Wx2 in the image height center region 101 corresponds to the second inter-waveguide light-shielding wall 62 having the length Wx5 in the image height end region 102. Likewise, the third inter-waveguide light-shielding wall 63 having the length Wx3 in the image height center region 101 corresponds to the third inter-waveguide light-shielding wall 63 having the length Wx6 in the image height end region 102. That is, the length Wx2 of the second inter-waveguide light-shielding wall 62 and the length Wx3 of the third inter-waveguide light-shielding wall 63 are each adjusted in accordance with an increase in height.

Accordingly, it is possible to effectively reduce or prevent the incident light L2 that enters a color mixture path between the color filters 5 having different colors uniformly over the entire effective pixel region 10. This makes it possible to effectively suppress or prevent variations among the pixel outputs of the light-receiving pixels 3, to reduce or prevent a sensitivity difference between the color filters 5 having different colors, and to effectively suppress or prevent color mixture.

It is to be noted that in the solid-state imaging device 1 according to the 1-6th embodiment, a length Wx of the inter-waveguide light-shielding walls 6 is adjusted at two points including the image height center region 101 and the image height end region 102 from the middle portion to the peripheral portion of the effective pixel region 10. In the present technology, it is possible to adjust the length Wx of the inter-waveguide light-shielding wall 6 at three or more points from the middle portion to the peripheral portion of the effective pixel region 10.

Furthermore, in the present technology, in the effective pixel region 10, the inter-waveguide light-shielding wall 6 disposed in the image height center region 101 may be formed to have the length Wx longer than the length Wx of the inter-waveguide light-shielding wall 6 disposed in the image height end region 102.

### 7. 1-7th Embodiment

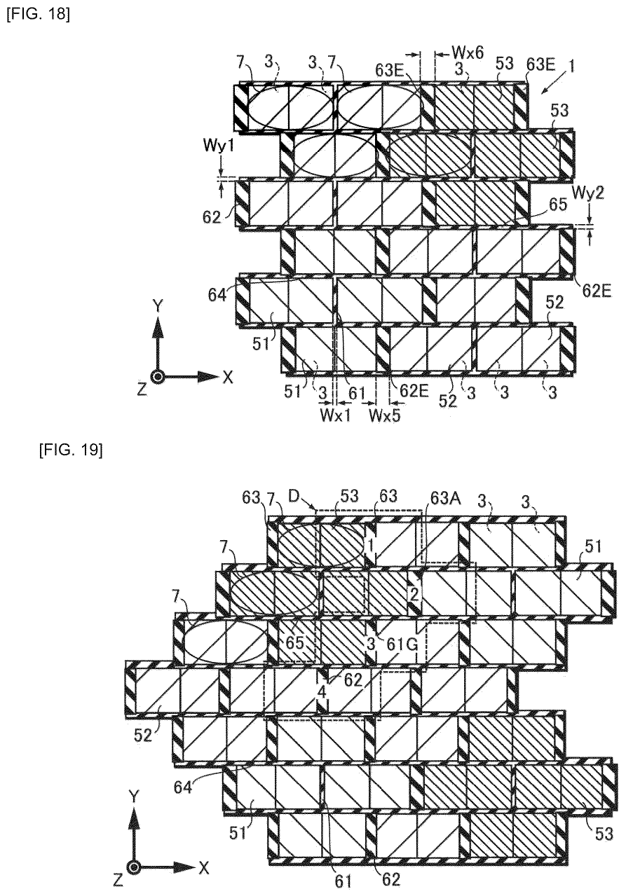

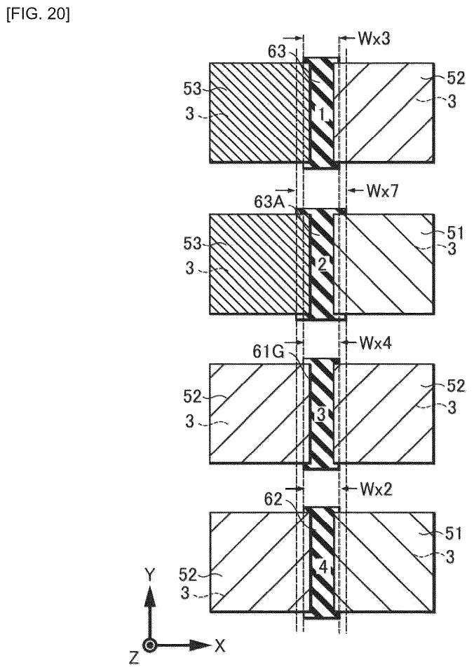

Description is given of the solid-state imaging device 1 according to the 1-7th embodiment with reference to FIGS. 19 and 20. The solid-state imaging device 1 according to the 1-7th embodiment is an application example of the solid-state imaging device 1 according to the 1-4th embodiment.

### [Configuration of Solid-State Imaging Device 1]

FIG. 19 illustrates an example of the arrangement configuration of the light-receiving pixels 3 in the effective pixel region 10 in the solid-state imaging device 1. FIG. 20 illustrates an example of the arrangement configuration of the light-receiving pixels 3, the arrangement configuration of the color filters 5, and the layout configuration of the inter-waveguide light-shielding walls 6 in a main part.

First, as illustrated in FIG. 19, in the solid-state imaging device 1 according to the 1-7th embodiment, the arrangement configuration of the color filters 5 is different from that in the solid-state imaging device 1 according to any of the 1-1st embodiment to the 1-6th embodiment.

In the solid-state imaging device 1 according to the 1-7th embodiment, pixel blocks of one kind, which are not specifically denoted by reference numerals, are arranged in the arrow-X direction, and with respect to these pixel blocks, pixel blocks adjacent in the arrow-Y direction are arranged in the arrow-X direction to be displaced by an amount corresponding to one color filter 5.

The pixel blocks each include one color filter 5, two color filters 5 adjacent in the arrow-X direction, one color filter 5 that are sequentially arranged in the arrow-Y direction. That is, the pixel blocks each include a total of four color filters 5, and are each formed in the shape of a cross in a plan view. That is, a blue pixel block, a green pixel block, and a red pixel block are each formed in the same shape.

As illustrated in FIGS. 19 and 20, as with the solid-state imaging device 1 according to the 1-4th embodiment, the solid-state imaging device 1 according to the 1-7th embodiment includes the light-receiving pixels 3, the first color filters 51 to the third color filters 53, and the first inter-waveguide light-shielding walls 61 to the fifth inter-waveguide light-shielding walls 65. The solid-state imaging device 1 further includes the first inter-waveguide light-shielding wall 61G and a third inter-waveguide light-shielding wall 63A.

Here, description is given of the light-receiving pixels 3, the color filters 5, and the inter-waveguide light-shielding walls 6 in a region encircled with a broken line with a reference number D in FIG. 19. For convenience, the inter-waveguide light-shielding walls 6 are numbered from 1 to 4 from top side to bottom side.

First, the third color filter 53 having red that is the third color is disposed on the light-receiving pixel 3 on left side in the drawing of the third inter-waveguide light-shielding wall 63 numbered 1. Relative to this light-receiving pixel 3 as a center, the second color filter 52 having green that is the second color is disposed on the light-receiving pixel 3 adjacent on right side in the drawing in the arrow-X direction. Relative to the light-receiving pixel 3 as the center, the second color filter 52 having green is disposed on the unillustrated light-receiving pixel 3 adjacent on top side in the drawing in the arrow-Y direction, and the third color filter 53 having red is disposed on the light-receiving pixel 3 adjacent on bottom side in the drawing in the arrow-Y direction. That is, two light-receiving pixels 3 on which the second color filters 52 having a different color are disposed are adjacent to one light-receiving pixel 3 on which the third color filter 53 is disposed.

The third inter-waveguide light-shielding wall 63 is formed to have the length Wx3 in the arrow-X direction.

Here, the third inter-waveguide light-shielding wall 63A is numbered 2. The third color filter 53 having red is disposed on the light-receiving pixel 3 on left side in the drawing of the third inter-waveguide light-shielding wall 63A. Relative to this light-receiving pixel 3 as a center, the first color filter 51 having blue that is the first color is disposed on the light-receiving pixel 3 adjacent on right side in the drawing in the arrow-X direction. Relative to the light-receiving pixel 3 as the center, the second color filter 52 having green is disposed on the light-receiving pixel 3 adjacent on top side in the drawing in the arrow-Y direction, and the second color filter 52 having green is disposed on the light-receiving pixel 3 adjacent on bottom side in the drawing in the arrow-Y direction. That is, a total of three light-receiving pixels 3 including one light-receiving pixel 3 on which the first color filter 51 having a different color is disposed, and two light-receiving pixels 3 on which the second color filters 52 having a different color are disposed are adjacent to one light-receiving pixel 3 on which the third color filter 53 is disposed.

The third inter-waveguide light-shielding wall 63A is formed to have a length Wx7 in the arrow-X direction that is longer than the length Wx3 in the arrow-X direction of the third inter-waveguide light-shielding wall 63.

The first inter-waveguide light-shielding wall 61G numbered 3 has a configuration similar to that of the first inter-waveguide light-shielding wall 61G of the solid-state imaging device 1 according to the 1-4th embodiment. That is, the second color filter 52 having green is disposed on the light-receiving pixel 3 on left side in the drawing of the first inter-waveguide light-shielding wall 61G, and the second color filter 52 having the same color green is also disposed on the light-receiving pixel 3 on right side in the drawing. Relative to the light-receiving pixel 3 as a center, the third color filter 53 having red is disposed on the light-receiving pixel 3 adjacent on top side in the drawing in the arrow-Y direction, and the first color filter 51 having blue is disposed on the light-receiving pixel 3 adjacent on bottom side in the drawing in the arrow-Y direction. That is, a total of three light-receiving pixels 3 including one light-receiving pixel 3 on which the second color filter 52 having the same color is disposed, one light-receiving pixel 3 on which the third color filter 53 having a different color is disposed, and one light-receiving pixel 3 on which the first color filter 51 having a different color is disposed are adjacent to one light-receiving pixel 3 on which the second color filter 52 is disposed.

Here, the length Wx4 in the arrow-X direction of the first inter-waveguide light-shielding wall 61 is equal to the length Wx3 in the arrow-X direction of the third inter-waveguide light-shielding wall 63.

The second color filter 52 having green is disposed on the light-receiving pixel 3 on left side in the drawing of the second inter-waveguide light-shielding wall 62 numbered 4. Relative to this light-receiving pixel 3 as a center, the first color filters 51 having blue are disposed on the light-receiving pixel 3 adjacent on right side in the drawing in the arrow-X direction and the light-receiving pixel 3 adjacent on bottom side in the drawing in the arrow-Y direction. Relative to the light-receiving pixel 3 as the center, the second color filter 52 having green is disposed on the light-receiving pixel 3 adjacent on bottom side in the drawing in the arrow-Y direction. That is, one light-receiving pixel 3 on which the second color filter 52 having the same color is disposed, and two light-receiving pixels 3 on which the first color filters 51 having a different color are disposed are adjacent to one light-receiving pixel 3 on which the second color filter 52 is disposed.

The length Wx2 in the arrow-x direction of the second inter-waveguide light-shielding wall 62 is equal to the length Wx3 in the arrow-X direction of the third inter-waveguide light-shielding wall 63.

Components other than the above-described components are the same or substantially the same as the components of the solid-state imaging device 1 according to the 1-4th embodiment described above.

### Workings and Effects

In the solid-state imaging device 1 according to the 1-7th embodiment, it is possible to achieve workings and effects similar to the workings and effects achieved by the solid-state imaging device 1 according to the 1-1st embodiment.

In addition, in the solid-state imaging device 1, as illustrated in FIGS. 19 to 20, the third inter-waveguide light-shielding wall 63A is disposed in accordance with the number of color filters 5 having different colors disposed on the light-receiving pixels 3 adjacent in the arrow-X direction and the arrow-Y direction to the light-receiving pixel 3 as a center on which the color filter 5 is disposed. The length Wx7 in the arrow-X direction of the third inter-waveguide light-shielding wall 63A is longer than the length Wx4 in the same direction of the first inter-waveguide light-shielding wall 61G, the length Wx2 in the same direction of the second inter-waveguide light-shielding wall 62, and the length Wx3 in the same direction of the third inter-waveguide light-shielding wall 63.

Accordingly, it is possible to effectively correct the light amount of the incident light L2 in accordance with the number of color filters 5 having different colors, which makes it possible to effectively reduce or prevent a sensitivity difference between the color filters 5 having different colors. Thus, it is possible to effectively suppress or prevent color mixture.

### 8. 1-8th Embodiment

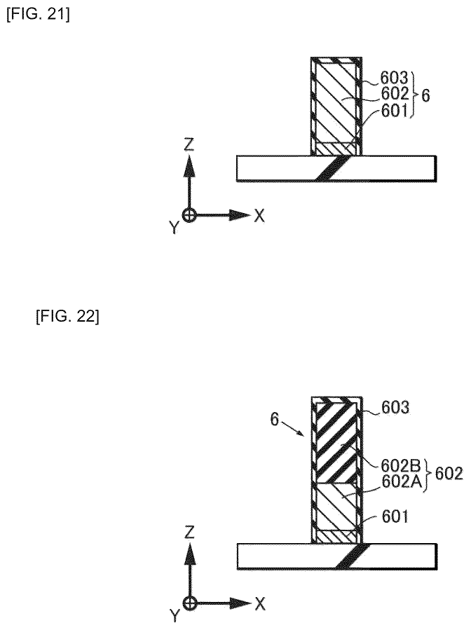

Description is given of the solid-state imaging device 1 according to the 1-8th embodiment with reference to FIG. 21. The solid-state imaging devices 1 according to the 1-8th embodiment and the 1-9th embodiment are examples in which the configuration of the inter-waveguide light-shielding wall 6 is changed.

### [Configuration of Solid-State Imaging Device 1]

FIG. 21 illustrates an example of a cross-sectional configuration of the inter-waveguide light-shielding wall 6 in the solid-state imaging device 1.

As illustrated in FIG. 21, as with the solid-state imaging device 1 according to the 1-1st embodiment, the solid-state imaging device 1 includes the inter-waveguide light-shielding walls 6 between the color filters 5. The inter-waveguide light-shielding walls 6 each include the barrier metal 601, the light-shielding wall body 602, and the protective film 603 in a side view.

The barrier metal 601 includes the same material as that of the barrier metal 601 of the inter-waveguide light-shielding wall 6 according to the 1-1st embodiment. The protective film 603 includes the same martial as that of the protective film 603 of the inter-waveguide light-shielding wall 6 according to the 1-1st embodiment.

The light-shielding wall body 602 is formed using, for example, a high-melting-point metal having a high light-shielding property such as tungsten (W). The thickness of the light-shielding wall body 602 is, for example, greater than or equal to 85 nm and less than or equal to 285 nm.

Here, the height of the inter-waveguide light-shielding wall 6 is, for example, greater than or equal to 100 nm and less than or equal to 600 nm.

Components other than the above-described components are the same or substantially the same as the components of the solid-state imaging device 1 according to the 1-1st embodiment described above.

### Workings and Effects

In the solid-state imaging device 1 according to the 1-8th embodiment, it is possible to achieve workings and effects similar to the workings and effects achieved by the solid-state imaging device 1 according to the 1-1st embodiment.

In addition, in the solid-state imaging device 1, as illustrated in FIG. 21, the light-shielding wall body 602 of the inter-waveguide light-shielding wall 6 includes a high-melting-point metal, which makes it possible to effectively reduce the light amount of the incident light L2 by the inter-waveguide light-shielding wall 6.

### 9. 1-9th Embodiment

Description is given of the solid-state imaging device 1 according to the 1-9th embodiment with reference to FIG. 22. The solid-state imaging device 1 according to the 1-9th embodiment is an example of a configuration in which the respective inter-waveguide light-shielding walls 6 of the solid-state imaging device 1 according to the 1-1st embodiment and the solid-state imaging device 1 according to the 1-8th embodiment are combined.

### [Configuration of Solid-State Imaging Device 1]

FIG. 22 illustrates an example of a cross-sectional configuration of the inter-waveguide light-shielding wall 6 in the solid-state imaging device 1.

As illustrated in FIG. 22, as with the solid-state imaging device 1 according to the 1-1st embodiment, the solid-state imaging device 1 includes the inter-waveguide light-shielding walls 6 between the color filters 5. The inter-waveguide light-shielding walls 6 each include the barrier metal 601, the light-shielding wall body 602, and the protective film 603 in a side view.

The barrier metal 601 includes the same material as that of the barrier metal 601 of the inter-waveguide light-shielding wall 6 according to the 1-1st embodiment. The protective film 603 includes the same martial as that of the protective film 603 of the inter-waveguide light-shielding wall 6 according to the 1-1st embodiment.

The light-shielding wall body 602 includes a first light-shielding wall body 602A formed on the barrier metal 601, and a second light-shielding wall body 602B formed on the first light-shielding wall body 602A. The first light-shielding wall body 602A is formed using the same material as that of the light-shielding wall body 602 of the solid-state imaging device 1 according to the 1-8th embodiment, for example, a high-melting-point metal such as W. The second light-shielding wall body 602B is formed using the same material as that of the light-shielding wall body 602 of the solid-state imaging device 1 according to the 1-1st embodiment, for example, SiO₂.

Components other than the above-described components are the same or substantially the same as the components of the solid-state imaging device 1 according to the 1-1st embodiment described above.

### Workings and Effects

In the solid-state imaging device 1 according to the 1-9th embodiment, it is possible to achieve workings and effects including a combination of the workings and effects achieved by the solid-state imaging device 1 according to the 1-1st embodiment and the workings and effects achieved by the solid-state imaging device 1 according to the 1-8th embodiment.

### 10. 1-10th Embodiment

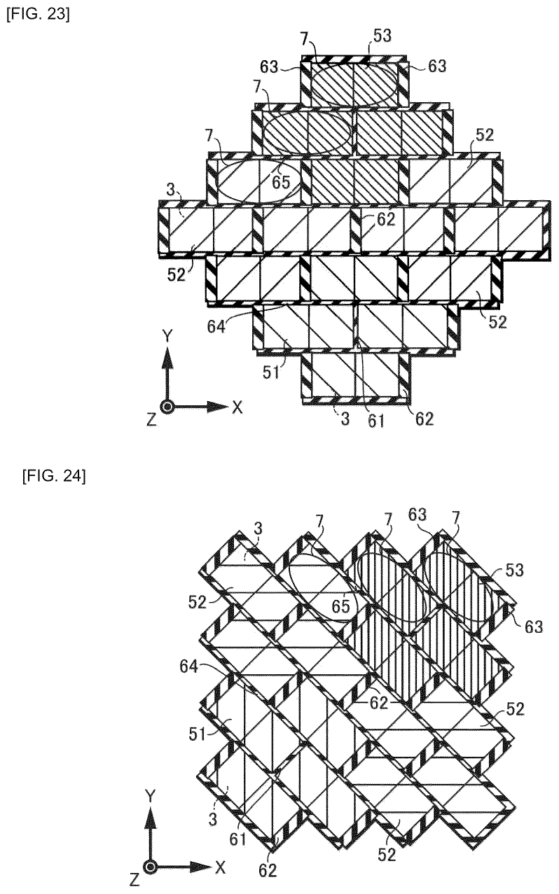

Description is given of the solid-state imaging device 1 according to the 1-10th embodiment with reference to FIG. 23.

### [Configuration of Solid-State Imaging Device 1]

FIG. 23 illustrates an example of the arrangement configuration of the color filters 5 in the solid-state imaging device 1.

The arrangement configuration of the color filters 5 of the solid-state imaging device 1 illustrated in FIG. 23 is the same as the arrangement configuration of the color filters 5 of the solid-state imaging device 1 according to the 1-7th embodiment. The arrangement configuration of the color filters 5 is applicable to the arrangement configurations of the color filters 5 in the solid-state imaging device 1 according to any of the 1-1st embodiment to the 1-6th embodiment, the 1-8th embodiment, and the 1-9th embodiment.

### Workings and Effects

In the solid-state imaging device 1 according to the 1-10th embodiment, it is possible to achieve workings and effects similar to the workings and effects achieved by the solid-state imaging device 1 according to the 1-1st embodiment.

### 11. 1-11th Embodiment

Description is given of the solid-state imaging device 1 according to the 1-11th embodiment with reference to FIG. 24.

### [Configuration of Solid-State Imaging Device 1]

FIG. 24 illustrates an example of the arrangement configuration of the color filters 5 in the solid-state imaging device 1.

An arrangement direction of the color filters 5 in the solid-state imaging device 1 illustrated in FIG. 24 is inclined with respect to an arrangement direction of the color filters 5 in the solid-state imaging device 1 according to the 1-10th embodiment. Here, for convenience, the arrow-X direction and the arrow-Y direction are inclined by 45 degrees with respect to the arrow-Z direction as a rotation axis direction. That is, the light-receiving pixels 3, the color filters 5, and the lenses 7 (see FIGS. 1, 2, and 5) are arranged in each of the inclined arrow-X direction and the inclined arrow-Y direction.

Components other than the above-described components are the same or substantially the same as the components of the solid-state imaging device 1 according to the 1-10th embodiment described above.

### Workings and Effects

In the solid-state imaging device 1 according to the 1-11th embodiment, it is possible to achieve workings and effects similar to the workings and effects achieved by the solid-state imaging device 1 according to the 1-10th embodiment.

### 12. 2-1st Embodiment

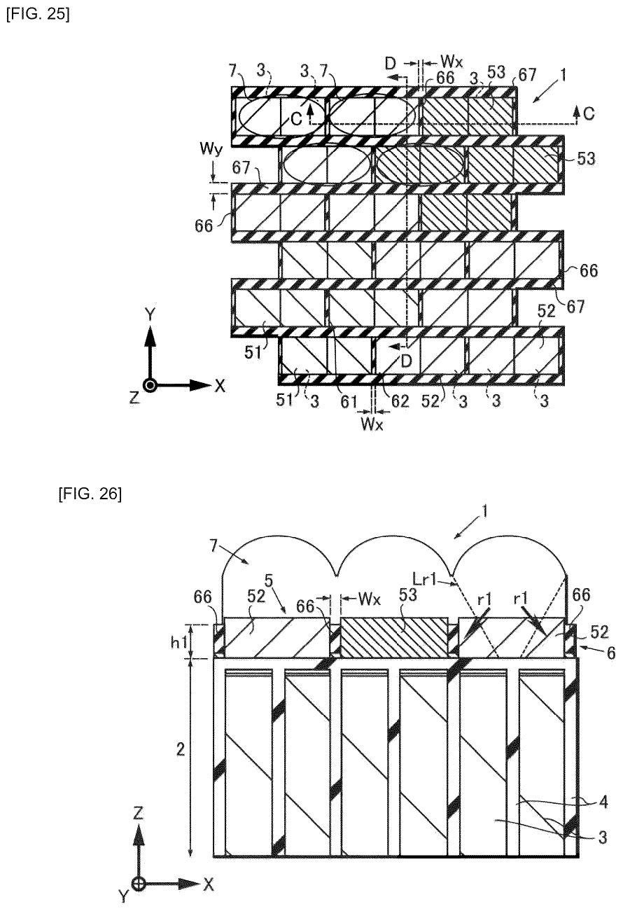

Description is given of the solid-state imaging device 1 according to the 2-1st embodiment with reference to FIGS. 25 to 27. The 2-1st embodiment to the 2-10th embodiment are examples in which the configuration of the inter-waveguide light-shielding wall 6 in the solid-state imaging device 1 according to the 1-1st embodiment is changed.

### [Configuration of Solid-State Imaging Device 1]

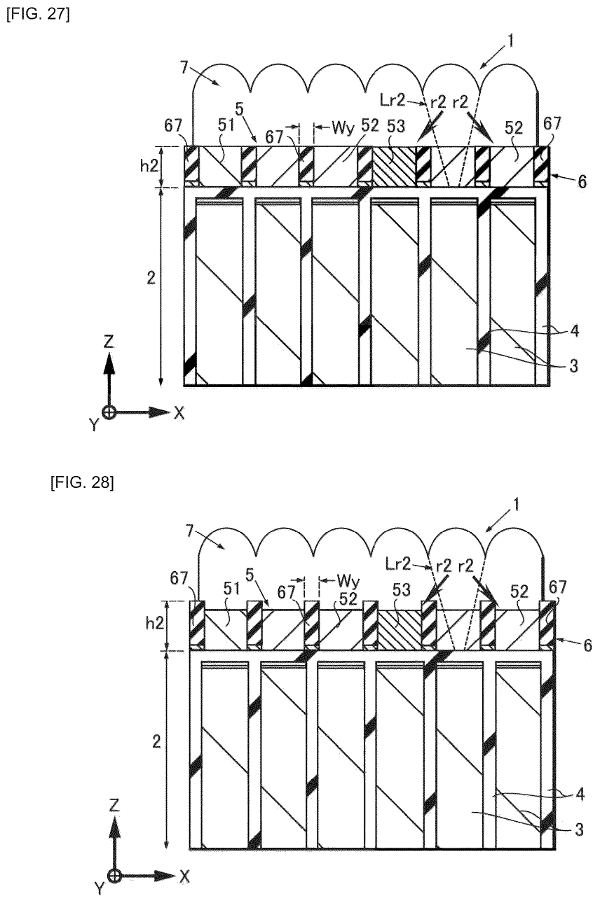

FIG. 25 illustrates an example of the arrangement configuration of the light-receiving pixels 3 and the arrangement configuration of the color filters 5 in the effective pixel region 10 in the solid-state imaging device 1. FIG. 26 illustrates an example of a cross-sectional configuration of a main part of the effective pixel region 10 taken along a line C-C illustrated in FIG. 25. FIG. 27 illustrates an example of a cross-sectional configuration of a main part of the effective pixel region 10 taken along a line D-D illustrated in FIG. 25.

As illustrated in FIGS. 25 to 27, in the solid-state imaging device 1, as with the solid-state imaging device 1 according to the 1-1st embodiment, a plurality of light-receiving pixels 3 is arranged. The color filters 5 are disposed on the light-receiving pixels 3. Further, the lenses 7 are disposed on the color filters 5. Furthermore, the inter-waveguide light-shielding walls 6 are disposed between the color filters 5. In the 2-1st embodiment, the inter-waveguide light-shielding walls 6 include a sixth inter-waveguide light-shielding wall 66 and a seventh inter-waveguide light-shielding wall 67.

The sixth inter-waveguide light-shielding wall 66 is disposed each between the first color filters 51 having blue that is the first color adjacent in the arrow-X direction, between the second color filters 52 having green that is the second color adjacent in the arrow-X direction, and between the third color filters 53 having red that is the third color adjacent in the arrow-X direction. That is, the sixth inter-waveguide light-shielding wall 66 is disposed between the color filters 5 having the same color adjacent in the arrow-X direction.

In addition, the sixth inter-waveguide light-shielding wall 66 is also disposed each between the first color filter 51 and the second color filter 52 adjacent in the arrow-X direction and between the second color filter 52 and the third color filter 53 adjacent in the arrow-X direction. That is, the sixth inter-waveguide light-shielding wall 66 is disposed between the color filters 5 having different colors.

The sixth inter-waveguide light-shielding wall 66 is a component corresponding to the first inter-waveguide light-shielding wall 61 to the third inter-waveguide light-shielding wall 63 in the solid-state imaging device 1 according to the 1-1st embodiment. Here, the length Wx in the arrow-X direction of the sixth inter-waveguide light-shielding wall 66 is the same irrespective of whether being disposed between the color filters 5 having the same color or between the color filters 5 having different colors.

In addition, a height h1 of the sixth inter-waveguide light-shielding wall 66 from the light-receiving pixel 3 is set to be slightly lower than the thickness of the color filter 5.

Meanwhile, the seventh inter-waveguide light-shielding wall 67 is disposed each between the first color filters 51 adjacent in the arrow-Y direction, between the second color filters 52 adjacent in the arrow-Y direction, and between the third color filters 53 adjacent in the arrow-Y direction. That is, the seventh inter-waveguide light-shielding wall 67 is disposed between the color filters 5 having the same color adjacent in the arrow-Y direction.

In addition, the seventh inter-waveguide light-shielding wall 67 is disposed each between the first color filter 51 and the second color filter 52 adjacent in the arrow-Y direction, between the second color filter 52 and the third color filter 53 adjacent in the arrow-Y direction, and between the third color filter 53 and the first color filter 51 adjacent in the arrow-Y direction. That is, the seventh inter-waveguide light-shielding wall 67 is also disposed between the color filters 5 having different colors.

The seventh inter-waveguide light-shielding wall 67 is a component corresponding to the fourth inter-waveguide light-shielding wall 64 and the fifth inter-waveguide light-shielding wall 65 in the solid-state imaging device 1 according to the 1-1st embodiment. Here, the length Wy in the arrow-Y direction of the seventh inter-waveguide light-shielding wall 67 is the same irrespective of whether being disposed between the color filters 5 having the same color or between the color filters 5 having different colors. Furthermore, the seventh inter-waveguide light-shielding wall 67 is formed to have the length Wy longer than the length Wx of the sixth inter-waveguide light-shielding wall 66. Accordingly, a light-shielding property of the seventh inter-waveguide light-shielding wall 67 is higher than a light-shielding property of the sixth inter-waveguide light-shielding wall 66.

As illustrated in FIG. 25, the seventh inter-waveguide light-shielding wall 67 continuously extends in the arrow-X direction between the color filter 5 having the same color adjacent in the arrow-Y direction and between the color filters 5 having different colors adjacent in the arrow-Y direction.

In addition, here, a height h2 of the seventh inter-waveguide light-shielding wall 67 from the light-receiving pixel 3 is higher than the height h1 of the sixth inter-waveguide light-shielding wall 66, and is set to be equal to the thickness of the color filter 5.

Components other than the above-described components are the same or substantially the same as the components of the solid-state imaging device 1 according to the 1-1st embodiment described above.

### Workings and Effects

As illustrated in FIGS. 25 to 27, the solid-state imaging device 1 according to the 2-1st embodiment includes the light-receiving pixels 3, the first color filters 51, the second color filters 52, the third color filters 53, the lenses 7, the sixth inter-waveguide light-shielding walls 66, and the seventh inter-waveguide light-shielding walls 67.

A plurality of light-receiving pixels 3 is arranged in the arrow-X direction and the arrow-Y direction intersecting with the arrow-X direction. The first color filter 51 is disposed over a plurality of light-receiving pixels 3 arranged in the arrow-X direction, and has the first color. The second color filter 52 is disposed over a plurality of light-receiving pixels 3 arranged in the arrow-X direction, and has the second color different from the first color. The third color filter 53 is disposed over a plurality of light-receiving pixels 3 arranged in the arrow-X direction, and has the third color different from the first color and the second color. The lens 7 is disposed on each of the first color filter 51, the second color filter 52, and the third color filter 53. The lens 7 has a small aspect ratio in the arrow-Y direction to the arrow-X direction, and protrudes and curves on side opposite to the light-receiving pixel 3.

Here, the sixth inter-waveguide light-shielding wall 66 is disposed each between the color filters 5 having the same color adjacent in the arrow-X direction and between the color filters 5 having the different colors adjacent in the arrow-X direction, and has a light-shielding property. In contrast, the seventh inter-waveguide light-shielding wall 67 is disposed between the color filters 5 having the same color adjacent in the arrow-Y direction and between the color filters 5 having different colors adjacent in the arrow-Y direction. The seventh inter-waveguide light-shielding wall 67 has a light-shielding property higher than the light-shielding property of the sixth inter-waveguide light-shielding wall 66.

As illustrated in FIG. 5 described above, the lens 7 has the major axis Lx and the minor axis Ly, and the is formed to have, for example, an aspect ratio of 2:1. As illustrated in FIG. 26, on side of the major axis Lx of the lens 7, refracted light Lr1 that has entered the lens 7 and has been refracted by the lens 7 passes through the color filter 5 and enters the two light-receiving pixels 3 adjacent in the arrow-X direction. At this time, leakage light r1 to the surrounding light-receiving pixels 3 is extremely small.

Meanwhile, as illustrated in FIG. 27, on side of the minor axis Ly of the lens 7, refracted light Lr2 that has entered the lens 7 and has been refracted by the lens 7 passes through the color filter 5 and enters one light-receiving pixel 3. At this time, the aperture of the refracted light Lr2 becomes steep, which causes leakage light r2 to the surrounding light-receiving pixels 3 to become larger than the leakage light r1.

The seventh inter-waveguide light-shielding wall 67 has the light-shielding property higher than that of the sixth inter-waveguide light-shielding wall 66, which makes it possible to effectively reduce or prevent the leakage light r2. This makes it possible to effectively suppress or prevent variations among the pixel outputs of the light-receiving pixels 3, in particular, among pixel outputs adjacent in the arrow-Y direction, to reduce or prevent, in particular, a sensitivity difference between the color filters 5 having different colors, and to effectively suppress or prevent color mixture.

In addition, in the solid-state imaging device 1, as illustrated in FIGS. 25 to 27, the length Wy in the arrow-Y direction of the seventh inter-waveguide light-shielding wall 67 is longer than the length Lx in the arrow-X direction of the sixth inter-waveguide light-shielding wall 66. Accordingly, it is possible to enhance the light-shielding property of the seventh inter-waveguide light-shielding wall 67 and effectively reduce or prevent the leakage light r2, which makes it possible to reduce or prevent, in particular, a sensitivity difference between the color filters 5 having different colors.

Furthermore, in the solid-state imaging device 1, the height h2 of the seventh inter-waveguide light-shielding wall 67 from the light-receiving pixel 3 is higher than the height h1 of the sixth inter-waveguide light-shielding wall 66 from the light-receiving pixel 3. Accordingly, it is possible to enhance the light-shielding property of the seventh inter-waveguide light-shielding wall 67 and effectively reduce or prevent the leakage light r2, which makes it possible to reduce or prevent, in particular, a sensitivity difference between the color filters 5 having different colors.

### 13. 2-2nd Embodiment

Description is given of the solid-state imaging device 1 according to the 2-2nd embodiment of the present disclosure with reference to FIG. 28. The 2-2nd embodiment to the 2-4th embodiment are examples in which the configuration of the inter-waveguide light-shielding wall 6 in the solid-state imaging device 1 according to the 2-1st embodiment is changed.

### [Configuration of Solid-State Imaging Device 1]

FIG. 28 illustrates an example of a cross-sectional configuration of a main part of the effective pixel region 10 in the solid-state imaging device 1.

As illustrated in FIG. 28, as with the solid-state imaging device 1 according to the 2-1st embodiment, the solid-state imaging device 1 includes the seventh inter-waveguide light-shielding wall 67. The height h2 of the seventh inter-waveguide light-shielding wall 67 is higher than the height h1 of the sixth inter-waveguide light-shielding wall 66. Here, the seventh inter-waveguide light-shielding wall 67 is formed to have the height h2 higher than the thickness of the color filter 5.

Components other than the above-described components are the same or substantially the same as the components of the solid-state imaging device 1 according to the 2-1st embodiment described above.

### Workings and Effects

In the solid-state imaging device 1 according to the 2-2nd embodiment, it is possible to achieve workings and effects similar to the workings and effects achieved by the solid-state imaging device 1 according to the 2-1st embodiment.

Furthermore, in the solid-state imaging device 1, the height h2 of the seventh inter-waveguide light-shielding wall 67 from the light-receiving pixel 3 is higher than the thickness of the color filter 5. This makes it possible to further enhance the light-shielding property of the seventh inter-waveguide light-shielding wall 67 and effectively reduce or prevent the leakage light r2.

### 14. 2-3rd Embodiment

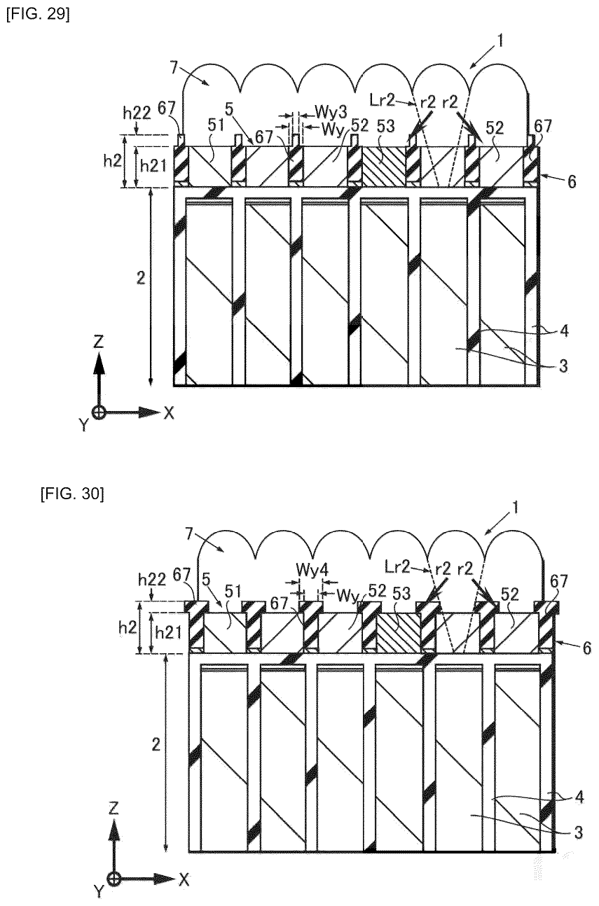

Description is given of the solid-state imaging device 1 according to the 2-3rd embodiment of the present disclosure with reference to FIG. 29.

### [Configuration of Solid-State Imaging Device 1]

FIG. 29 illustrates an example of a cross-sectional configuration of a main part of the effective pixel region 10 in the solid-state imaging device 1.

As illustrated in FIG. 29, as with the solid-state imaging device 1 according to the 2-1st embodiment, the solid-state imaging device 1 includes the sixth inter-waveguide light-shielding wall 66 and the seventh inter-waveguide light-shielding wall 67.

Here, the sixth inter-waveguide light-shielding wall 66 is formed to have the height h1 slightly higher than the thickness of the color filter 5.

Meanwhile, the seventh inter-waveguide light-shielding wall 67 is formed to have the height h2 higher than the height h1 of the sixth inter-waveguide light-shielding wall 66.

More specifically, the seventh inter-waveguide light-shielding wall 67 includes a low part having a height equal to the thickness of the color filter 5 and a high part having a height higher than the height h1 of the sixth inter-waveguide light-shielding wall 66. The height h2 is a height obtained by adding a height h22 of the high part from the color filter 5 to a height h21 of the low part from the light-receiving pixel 3. The high part of the seventh inter-waveguide light-shielding wall 67 is formed to have a short length Wy3 in the arrow-Y direction, relative to the length Wy in the arrow-Y direction of the low part.

Components other than the above-described components are the same or substantially the same as the components of the solid-state imaging device 1 according to the 2-1st embodiment described above.

### Workings and Effects

In the solid-state imaging device 1 according to the 2-3rd embodiment, it is possible to achieve workings and effects similar to the workings and effects achieved by the solid-state imaging device 1 according to the 2-2nd embodiment.

In addition, in the solid-state imaging device 1, as illustrated in FIG. 29, the height h2 of the seventh inter-waveguide light-shielding wall 67 from the light-receiving pixel 3 is higher than the height h1 of the sixth inter-waveguide light-shielding wall 66 from the light-receiving pixel 3. Furthermore, the length Wy3 in the arrow-Y direction of a part higher than the sixth inter-waveguide light-shielding wall 66 of the seventh inter-waveguide light-shielding wall 67 is shorter than the length Wy in the arrow-Y direction of a part lower than the sixth inter-waveguide light-shielding wall 66 of the seventh inter-waveguide light-shielding wall 67.

Accordingly, it is possible to further enhance the light-shielding property by the high part of the seventh inter-waveguide light-shielding wall 67 and effectively reduce or prevent the leakage light r2.

### 15. 2-4th Embodiment

Description is given of the solid-state imaging device 1 according to the 2-4th embodiment of the present disclosure with reference to FIG. 30.

### [Configuration of Solid-State Imaging Device 1]

FIG. 30 illustrates an example of a cross-sectional configuration of a main part of the effective pixel region 10 in the solid-state imaging device 1.

As illustrated in FIG. 30, as with the solid-state imaging device 1 according to the 2-3rd embodiment, the solid-state imaging device 1 includes the seventh inter-waveguide light-shielding wall 67.

As with the seventh inter-waveguide light-shielding wall 67 in the solid-state imaging device 1 according to the 2-4th embodiment, the seventh inter-waveguide light-shielding wall 67 includes a low part having a height equal to the thickness of the color filter 5 and a high part having a height higher than the height h1 of the sixth inter-waveguide light-shielding wall 66. Furthermore, the high part of the seventh inter-waveguide light-shielding wall 67 is formed to have a long length Wy4 in the arrow-Y direction, relative to the length Wy in the arrow-Y direction of the low part.

Components other than the above-described components are the same or substantially the same as the components of the solid-state imaging device 1 according to the 2-1st embodiment described above.

### Workings and Effects

In the solid-state imaging device 1 according to the 2-4th embodiment, it is possible to achieve workings and effects similar to the workings and effects achieved by the solid-state imaging device 1 according to the 2-3rd embodiment.

In addition, in the solid-state imaging device 1, as illustrated in FIG. 30, the length Wy4 in the arrow-Y direction of a part higher than the sixth inter-waveguide light-shielding wall 66 of the seventh inter-waveguide light-shielding wall 67 is longer than the length Wy in the arrow-Y direction of a low part of the seventh inter-waveguide light-shielding wall 67. Accordingly, it is possible to further enhance the light-shielding property by the high part of the seventh inter-waveguide light-shielding wall 67 and effectively reduce or prevent the leakage light r2.

### 16. 2-5th Embodiment

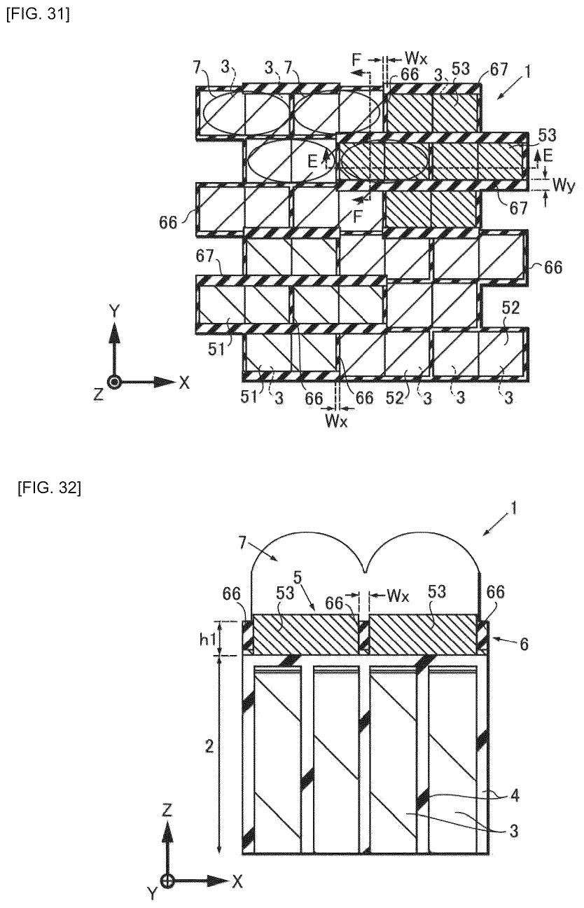

Description is given of the solid-state imaging device 1 according to the 2-5th embodiment of the present disclosure with reference to FIGS. 31 to 33. The 2-5th embodiment to the 2-10th embodiment are examples in which the arrangement configuration of the inter-waveguide light-shielding walls 6 in the solid-state imaging device 1 according to the 2-1st embodiment is changed.

### [Configuration of Solid-State Imaging Device 1]

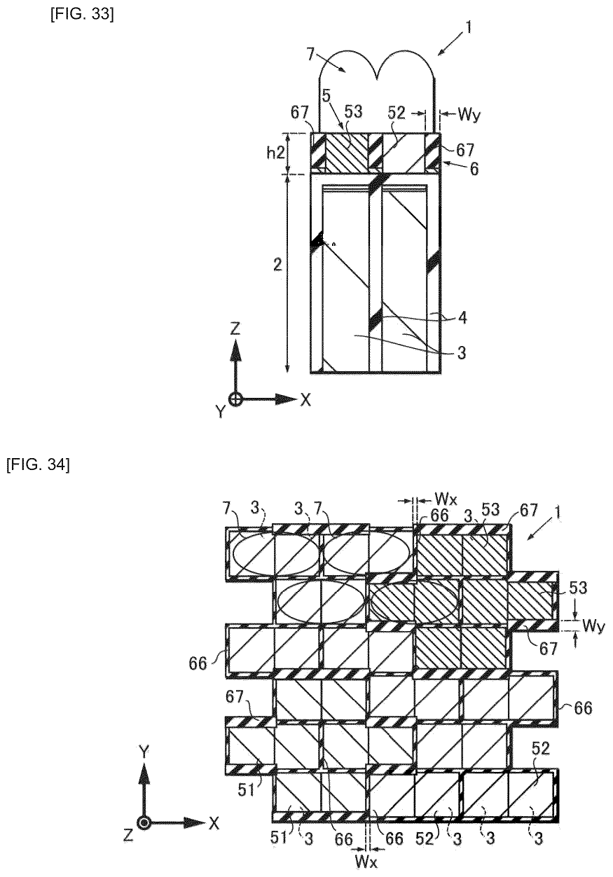

FIG. 31 illustrates an example of the arrangement configuration of the light-receiving pixels 3 and the arrangement configuration of the color filters 5 in the effective pixel region 10 in the solid-state imaging device 1. FIG. 32 illustrates an example of a cross-sectional configuration of a main part of the effective pixel region 10 taken along a line E-E illustrated in FIG. 31. FIG. 33 illustrates an example of a cross-sectional configuration of a main part of the effective pixel region 10 taken along a line F-F illustrated in FIG. 31.

As illustrated in FIGS. 31 to 33, as with the solid-state imaging device 1 according to the 2-1st embodiment, the solid-state imaging device 1 includes the sixth inter-waveguide light-shielding wall 66 and the seventh inter-waveguide light-shielding wall 67.

As with the sixth inter-waveguide light-shielding wall 66 of the solid-state imaging device 1 according to the 2-1st embodiment, the sixth inter-waveguide light-shielding wall 66 is disposed each between the first color filters 51 adjacent in the arrow-X direction, between the second color filters 52 adjacent in the arrow-X direction, and between the third color filters 53 adjacent in the arrow-X direction. That is, the sixth inter-waveguide light-shielding wall 66 is disposed between the color filters 5 having the same color adjacent in the arrow-X direction.

In addition, the sixth inter-waveguide light-shielding wall 66 is also disposed each between the first color filter 51 and the second color filter 52 adjacent in the arrow-X direction, between the second color filter 52 and the third color filter 53 adjacent in the arrow-X direction, and between the third color filter 53 and the first color filter 51 adjacent in the arrow-X direction. That is, the sixth inter-waveguide light-shielding wall 66 is also disposed between the color filters 5 having different colors.

The length Wx in the arrow-X direction of the sixth inter-waveguide light-shielding wall 66 is the same irrespective of whether being disposed between the color filters 5 having the same color or between the color filters 5 having different colors.

Meanwhile, the seventh inter-waveguide light-shielding wall 67 is disposed each between the first color filter 51 adjacent in the arrow-Y direction and between the third color filters 53 adjacent in the arrow-Y direction. That is, the seventh inter-waveguide light-shielding wall 67 is disposed between the color filters 5 having the same color adjacent in the arrow-Y direction, except for between the second color filters 52.

In addition, the seventh inter-waveguide light-shielding wall 67 is also disposed each between the first color filter 51 and the second color filter 52 adjacent in the arrow-Y direction and between the second color filter 52 and the third color filter 53 adjacent in the arrow-Y direction. That is, the seventh inter-waveguide light-shielding wall 67 is also disposed between the color filters 5 having different colors.

The fourth inter-waveguide light-shielding wall 64 is disposed between the second color filters 52 adjacent in the arrow-Y direction.

Components other than the above-described components are the same or substantially the same as the components of the solid-state imaging device 1 according to the 2-1st embodiment described above.

### Workings and Effects

In the solid-state imaging device 1 according to the 2-5th embodiment, it is possible to achieve workings and effects similar to the workings and effects achieved by the solid-state imaging device 1 according to the 2-1st embodiment.

### 17. 2-6th Embodiment

Description is given of the solid-state imaging device 1 according to the 2-6th embodiment of the present disclosure with reference to FIG. 34.

### [Configuration of Solid-State Imaging Device 1]

FIG. 34 illustrates an example of the arrangement configuration of the light-receiving pixels 3 and the arrangement configuration of the color filters 5 in the effective pixel region 10 in the solid-state imaging device 1.

As illustrated in FIG. 34, as with the solid-state imaging device 1 according to the 2-5th embodiment, the solid-state imaging device 1 includes the sixth inter-waveguide light-shielding wall 66 and the seventh inter-waveguide light-shielding wall 67.

As with the sixth inter-waveguide light-shielding wall 66 in the solid-state imaging device 1 according to the 2-5th embodiment, the sixth inter-waveguide light-shielding wall 66 is disposed each between the first color filters 51 adjacent in the arrow-X direction, between the second color filters 52 adjacent in the arrow-X direction, and between the third color filters 53 adjacent in the arrow-X direction. That is, the sixth inter-waveguide light-shielding wall 66 is disposed between the color filters 5 having the same color adjacent in the arrow-X direction.

In addition, the sixth inter-waveguide light-shielding wall 66 is also disposed each between the first color filter 51 and the second color filter 52 adjacent in the arrow-X direction and between the second color filter 52 and the third color filter 53 adjacent in the arrow-X direction. That is, the sixth inter-waveguide light-shielding wall 66 is also disposed between the color filters 5 having different colors.

The length Wx in the arrow-X direction of the sixth inter-waveguide light-shielding wall 66 is the same irrespective of whether being disposed between the color filters 5 having the same color or between the color filters 5 having different colors.

Meanwhile, the seventh inter-waveguide light-shielding wall 67 is disposed each between the first color filter 51 and the second color filter 52 adjacent in the arrow-Y direction and between the second color filter 52 and the third color filter 53 adjacent in the arrow-Y direction. That is, the seventh inter-waveguide light-shielding wall 67 is also disposed between the color filters 5 having different colors.

Here, the fourth inter-waveguide light-shielding wall 64 is disposed each between the first color filters 51 adjacent in the arrow-Y direction, between the second color filters 52 adjacent in the arrow-Y direction, and between the third color filters 53 adjacent in the arrow-Y direction. That is, the seventh inter-waveguide light-shielding wall 67 is not disposed between the color filters 5 having the same color, and in place of the seventh inter-waveguide light-shielding wall 67, the fourth inter-waveguide light-shielding wall 64 is disposed between the color filters 5 having the same color.

Components other than the above-described components are the same or substantially the same as the components of the solid-state imaging device 1 according to the 2-1st embodiment described above.

### Workings and Effects

In the solid-state imaging device 1 according to the 2-6th embodiment, it is possible to achieve workings and effects similar to the workings and effects achieved by the solid-state imaging device 1 according to the 2-1st embodiment.

### 18. 2-7th Embodiment

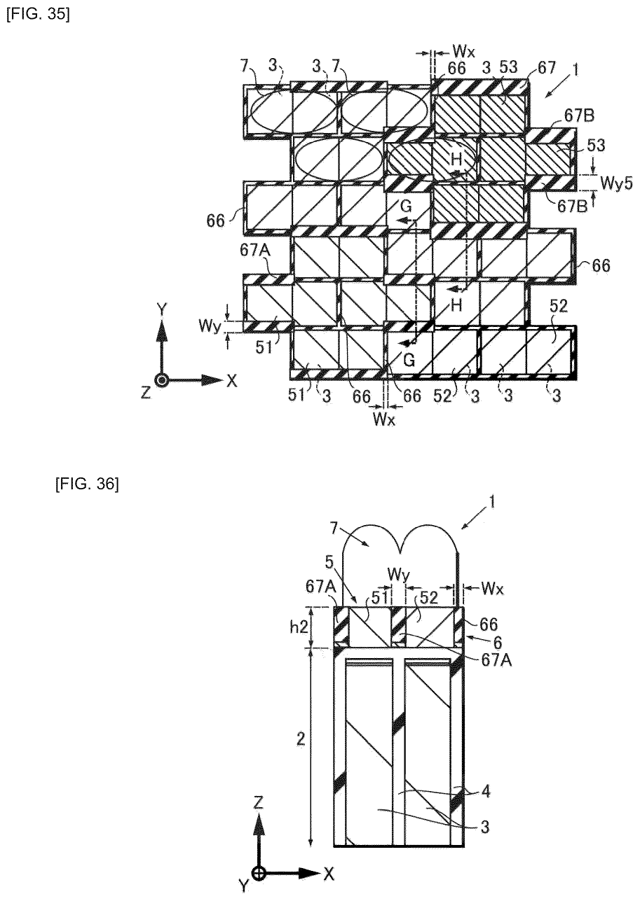

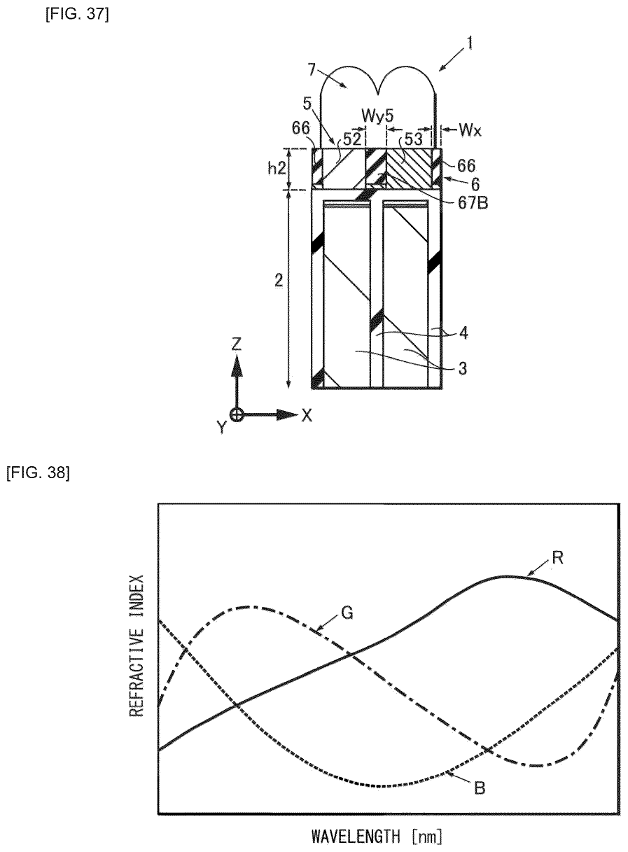

Description is given of the solid-state imaging device 1 according to the 2-7th embodiment of the present disclosure with reference to FIGS. 35 to 38.

### [Configuration of Solid-State Imaging Device 1]

FIG. 35 illustrates an example of the arrangement configuration of the light-receiving pixels 3 and the arrangement configuration of the color filters 5 in the effective pixel region 10 in the solid-state imaging device 1. FIG. 36 illustrates an example of a cross-sectional configuration of a main part of the effective pixel region 10 taken along a line G-G illustrated in FIG. 35. FIG. 36 illustrates an example of a cross-sectional configuration of a main part of the effective pixel region 10 taken along a line H-H illustrated in FIG. 35.

As illustrated in FIGS. 35 to 37, as with the solid-state imaging device 1 according to the 2-6th embodiment, the solid-state imaging device 1 includes the seventh inter-waveguide light-shielding walls 67. The seventh inter-waveguide light-shielding walls 67 further include a seventh inter-waveguide light-shielding wall 67A and a seventh inter-waveguide light-shielding wall 67B.

The seventh inter-waveguide light-shielding wall 67A is disposed between the first color filter 51 and the second color filter 52 adjacent in the arrow-Y direction. The seventh inter-waveguide light-shielding wall 67A corresponds to the seventh inter-waveguide light-shielding wall 67 of the solid-state imaging device 1 according to the 2-6th embodiment, and is formed to have the length Wy in the arrow-Y direction.

Relative to the seventh inter-waveguide light-shielding wall 67A, the seventh inter-waveguide light-shielding wall 67B is disposed between the second color filter 52 and the third color filter 53 adjacent in the arrow-Y direction. In other words, the seventh inter-waveguide light-shielding wall 67B is disposed around the third color filter 53 in the arrow-Y direction. A length Wy5 in the arrow-Y direction of the seventh inter-waveguide light-shielding wall 67B is longer than the length Wy in the same direction of the seventh inter-waveguide light-shielding wall 67A.

FIG. 38 illustrates an example of a relationship between a wavelength of light passing through the color filter 5 and a refractive index. A horizontal axis indicates the wavelength, and a vertical axis indicates the refractive index.

As illustrated in FIG. 38, in the third color filter 53 having red, the refractive index becomes high in a long wavelength range. Accordingly, a refractive index difference between the third color filter 53 and the first color filter 51 having blue, and a refractive index difference between the third color filter 53 and the second color filter 52 having green become larger than a refractive index difference between the first color filter 51 and the second color filter 52. Accordingly, the seventh inter-waveguide light-shielding wall 67B having the length Wy5 is disposed around the third color filter 53, and the leakage light r2 (see FIG. 23) is effectively limited.

Components other than the above-described components are the same or substantially the same as the components of the solid-state imaging device 1 according to the 2-1st embodiment described above.

### Workings and Effects

In the solid-state imaging device 1 according to the 2-7th embodiment, it is possible to achieve workings and effects similar to the workings and effects achieved by the solid-state imaging device 1 according to the 2-6th embodiment.

In addition, in the solid-state imaging device 1, as illustrated in FIGS. 35 to 37, the seventh inter-waveguide light-shielding walls 67 include the seventh inter-waveguide light-shielding wall 67A and the seventh inter-waveguide light-shielding wall 67B. The length Wy in the arrow-Y direction of the seventh inter-waveguide light-shielding wall 67B is adjusted in accordance with a refractive index difference between the refractive index of the first color filter 51 and the refractive index of the second color filter 52. The length Wy5 in the arrow-Y direction of the seventh inter-waveguide light-shielding wall 67B is adjusted in accordance with a refractive index difference between the refractive index of the second color filter 52 and the refractive index of the third color filter 53.

Here, the length Wy5 of the seventh inter-waveguide light-shielding wall 67B is longer than the length Wy5 of the seventh inter-waveguide light-shielding wall 67B, because the refractive index difference is large.

Accordingly, it is possible to further enhance the light-shielding property by the seventh inter-waveguide light-shielding wall 67B and effectively reduce or prevent the leakage light r2.

### 19. 2-8th Embodiment

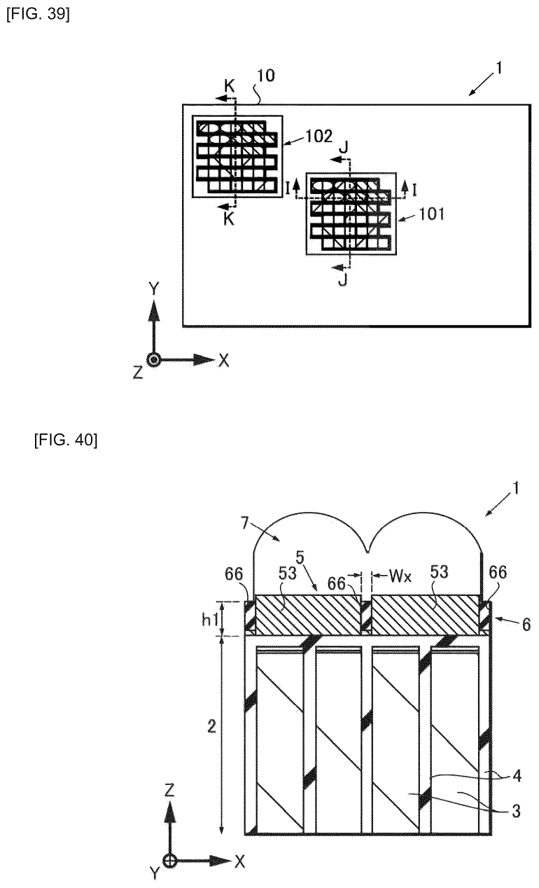

Description is given of the solid-state imaging device 1 according to the 2-8th embodiment of the present disclosure with reference to FIGS. 39 to 42.

### [Configuration of Solid-State Imaging Device 1]

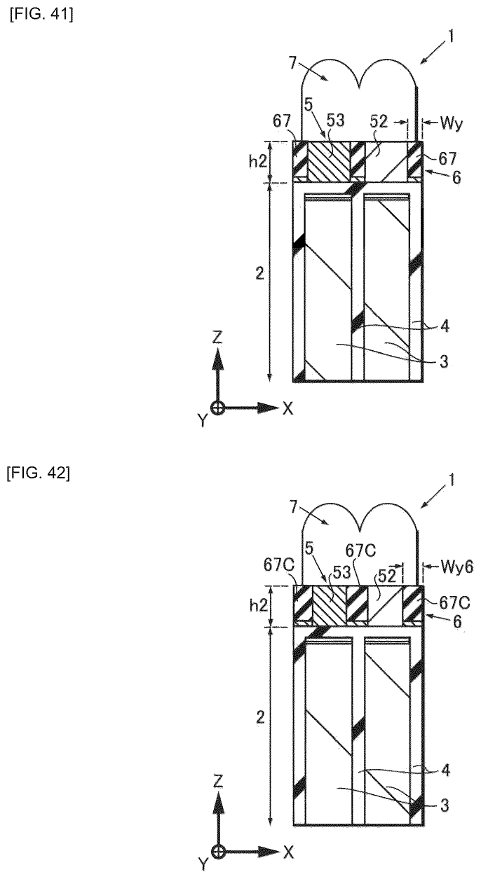

FIG. 39 illustrates an example of the arrangement configuration of the light-receiving pixels 3 and the arrangement configuration of the color filters 5 in the effective pixel region 10 in the solid-state imaging device 1. FIG. 40 illustrates an example of a cross-sectional configuration of a main part of the effective pixel region 10 taken along a line I-I illustrated in FIG. 39. FIG. 41 illustrates an example of a cross-sectional configuration of a main part of the effective pixel region 10 taken along a line J-J illustrated in FIG. 39. FIG. 42 illustrates an example of a cross-sectional configuration of a main part of the effective pixel region 10 taken along a line K-K illustrated in FIG. 39.

As illustrated in FIG. 39, as with the solid-state imaging device 1 according to the 1-6th embodiment, the solid-state imaging device 1 includes the effective pixel region 10.

As illustrated in FIGS. 40 and 41, as with the solid-state imaging device 1 according to the 2-1st embodiment, in the image height center region 101 of the effective pixel region 10, the sixth inter-waveguide light-shielding wall 66 and the seventh inter-waveguide light-shielding wall 67 are included. The seventh inter-waveguide light-shielding wall 67 is formed to have a long length Wy in the arrow-Y direction, relative to the length Wx in the arrow-X direction of the sixth inter-waveguide light-shielding wall 66.

As illustrated in FIG. 42, in the image height end region 102 of the effective pixel region 10, the sixth inter-waveguide light-shielding wall 66 and a seventh inter-waveguide light-shielding wall 67C are included. The seventh inter-waveguide light-shielding wall 67C is formed to have a long length Wy6 in arrow-Y direction, relative to the length Wy of the seventh inter-waveguide light-shielding wall 67.

Components other than the above-described components are the same or substantially the same as the components of the solid-state imaging device 1 according to the 2-1st embodiment described above.

### Workings and Effects

In the solid-state imaging device 1 according to the 2-8th embodiment, it is possible to achieve workings and effects similar to the workings and effects achieved by the solid-state imaging device 1 according to the 2-1st embodiment.

In addition, in the solid-state imaging device 1, as illustrated in FIGS. 39 to 42, the length Wy6 in the arrow-Y direction of the seventh inter-waveguide light-shielding wall 67C disposed in the image height end region 102 is longer than the length Wy of the seventh inter-waveguide light-shielding wall 67 disposed in the image height center region 101.

In the image height end region 102, the leakage light r2 is limited by the seventh inter-waveguide light-shielding wall 67C, which makes it possible to effectively reduce or prevent the leakage light r2 uniformly over the entire effective pixel region 10. This makes it possible to effectively suppress or prevent variations among the pixel outputs of the light-receiving pixels 3.

It is to be noted that as with the solid-state imaging device 1 according to the 1-6th embodiment, in the solid-state imaging device 1 according to the 2-8th embodiment, it is possible to adjust the length Wy of the seventh inter-waveguide light-shielding wall 67 at three or more points from the middle portion to the peripheral portion of the effective pixel region 10.

Furthermore, in the solid-state imaging device 1, in the effective pixel region 10, the seventh inter-waveguide light-shielding wall 67 disposed in the image height center region 101 may be formed to have the length Wy longer than the length Wy6 of the seventh inter-waveguide light-shielding wall 67C disposed in the image height end region 102.

### 20. 2-9th Embodiment

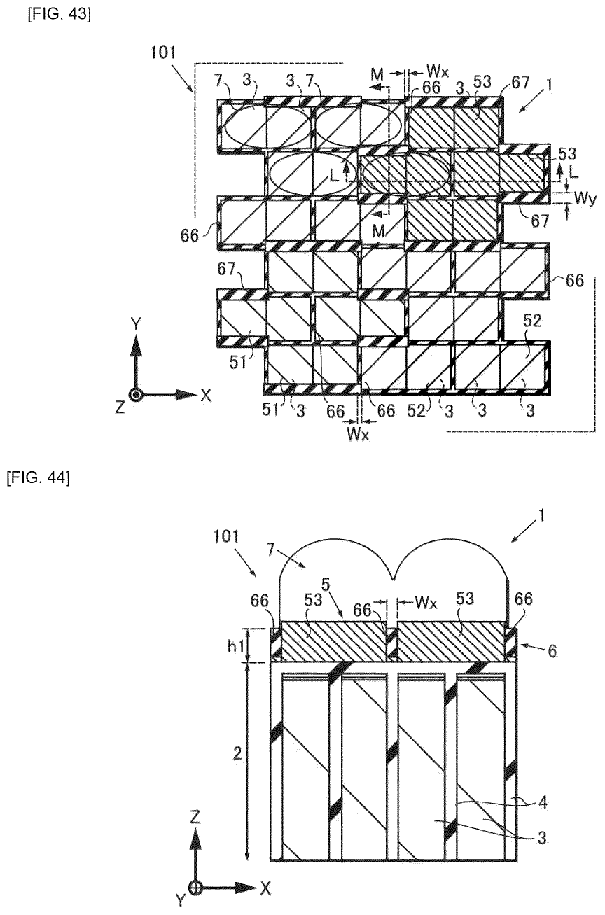

Description is given of the solid-state imaging device 1 according to the 2-9th embodiment of the present disclosure with reference to FIGS. 43 to 48.

### [Configuration of Solid-State Imaging Device 1]

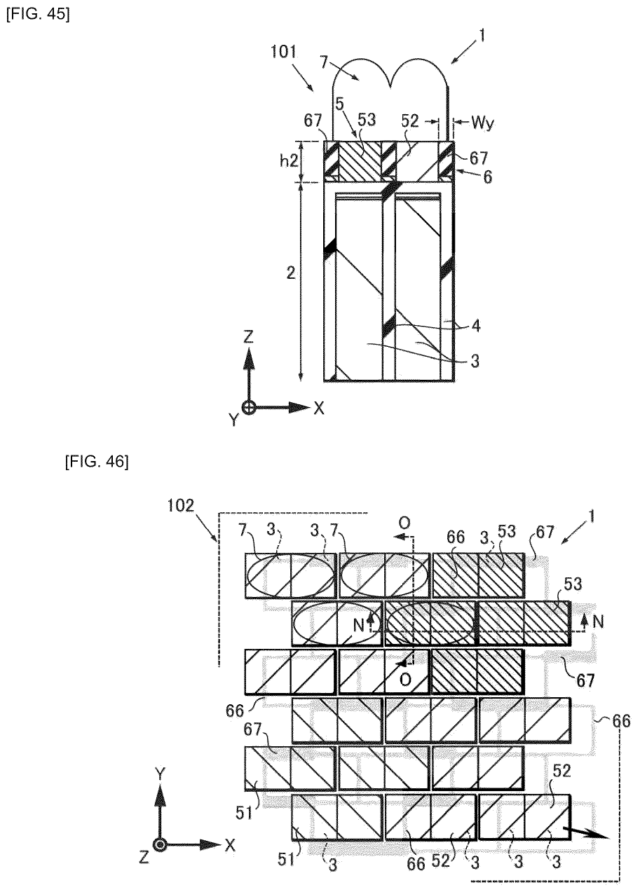

FIG. 43 illustrates an example of the arrangement configuration of the light-receiving pixels 3, and the arrangement configuration of the color filters 5 in the image height center region 101 of the effective pixel region 10 in the solid-state imaging device 1. FIG. 44 illustrates an example of a cross-sectional configuration of a main part of the image height center region 101 taken along a line L-L illustrated in FIG. 43. FIG. 45 illustrates an example of a cross-sectional configuration of a main part of the image height center region 101 taken along a line M-M illustrated in FIG. 43.

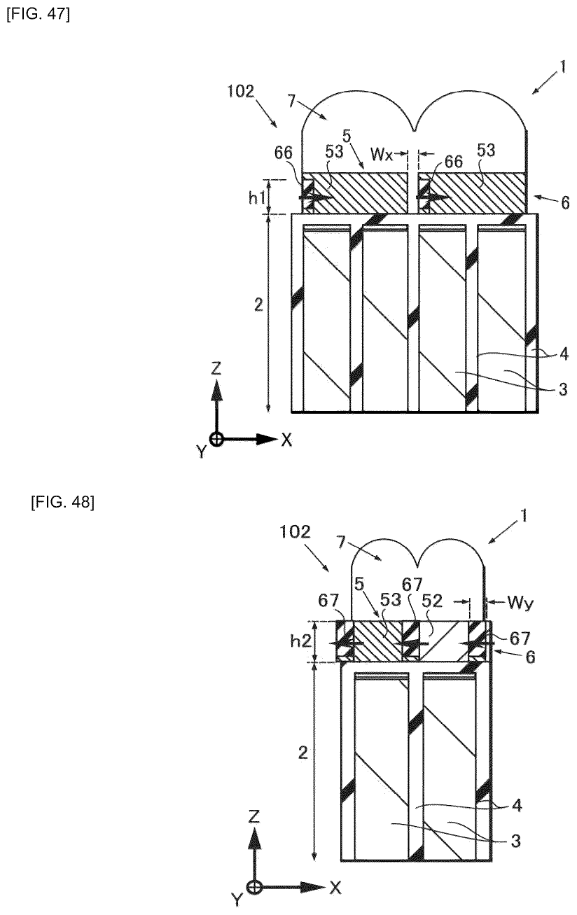

In addition, FIG. 46 illustrates an example of the arrangement configuration of the light-receiving pixels 3, and the arrangement configuration of the color filters 5 in the image height end region 102 of the effective pixel region 10 in the solid-state imaging device 1. FIG. 47 illustrates an example of a cross-sectional configuration of a main part of the image height end region 102 taken along a line N-N illustrated in FIG. 46. FIG. 48 illustrates an example of a cross-sectional configuration of a main part of the image height end region 102 taken along a line O-O illustrated in FIG. 46.

As illustrated in FIGS. 43 to 45, as with the solid-state imaging device 1 according to the 2-6th embodiment, the solid-state imaging device 1 includes the sixth inter-waveguide light-shielding wall 66 and the seventh inter-waveguide light-shielding wall 67 in the image height center region 101 of the effective pixel region 10.

Meanwhile, as illustrated in FIGS. 46 to 48, as with the image height center region 101, the sixth inter-waveguide light-shielding wall 66 and the seventh inter-waveguide light-shielding wall 67 are included in the image height end region 102 of the effective pixel region 10. In the image height end region 102, positions at which the sixth inter-waveguide light-shielding wall 66 and the seventh inter-waveguide light-shielding wall 67 are disposed are shifted by a pupil correction amount with respect to the light-receiving pixel 3 from the middle portion to the peripheral portion of the effective pixel region 10. Shift directions are the arrow-X direction and the arrow-Y direction.

In addition, in the image height end region 102, a position where the lens 7 is disposed is shifted with respect to a position where the lens 7 is disposed in the image height center region 101.

Components other than the above-described components are the same or substantially the same as the components of the solid-state imaging device 1 according to the 2-6th embodiment described above.

### Workings and Effects

In the solid-state imaging device 1 according to the 2-9th embodiment, it is possible to achieve workings and effects similar to the workings and effects achieved by the solid-state imaging device 1 according to the 2-6th embodiment.

### 21. 2-10th Embodiment

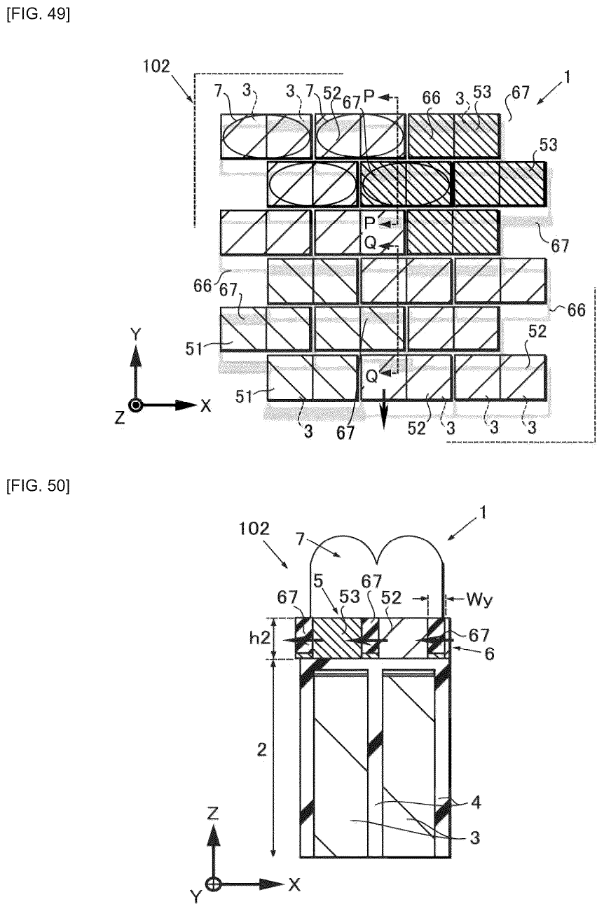

Description is given of the solid-state imaging device 1 according to the 2-10th embodiment of the present disclosure with reference to FIGS. 49 to 51. The 2-10th embodiment is an application example of the solid-state imaging device 1 according to the 2-9th embodiment.

### [Configuration of Solid-State Imaging Device 1]

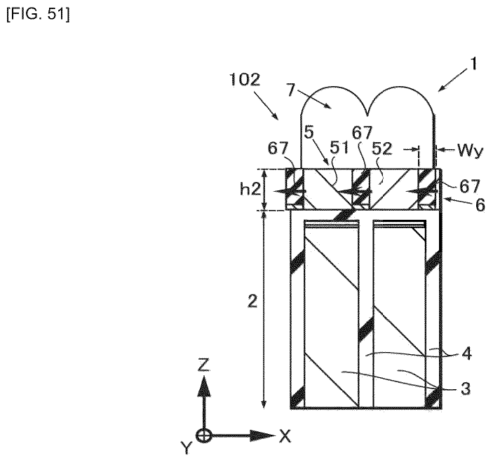

FIG. 49 illustrates an example of the arrangement configuration of the light-receiving pixels 3 and the arrangement configuration of the color filters 5 in the image height end region 102 of the effective pixel region 10 in the solid-state imaging device 1. FIG. 50 illustrates an example of a cross-sectional configuration of a main part of the image height end region 102 taken along a line P-P illustrated in FIG. 49. FIG. 51 illustrates an example of a cross-sectional configuration of a main part of the image height end region 102 taken along a line Q-Q illustrated in FIG. 49.

As illustrated in FIGS. 49 to 51, as with the solid-state imaging device 1 according to the 2-9th embodiment, the solid-state imaging device 1 includes the sixth inter-waveguide light-shielding wall 66 and the seventh inter-waveguide light-shielding wall 67 in the image height end region 102 of the effective pixel region 10. In the image height end region 102, the positions where the sixth inter-waveguide light-shielding wall 66 and the seventh inter-waveguide light-shielding wall 67 are disposed are shifted by a pupil correction amount with respect to the light-receiving pixel 3 from the middle portion to the peripheral portion of the effective pixel region 10.

Furthermore, the shift amount is adjusted in accordance with a refractive index difference between the color filters 5. The refractive index difference is as described in the solid-state imaging device 1 according to the 2-7th embodiment. That is, in the long wavelength range, refractive index differences between the third color filter 53 having red and the first color filter 51 having blue and between the third color filter 53 and the second color filter 52 having green become large. Conversely, a refractive index difference between the first color filter 51 and the second color filter 52 becomes small. Accordingly, the shift amounts of the sixth inter-waveguide light-shielding wall 66 and the seventh inter-waveguide light-shielding wall 67 that are disposed between the color filters 5 having a large refractive index difference are formed to be larger than the shift amounts of the sixth inter-waveguide light-shielding wall 66 and the seventh inter-waveguide light-shielding wall 67 that are disposed between the color filters 5 having a small refractive index difference.

Components other than the above-described components are the same or substantially the same as the components of the solid-state imaging device 1 according to the 2-9th embodiment described above.

### Workings and Effects

In the solid-state imaging device 1 according to the 2-10th embodiment, it is possible to achieve workings and effects similar to the workings and effects achieved by the solid-state imaging device 1 according to the 2-9th embodiment.

In addition, in the solid-state imaging device 1, the shift amounts are adjusted on the basis of pupil correction and a refractive index difference, which makes it possible to effectively reduce or prevent the leakage light r2 uniformly over the entire effective pixel region 10.

### 22. 3-1st Embodiment

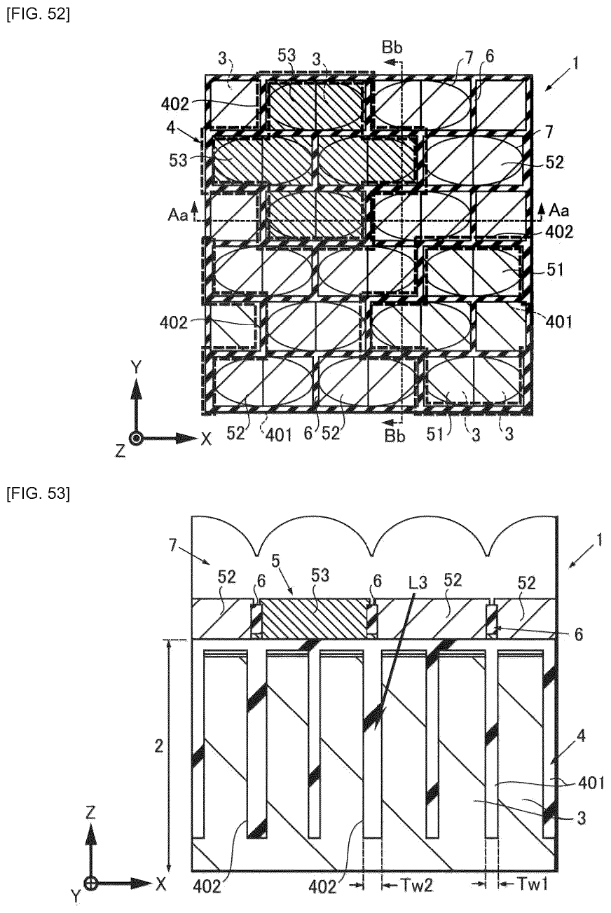

Description is given of the solid-state imaging device 1 according to the 3-1st embodiment of the present disclosure with reference to FIGS. 52 to 54. The 3-1st embodiment to the 3-7th embodiment are examples in which color mixture is effectively suppressed or prevented by the inter-pixel light-shielding wall 4 in place of the inter-waveguide light-shielding wall 6 in the solid-state imaging device 1 according to the 1-1st embodiment or the 2-1st embodiment.

### [Configuration of Solid-State Imaging Device 1]

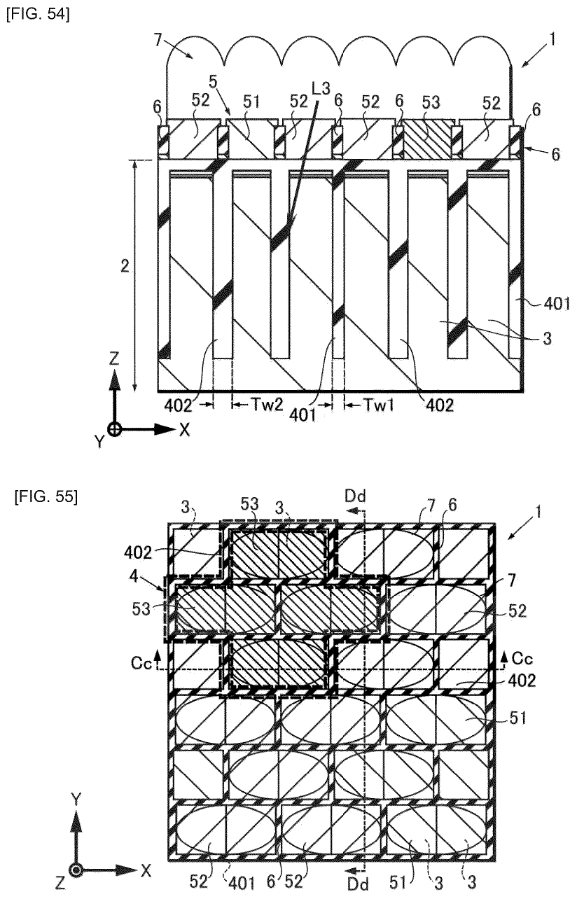

FIG. 52 illustrates an example of the arrangement configuration of the light-receiving pixels 3, the arrangement configuration of the color filters 5, and a layout configuration of the inter-pixel light-shielding walls 4 in the effective pixel region 10 in the solid-state imaging device 1. FIG. 53 illustrates an example of a cross-sectional configuration of a main part of the effective pixel region 10 taken along a line Aa-Aa illustrated in FIG. 52. FIG. 54 illustrates an example of a cross-sectional configuration of a main part of the effective pixel region 10 taken along a line Bb-Bb illustrated in FIG. 52.

As illustrated in FIGS. 52 to 54, as with the solid-state imaging device 1 according to the 1-1st embodiment or the 2-1st embodiment, the solid-state imaging device 1 includes the light-receiving pixels 3, the inter-pixel light-shielding walls 4, the color filters 5, the inter-waveguide light-shielding walls 6, and the lenses 7.

Furthermore, in the solid-state imaging device 1, the inter-pixel light-shielding walls 4 includes a first inter-pixel light-shielding wall 401 and a first inter-pixel light-shielding wall 402.

The first inter-pixel light-shielding wall 401 is disposed between the light-receiving pixels 3 corresponding to between the color filters 5 having the same color adjacent in the arrow-X direction or the arrow-Y direction. The first inter-pixel light-shielding wall 401 is disposed at a position coinciding with a position where the inter-waveguide light-shielding wall 6 is disposed in a plan view, and is disposed below the inter-waveguide light-shielding wall 6.

As with the inter-pixel light-shielding wall 4 (see FIG. 2) of the solid-state imaging device 1 according to the 1-1st embodiment, the first inter-pixel light-shielding wall 401 includes the groove 41, the inner-wall insulator 42, and the separation material 43. In the first inter-pixel light-shielding wall 401 disposed between the light-receiving pixels 3 arranged in the arrow-X direction, a width (a length in a width direction, the same applies hereinafter) Tw1 in the arrow-X direction of the groove 41 is, for example, greater than or equal to 80 nm and less than or equal to 120 nm. In addition, a depth of the groove 41 is, for example, greater than or equal to 2 μm and less than or equal to 5 μm. The width Tw1 in the arrow-Y direction of the groove 41 and the depth of the groove 41 in the first inter-pixel light-shielding wall 401 disposed between the light-receiving pixels 3 arranged in the arrow-Y direction are equal to the width Tw1 in the arrow-X direction and the depth.

Meanwhile, the first inter-pixel light-shielding wall 402 is disposed between the light-receiving pixels 3 corresponding to between the color filters 5 having different colors adjacent in the arrow-X direction or the arrow-Y direction.

Detailed description is given. The first inter-pixel light-shielding wall 402 is disposed at a position corresponding to between a pixel block including a total of eight light-receiving pixels 3 on which four first color filters 51 are disposed, and a pixel block including a total of ten light-receiving pixels 3 on which five second color filters 52 are disposed. In other words, the first inter-pixel light-shielding wall 402 is disposed at a position surrounding the pixel block including a total of eight light-receiving pixels 3 on which four first color filters 51 are disposed.

In addition, the first inter-pixel light-shielding wall 402 is disposed at a position corresponding to between a pixel block including a total of eight light-receiving pixels 8 on which four third color filters 53 are disposed and a pixel block including a total of ten light-receiving pixels 3 on which five second color filters 52 are disposed. In other words, the first inter-pixel light-shielding wall 402 is disposed at a position surrounding the pixel block including a total of eight light-receiving pixels 3 on which four third color filters 53 are disposed.

The first inter-pixel light-shielding wall 402 is disposed at a position coinciding with the position where the inter-waveguide light-shielding wall 6 is disposed in the arrow-Z direction, and is disposed below the inter-waveguide light-shielding wall 6.

As with the first inter-pixel light-shielding wall 401, the first inter-pixel light-shielding wall 402 includes the groove 41, the inner-wall insulator 42, and the separation material 43. In the first inter-pixel light-shielding wall 402 disposed between the light-receiving pixels 3 arranged in the arrow-X direction, a width Tw2 in the arrow-X direction of the groove 41 is, for example, greater than or equal to 130 nm and less than or equal to 170 nm. The width Tw2 of the groove 41 of the first inter-pixel light-shielding wall 402 is larger than the width Tw1 of the groove 41 of the first inter-pixel light-shielding wall 401; therefore, the first inter-pixel light-shielding wall 402 has a light-shielding property higher than a light-shielding property of the first inter-pixel light-shielding wall 401. In other words, the first inter-pixel light-shielding wall 402 has light transmittance lower than light transmittance of the first inter-pixel light-shielding wall 401.

In addition, the depth of the groove 41 is equal to the depth of the groove 41 of the first inter-pixel light-shielding wall 401. In the first inter-pixel light-shielding wall 402 disposed between the light-receiving pixels 3 arranged in the arrow-Y direction, the width Tw2 in the arrow-Y direction of the groove 41 and the depth of the groove 41 are equal to the width Tw2 in the arrow-X direction and the depth.

### Workings and Effects

As illustrated in FIGS. 52 to 54, the solid-state imaging device 1 according to the 3-1st embodiment includes the light-receiving pixels 3, the color filters 5, and the inter-pixel light-shielding walls 4.

A plurality of light-receiving pixels 3 is arranged in the arrow-X direction and the arrow-Y direction intersecting with the arrow-X direction. The color filters 5 are disposed on the respective light-receiving pixels 3.

The inter-pixel light-shielding walls 4 include the first inter-pixel light-shielding wall 401 and the first inter-pixel light-shielding wall 402. The first inter-pixel light-shielding wall 401 is disposed between the light-receiving pixels 3 corresponding to between the color filters 5 having the same color adjacent in the arrow-X direction or the arrow-Y direction, and has a light-shielding property. The first inter-pixel light-shielding wall 402 is disposed between the light-receiving pixels 3 corresponding to between the color filters 5 having different colors adjacent in the arrow-X direction or the arrow-Y direction, and has a light-shielding property higher than the light-shielding property of the first inter-pixel light-shielding wall 401.

Accordingly, as illustrated in FIG. 53, incident light L3 that passes through the lens 7 and the color filter 5 and enters the light-receiving pixel 3 is physically limited by the first inter-pixel light-shielding wall 402. That is, it is possible to effectively suppress or prevent entry of the incident light L3 into other light-receiving pixels 3 adjacent to the light-receiving pixel 3 where the incident light L3 has entered. This makes it possible to effectively suppress or prevent variations among the pixel outputs of the light-receiving pixels 3, to reduce or prevent a sensitivity difference between the color filters 5 having different colors, and to effectively suppress or prevent color mixture.

In addition, in the solid-state imaging device 1, as illustrated in FIGS. 52 to 54, the width (a length in the width direction) Tw2 in the arrow-X direction or the arrow-Y direction of the first inter-pixel light-shielding wall 402 is larger (longer) than the width (a length in the width direction) Tw1 in the arrow-X direction or the arrow-Y direction of the first inter-pixel light-shielding wall 401. Accordingly, it is possible to easily enhance the light-shielding property of the first inter-pixel light-shielding wall 402 by width adjustment, relative to the light-shielding property of the first inter-pixel light-shielding wall 401.

Furthermore, in the solid-state imaging device 1, as illustrated in FIGS. 52 to 54, the first inter-pixel light-shielding wall 401 and first inter-pixel light-shielding wall 402 each include the groove 41 formed along the light-receiving pixels 3 in the arrow-Z direction. The length (Tw2) of a groove width of the first inter-pixel light-shielding wall 402 is longer than the length (Tw1) of a groove width of the first inter-pixel light-shielding wall 401. Accordingly, it is possible to easily enhance the light-shielding property of the first inter-pixel light-shielding wall 402 by width adjustment, relative to the light-shielding property of the first inter-pixel light-shielding wall 401.

### 23. 3-2nd Embodiment

Description is given of the solid-state imaging device 1 according to the 3-2nd embodiment of the present disclosure with reference to FIGS. 55 to 57.

### [Configuration of Solid-State Imaging Device 1]

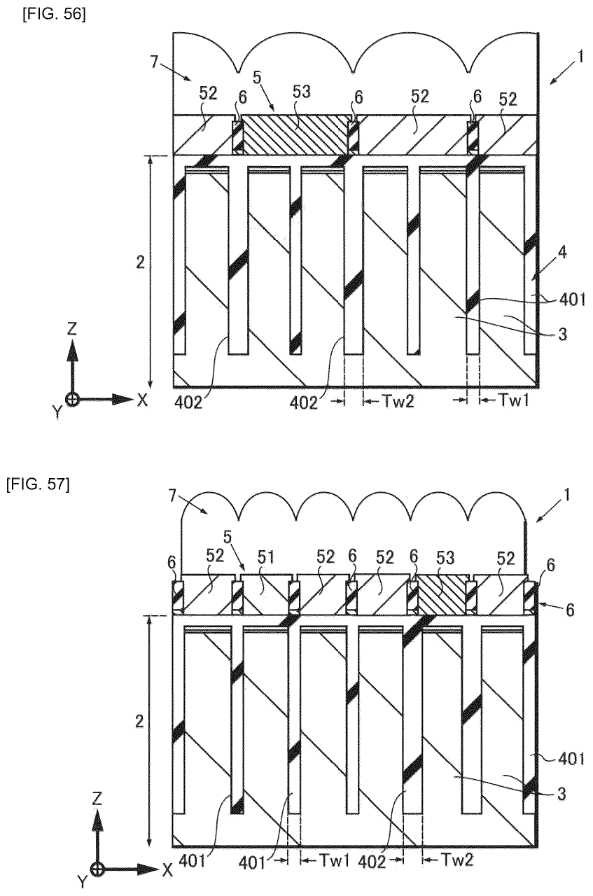

FIG. 55 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1. FIG. 56 illustrates an example of a cross-sectional configuration of a main part of the effective pixel region 10 taken along a line Cc-Cc illustrated in FIG. 55. FIG. 57 illustrates an example of a cross-sectional configuration of a main part of the effective pixel region 10 taken along a line Dd-Dd illustrated in FIG. 55.

As illustrated in FIGS. 55 to 57, as with the solid-state imaging device 1 according to the 3-1st embodiment, the solid-state imaging device 1 includes the first inter-pixel light-shielding wall 401 and the first inter-pixel light-shielding wall 402. As described in the solid-state imaging device 1 according to the 2-7th embodiment, the refractive index of the third color filter 53 having red is high in the long wavelength range, and a refractive index difference between the third color filter 53 and each of the first color filter 51 having blue and the second color filter 52 having green that are adjacent to the third color filter 53 becomes large.

Accordingly, in the solid-state imaging device 1, the first inter-pixel light-shielding wall 402 is disposed at a position surrounding the third color filter 53. Here, the first inter-pixel light-shielding wall 402 is disposed at a position surrounding a pixel block including a total of eight light-receiving pixels 3 on which four third color filters 53 are disposed.

Components other than the above-described components are the same or substantially the same as the components of the solid-state imaging device 1 according to the 3-1st embodiment described above.

### Workings and Effects

In the solid-state imaging device 1 according to the 3-2nd embodiment, it is possible to achieve workings and effects similar to the workings and effects achieved by the solid-state imaging device 1 according to the 3-1st embodiment.

In addition, in the solid-state imaging device 1, as illustrated in FIGS. 55 to 57, the first inter-pixel light-shielding wall 402 is disposed between the light-receiving pixels 3 adjacent in the arrow-X direction and the arrow-Y direction at a position surrounding the third color filter 53.

Accordingly, the first inter-pixel light-shielding wall 402 is disposed between the light-receiving pixels 3 corresponding to a position between the color filters 5 having different colors and having a refractive index that increases specifically in the long wavelength range, which makes it possible to effectively suppress or prevent variations among the pixel outputs of the light-receiving pixels 3. As a result, it is possible to effectively suppress or prevent color mixture.

### 24. 3-3rd Embodiment

Description is given of the solid-state imaging device 1 according to the 3-3rd embodiment of the present disclosure with reference to FIGS. 58 to 60.

### [Configuration of Solid-State Imaging Device 1]

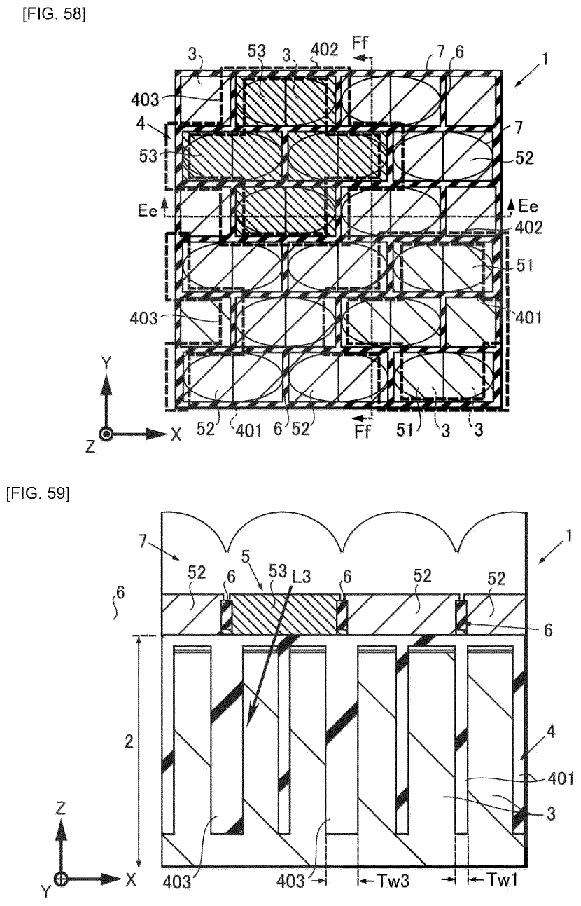

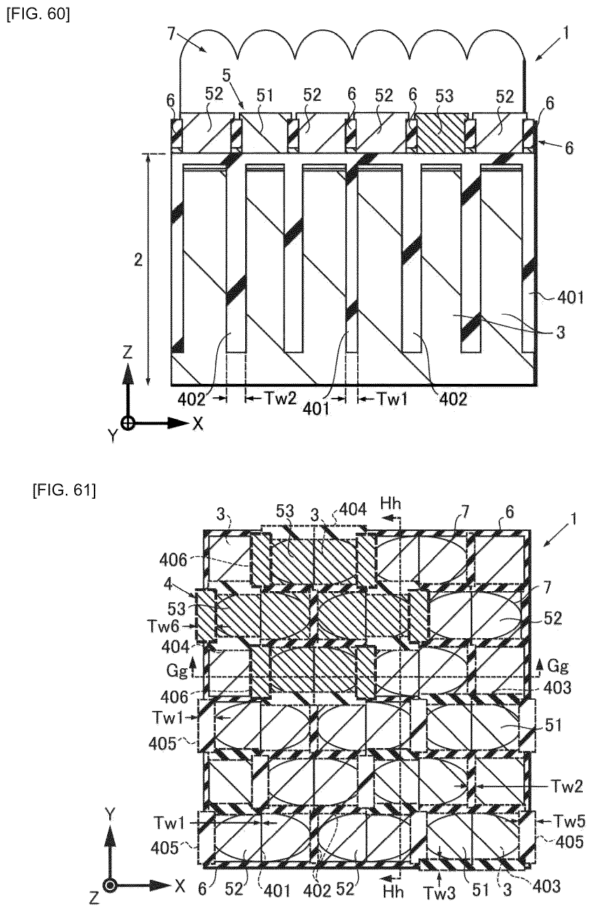

FIG. 58 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1. FIG. 59 illustrates an example of a cross-sectional configuration of a main part of the effective pixel region 10 taken along a line Ee-Ee illustrated in FIG. 58. FIG. 60 illustrates an example of a cross-sectional configuration of a main part of the effective pixel region 10 taken along a line Ff-Ff illustrated in FIG.

As illustrated in FIGS. 58 to 60, as with the solid-state imaging device 1 according to the 3-1st embodiment, the solid-state imaging device 1 includes the first inter-pixel light-shielding wall 401 and the first inter-pixel light-shielding wall 402, and further includes a third inter-pixel light-shielding wall 403.

As described in the solid-state imaging device 1 according to the 1-1st embodiment, color mixture pronouncedly occurs between the color filters 5 having different colors adjacent in the arrow-X direction. Accordingly, in place of the first inter-pixel light-shielding wall 402, the third inter-pixel light-shielding wall 403 is disposed at each of positions corresponding to between the first color filter 51 and the second color filter 52 having different colors adjacent in the arrow-X direction and between the second color filter 52 and the third color filter 53 having different colors adjacent in the arrow-X direction.

A basic configuration of the third inter-pixel light-shielding wall 403 is the same as the configuration of each of the first inter-pixel light-shielding wall 401 and the first inter-pixel light-shielding wall 402. A width Tw3 of the groove 41 of the third inter-pixel light-shielding wall 403 is larger than the width Tw2 of the groove 41 of the first inter-pixel light-shielding wall 402. The width Tw3 is, for example, greater than or equal to 180 nm and less than or equal to 220 nm.

Components other than the above-described components are the same or substantially the same as the components of the solid-state imaging device 1 according to the 3-1st embodiment described above.

### Workings and Effects

In the solid-state imaging device 1 according to the 3-3rd embodiment, it is possible to achieve workings and effects similar to the workings and effects achieved by the solid-state imaging device 1 according to the 3-1st embodiment.

In addition, in the solid-state imaging device 1, as illustrated in FIGS. 58 to 60, the third inter-pixel light-shielding wall 403 is disposed between the light-receiving pixels 3 at a position corresponding to between the color filters 5 having different colors adjacent in the arrow-X direction. The width Tw3 of the third inter-pixel light-shielding wall 403 is larger than the width Tw2 of the first inter-pixel light-shielding wall 402.

Accordingly, the first inter-pixel light-shielding wall 402 is disposed between the light-receiving pixels 3 corresponding to a position where color mixture pronouncedly easily occurs, which makes it possible to effectively suppress or prevent variations among the pixel outputs of the light-receiving pixels 3. As a result, it is possible to effectively suppress or prevent color mixture.

It is to be noted that as described in the solid-state imaging device 1 according to the 2-1st embodiment, for color mixture by the aspect ratio of the lens 7, the third inter-pixel light-shielding wall 403 is disposed between the light-receiving pixels 3 at a position corresponding to between the color filters 5 having different colors adjacent in the arrow-Y direction.

### 25. 3-4th Embodiment

Description is given of the solid-state imaging device 1 according to the 3-4th embodiment of the present disclosure with reference to FIGS. 61 to 63.

### [Configuration of Solid-State Imaging Device 1]

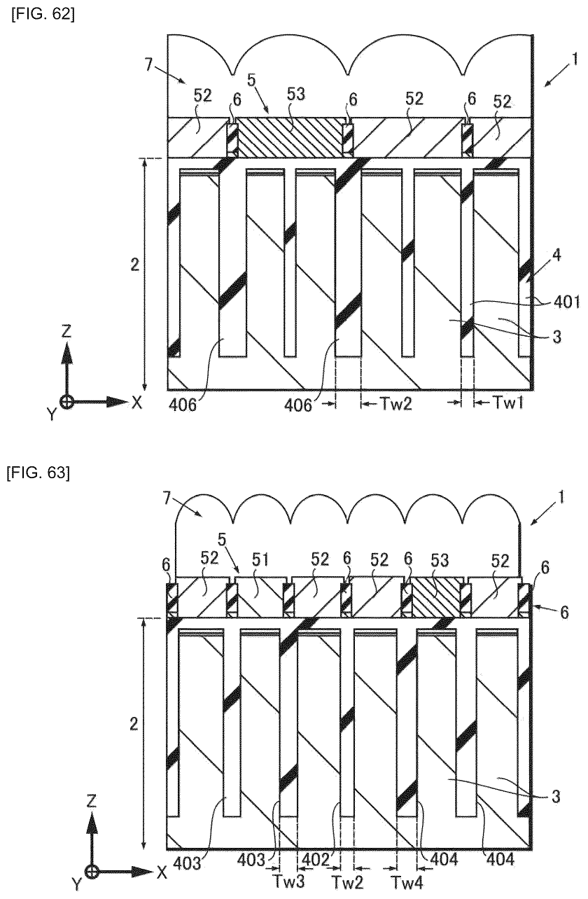

FIG. 61 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1. FIG. 62 illustrates an example of a cross-sectional configuration of a main part of the effective pixel region 10 taken along a line Gg-Gg illustrated in FIG. 61. FIG. 63 illustrates an example of a cross-sectional configuration of a main part of the effective pixel region 10 taken along a line Hh-Hh illustrated in FIG. 61.

As illustrated in FIGS. 61 to 63, the solid-state imaging device 1 includes the first inter-pixel light-shielding wall 401 to a sixth inter-pixel light-shielding wall 406. Each of the first inter-pixel light-shielding wall 401 to the sixth inter-pixel light-shielding wall 406 is disposed from a position corresponding to between the light-receiving pixels 3 where color mixture is hard to occur to a position corresponding to between the light-receiving pixels 3 where color mixture easily occurs.

Detailed description is given. The first inter-pixel light-shielding wall 401 is disposed between the light-receiving pixels 3, on which the first color filters 51 are disposed, adjacent in the arrow-X direction. The groove 41 of the first inter-pixel light-shielding wall 401 has the width Tw1.

The first inter-pixel light-shielding wall 402 is disposed between the light-receiving pixels 3 at a position corresponding to between the color filters 5 having the same color adjacent in the arrow-X direction or the arrow-Y direction. The groove 41 of the first inter-pixel light-shielding wall 402 has the width Tw2. The width Tw2 is larger than the width Tw1.

The third inter-pixel light-shielding wall 403 is disposed between the light-receiving pixels 3 at a position corresponding to between the first color filter 51 and the second color filter 52 having different colors adjacent in the arrow-Y direction. The groove 41 of the third inter-pixel light-shielding wall 403 has the width Tw3. The width Tw3 is larger than the width Tw2.

The fourth inter-pixel light-shielding wall 404 is disposed between the light-receiving pixels 3 at a position corresponding to between the second color filter 52 and the third color filter 53 having different colors adjacent in the arrow-Y direction. The groove 41 of the fourth inter-pixel light-shielding wall 404 has a width Tw4. The width Tw4 is larger than the width Tw3.

The fifth inter-pixel light-shielding wall 405 is disposed between the light-receiving pixels 3 at a position corresponding to between the first color filter 51 and the second color filter 52 having different colors adjacent in the arrow-X direction. The groove 41 of the fifth inter-pixel light-shielding wall 405 has a width Tw5. The width Tw5 is larger than the width Tw4.

Furthermore, the sixth inter-pixel light-shielding wall 406 is disposed between the light-receiving pixels 3 at a position corresponding to between the second color filter 52 and the third color filter 53 having different colors adjacent in the arrow-X direction. The groove 41 of the sixth inter-pixel light-shielding wall 406 has a width Tw6. The width Tw6 is larger than the width Tw5.

Components other than the above-described components are the same or substantially the same as the components of the solid-state imaging device 1 according to the 3-1st embodiment described above.

### Workings and Effects

In the solid-state imaging device 1 according to the 3-4th embodiment, it is possible to achieve workings and effects similar to the workings and effects achieved by the solid-state imaging device 1 according to the 3-1st embodiment.

In addition, in the solid-state imaging device 1, as illustrated in FIGS. 61 to 63, each of the first inter-pixel light-shielding wall 401 to the sixth inter-pixel light-shielding wall 406 is disposed from a position corresponding to between the light-receiving pixels 3 where color mixture is hard to occur to a position corresponding to between the light-receiving pixels 3 where color mixture easily occurs.

Accordingly, the inter-pixel light-shielding wall 4 is disposed in accordance with the degree of color mixture, which makes it possible to more effectively suppress or prevent variations among the pixel outputs of the light-receiving pixels 3. As a result, it is possible to effectively suppress or prevent color mixture.

### 26. 3-5th Embodiment

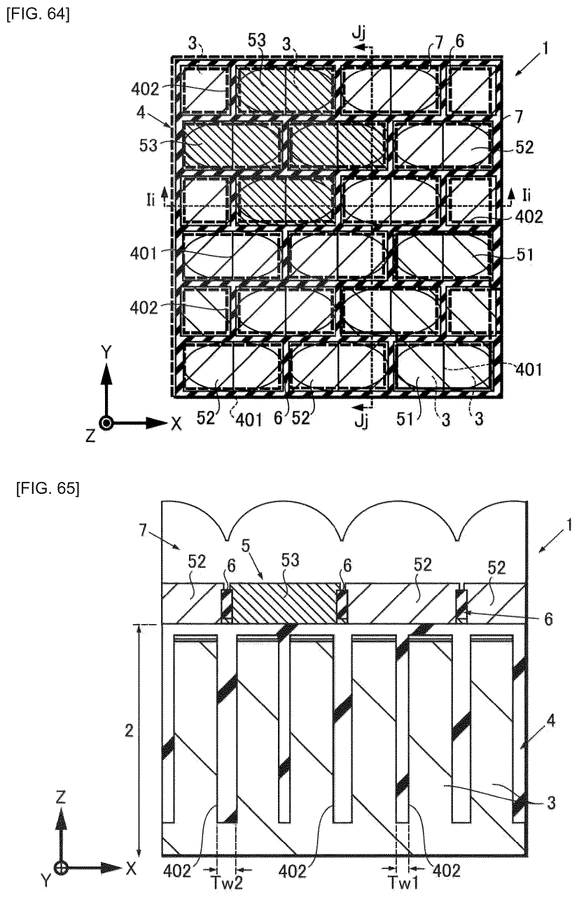

Description is given of the solid-state imaging device 1 according to the 3-5th embodiment of the present disclosure with reference to FIGS. 64 to 66.

### [Configuration of Solid-State Imaging Device 1]

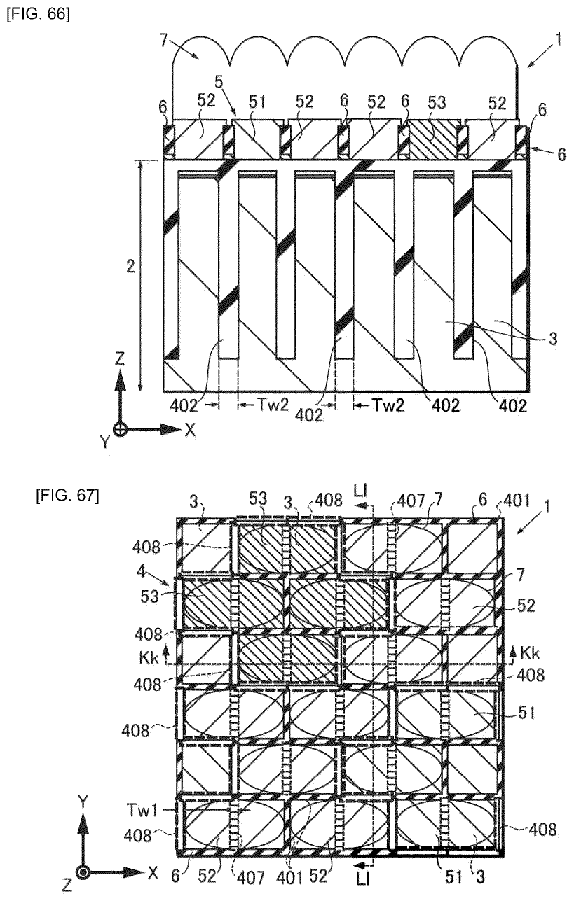

FIG. 64 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1. FIG. 65 illustrates an example of a cross-sectional configuration of a main part of the effective pixel region 10 taken along a line Ii-Ii illustrated in FIG. 64. FIG. 66 illustrates an example of a cross-sectional configuration of a main part of the effective pixel region 10 taken along a line Jj-Jj illustrated in FIG. 64.

As illustrated in FIGS. 64 to 66, as with the solid-state imaging device 1 according to the 3-1st embodiment, in the solid-state imaging device 1, the inter-pixel light-shielding walls 4 include the first inter-pixel light-shielding wall 401 and the first inter-pixel light-shielding wall 402.

The first inter-pixel light-shielding wall 401 is disposed between the light-receiving pixels 3, on which the color filters 5 are disposed, adjacent in the arrow-X direction. The groove 41 of the first inter-pixel light-shielding wall 401 has the width Tw1.

The first inter-pixel light-shielding wall 402 is disposed between the light-receiving pixels 3 at a position corresponding to between the color filters 5 having the same color or different colors adjacent in the arrow-X direction or the arrow-Y direction. That is, the first inter-pixel light-shielding wall 402 is disposed between the light-receiving pixels 3 corresponding to a position surrounding the color filter 5 for each color filter 5 irrespective of having the same color or a different color. The groove 41 of the first inter-pixel light-shielding wall 402 has the width Tw2. The width Tw2 is larger than the width Tw1.

Components other than the above-described components are the same or substantially the same as the components of the solid-state imaging device 1 according to the 3-1st embodiment described above.

### Workings and Effects

In the solid-state imaging device 1 according to the 3-5th embodiment, it is possible to achieve workings and effects similar to the workings and effects achieved by the solid-state imaging device 1 according to the 3-1st embodiment.

In addition, in the solid-state imaging device 1, as illustrated in FIGS. 64 to 66, the first inter-pixel light-shielding wall 402 is disposed between the light-receiving pixels 3 corresponding to a position surrounding the color filter 5 irrespective of having the same color or a different color. The widths Tw2 of the first inter-pixel light-shielding walls 402 are all the same.

Accordingly, it is not necessary to adjust the width of the groove 41 for each position, which makes it possible to simply configure the first inter-pixel light-shielding wall 402, and makes it possible to simplify the configuration of the solid-state imaging device 1.

### 27. 3-6th Embodiment

Description is given of the solid-state imaging device 1 according to the 3-6th embodiment of the present disclosure with reference to FIGS. 67 to 69.

### [Configuration of Solid-State Imaging Device 1]

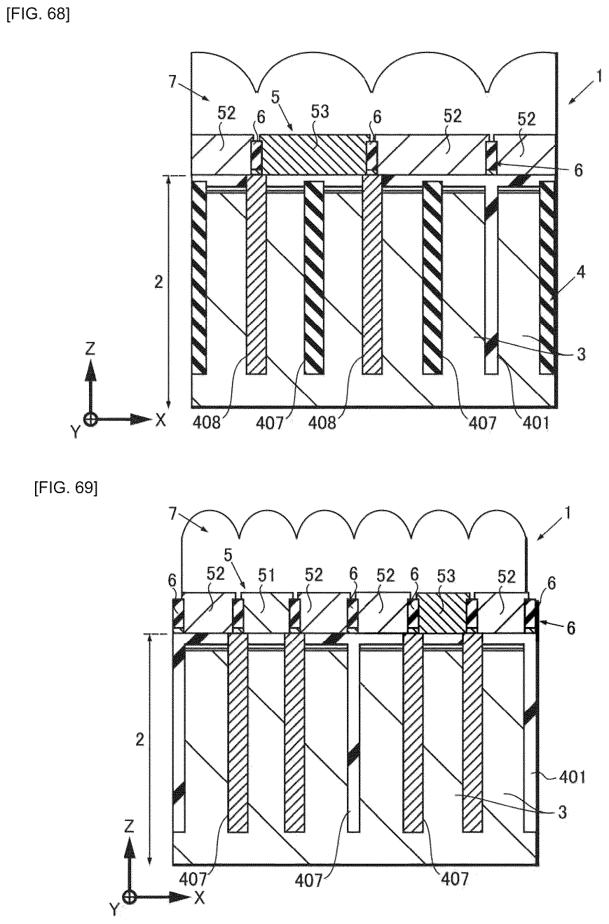

FIG. 67 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1. FIG. 68 illustrates an example of a cross-sectional configuration of a main part of the effective pixel region 10 taken along a line Kk-Kk illustrated in FIG. 67. FIG. 69 illustrates an example of a cross-sectional configuration of a main part of the effective pixel region 10 taken along a line Ll-Ll illustrated in FIG. 67.

As illustrated in FIGS. 67 to 69, as with the solid-state imaging device 1 according to the 3-1st embodiment, the solid-state imaging device 1 includes the inter-pixel light-shielding walls 4. The inter-pixel light-shielding walls 4 include the first inter-pixel light-shielding wall 401, a first inter-pixel light-shielding wall 407, and a second inter-pixel light-shielding wall 408.

The first inter-pixel light-shielding wall 401 is disposed between the light-receiving pixels 3 corresponding to a position between the color filters 5 having the same color adjacent in the arrow-X direction or the arrow-Y direction. The first inter-pixel light-shielding wall 401 has the same configuration as that of the inter-pixel light-shielding wall 4 of the solid-state imaging device 1 according to the 1-1st embodiment. The groove 41 of the first inter-pixel light-shielding wall 401 has the width Tw1.

In addition, the first inter-pixel light-shielding wall 407 is disposed between the light-receiving pixels 3, on which the color filters 5 are disposed, adjacent in the arrow-X direction. As with the inter-pixel light-shielding wall 4 of the solid-state imaging device 1 according to the 1-1st embodiment, the first inter-pixel light-shielding wall 407 includes the groove 41, the inner-wall insulator 42, and the separation material 43.

Here, for the separation material (a first separation material in the present technology) 43 of the first inter-pixel light-shielding wall 407, a high refractive index material having a high refractive index is used. The high refractive index material is a material that does not absorb light and has a refractive index close to that of Si. For example, as the high refractive index material, it is possible to practically use titanium oxide (TiO), silicon nitride (SiN), indium tin oxide (ITO), or the like.

The groove 41 of the first inter-pixel light-shielding wall 407 has a width Tw7. The width Tw7 is larger than the width Tw1.

The second inter-pixel light-shielding wall 408 is disposed between the light-receiving pixels 3 corresponding to a position between the color filters 5 having different colors adjacent in the arrow-X direction or the arrow-Y direction. As with the inter-pixel light-shielding wall 4 of the solid-state imaging device 1 according to the 1-1st embodiment, the second inter-pixel light-shielding wall 408 includes the groove 41, the inner-wall insulator 42, and the separation material 43.

Here, for the separation material (a second separation material in the present technology) 43 of the second inter-pixel light-shielding wall 408, a low refractive index material is used that has a lower refractive index than that of the separation material 43 of the first inter-pixel light-shielding wall 407. The low refractive index material effectively suppresses light transmission to the adjacent light-receiving pixels 3 and enhances a light-shielding property. As the low refractive index material, it is possible to practically use air or a material having a refractive index close to that of air.

For the separation material 43 of the second inter-pixel light-shielding wall 408, it is possible to use an absorbent having light absorptance lower than that of the separation material 43 of the first inter-pixel light-shielding wall 407. As the absorbent, it is possible to practically use, for example, polycrystalline silicon (poly-Si).

The groove 41 of the second inter-pixel light-shielding wall 408 has a width Tw8. The width Tw8 is larger than the width Tw7.

Components other than the above-described components are the same or substantially the same as the components of the solid-state imaging device 1 according to the 3-1st embodiment described above.

### Workings and Effects

In the solid-state imaging device 1 according to the 3-6th embodiment, it is possible to achieve workings and effects similar to the workings and effects achieved by the solid-state imaging device 1 according to the 3-1st embodiment.

In addition, as illustrated in FIGS. 67 to 69, the solid-state imaging device 1 includes the first inter-pixel light-shielding wall 407 and the second inter-pixel light-shielding wall 408.

The first inter-pixel light-shielding wall 407 is formed including the separation material (the first separation material) 43. This separation material is embedded in the groove 41 of the first inter-pixel light-shielding wall 407.

The second inter-pixel light-shielding wall 408 is formed including the separation material (the second separation material) 43 having a refractive index higher than or light absorptance lower than that of the separation material 43 of the first inter-pixel light-shielding wall 407. This separation material is embedded in the groove 41 of the second inter-pixel light-shielding wall 408.

Accordingly, in the solid-state imaging device 1, it is possible to effectively suppress or prevent color mixture while securing the pixel outputs of the light-receiving pixels 3.

### 28. 3-7th Embodiment

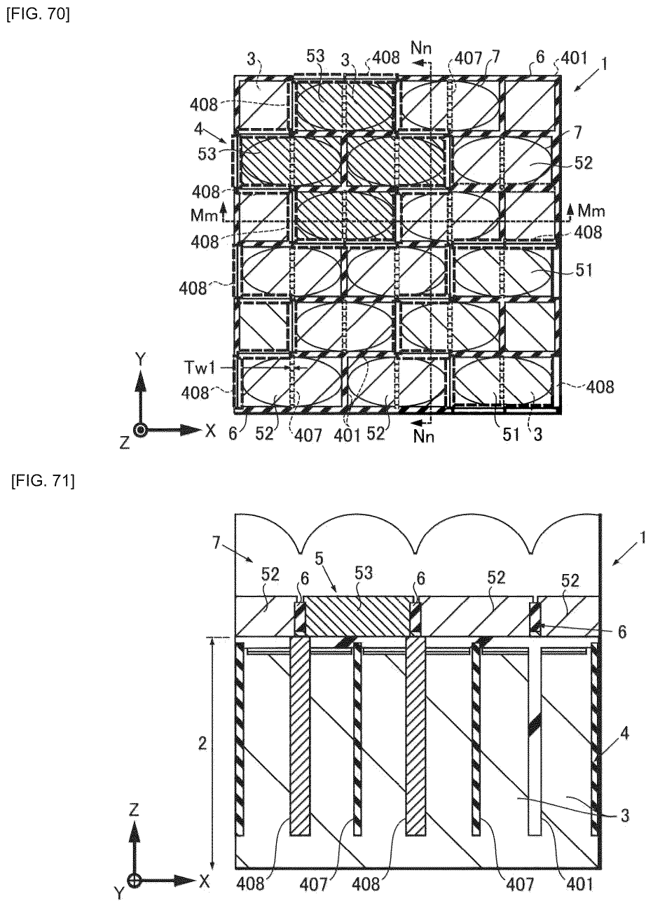

Description is given of the solid-state imaging device 1 according to the 3-7th embodiment of the present disclosure with reference to FIGS. 70 to 72.

### [Configuration of Solid-State Imaging Device 1]

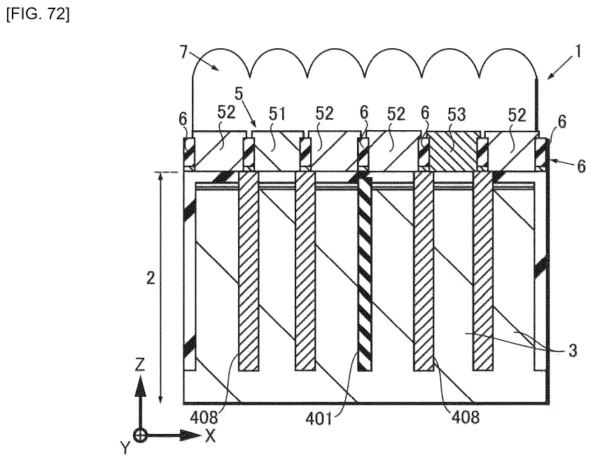

FIG. 70 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1. FIG. 71 illustrates an example of a cross-sectional configuration of a main part of the effective pixel region 10 taken along a line Mm-Mm illustrated in FIG. 70. FIG. 72 illustrates an example of a cross-sectional configuration of a main part of the effective pixel region 10 taken along a line Nn-Nn illustrated in FIG. 70.

As illustrated in FIGS. 70 to 72, as with the solid-state imaging device 1 according to the 3-6th embodiment, the solid-state imaging device 1 includes the inter-pixel light-shielding walls 4. The inter-pixel light-shielding walls 4 include the first inter-pixel light-shielding wall 401, the first inter-pixel light-shielding wall 407, and the second inter-pixel light-shielding wall 408.

The first inter-pixel light-shielding wall 401 is disposed between the light-receiving pixels 3 corresponding to a position between the color filters 5 having the same color adjacent in the arrow-X direction or the arrow-Y direction. In the first inter-pixel light-shielding wall 401, the low refractive index material or the high refractive index material described in the solid-state imaging device 1 according to the 3-6th embodiment is used for the separation material 43 of the first inter-pixel light-shielding wall 401. The groove 41 of the first inter-pixel light-shielding wall 401 has the width Tw1.

In addition, the first inter-pixel light-shielding wall 407 is disposed between the light-receiving pixels 3, on which the color filters 5 are disposed, adjacent in the arrow-X direction. For the separation material 43 of the first inter-pixel light-shielding wall 407, a high refractive index material is used.

The groove 41 of the first inter-pixel light-shielding wall 407 has the width Tw7. The width Tw7 is smaller than the width Tw1.

The second inter-pixel light-shielding wall 408 is disposed between the light-receiving pixels 3 corresponding to a position between the color filters 5 having different colors adjacent in the arrow-X direction or the arrow-Y direction. For the separation material 43 of the second inter-pixel light-shielding wall 408, a high refractive index material or an absorbent is used.

The groove 41 of the second inter-pixel light-shielding wall 408 has the width Tw8. The width Tw8 is larger than the width Tw1.

Components other than the above-described components are the same or substantially the same as the components of the solid-state imaging device 1 according to the 3-6th embodiment described above.

### Workings and Effects

In the solid-state imaging device 1 according to the 3-7th embodiment, it is possible to achieve workings and effects similar to the workings and effects achieved by the solid-state imaging device 1 according to the 3-6th embodiment.

### 29. 3-8th Embodiment

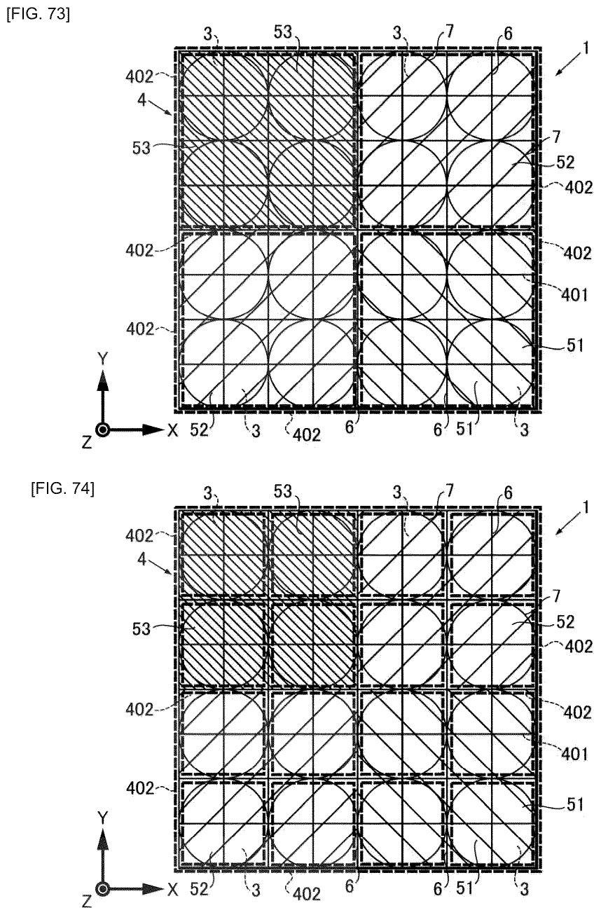

Description is given of the solid-state imaging device 1 according to the 3-8th embodiment of the present disclosure with reference to FIG. 73. The 3-8th embodiment to the 3-13th embodiment are examples in which the arrangement configuration of the light-receiving pixels 3, the arrangement configuration of the color filters 5, and the configuration of the lens 7 in the solid-state imaging device 1 according to the 3-1st embodiment are changed.

### [Configuration of Solid-state Imaging Device 1]

FIG. 73 illustrates an example of the arrangement configuration of the light-receiving pixels 3, the arrangement configuration of the color filters 5, the configuration of the lens 7, and the layout configuration of the inter-pixel light-shielding walls 4 in the effective pixel region 10 in the solid-state imaging device 1.

As illustrated in FIG. 73, in the solid-state imaging device 1, a pixel block is constructed that includes a total of sixteen light-receiving pixels 3 including four light-receiving pixels 3 arranged in the arrow-X direction and four light-receiving pixels 3 arranged in the arrow-Y direction. The color filters 5 are disposed on the light-receiving pixels 3 of this pixel block, and the lenses 7 are disposed on the color filters 5. One lens 7 is disposed for every four light-receiving pixels 3 adjacent in the arrow-X direction and the arrow-Y direction. That is, in one pixel block, a total of four lenses 7 are disposed, two in the arrow-X direction and two in the arrow-Y direction. Furthermore, the pixel blocks are arranged in the arrow-X direction and the arrow-Y direction.

In the solid-state imaging device 1 configured in such a manner, as with the solid-state imaging device 1 according to the 3-1st embodiment, the inter-pixel light-shielding walls 4 include the first inter-pixel light-shielding wall 401 and the first inter-pixel light-shielding wall 402.

The first inter-pixel light-shielding wall 401 is disposed between the light-receiving pixels 3 adjacent in the arrow-X direction and the arrow-Y direction in the pixel block. The groove 41 of the first inter-pixel light-shielding wall 401 has the width Tw1.

The first inter-pixel light-shielding wall 402 is disposed between the light-receiving pixels 3 corresponding to a position between the color filters 5 having different colors adjacent in the arrow-X direction and the arrow-Y direction. The groove 41 of the first inter-pixel light-shielding wall 402 has the width Tw2. The width Tw2 is larger than the width Tw1.

Components other than the above-described components are the same or substantially the same as the components of the solid-state imaging device 1 according to the 3-1st embodiment described above.

### Workings and Effects

In the solid-state imaging device 1 according to the 3-8th embodiment, it is possible to achieve workings and effects similar to the workings and effects achieved by the solid-state imaging device 1 according to the 3-1st embodiment.

### 30. 3-9th Embodiment

Description is given of the solid-state imaging device 1 according to the 3-9th embodiment of the present disclosure with reference to FIG. 74.

### [Configuration of Solid-State Imaging Device 1]

FIG. 74 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1.

As illustrated in FIG. 74, in the solid-state imaging device 1, the second inter-pixel light-shielding wall 402 is disposed for every four light-receiving pixels 3 in the same pixel block in the solid-state imaging device 1 according to the 3-8th embodiment. In other words, the second inter-pixel light-shielding wall 402 is disposed for every four light-receiving pixels 3 on which one lens 7 is disposed to surround the four light-receiving pixels 3.

Components other than the above-described components are the same or substantially the same as the components of the solid-state imaging device 1 according to the 3-8th embodiment described above.

### Workings and Effects

In the solid-state imaging device 1 according to the 3-9th embodiment, it is possible to achieve workings and effects similar to the workings and effects achieved by the solid-state imaging device 1 according to the 3-8th embodiment.

### 31. 3-10th Embodiment

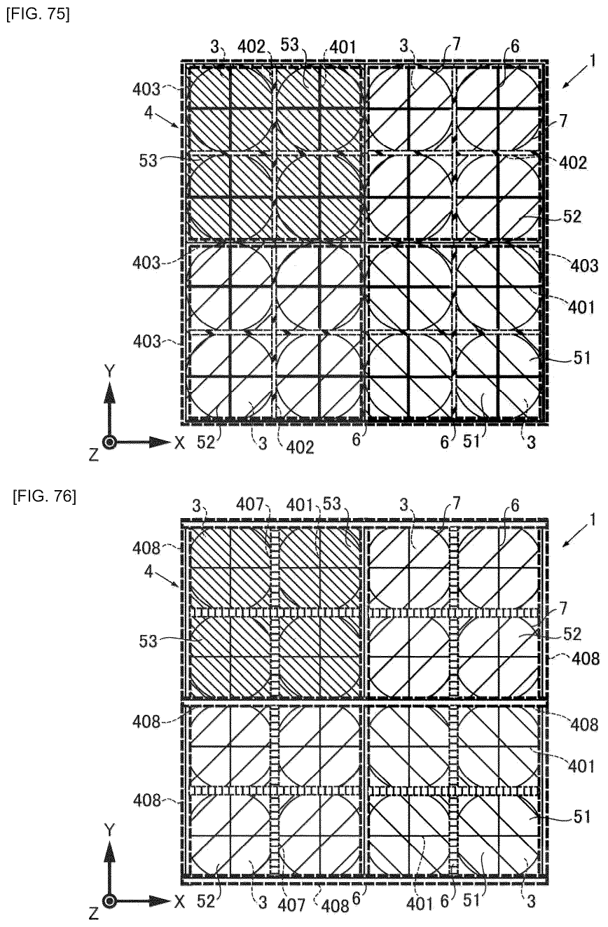

Description is given of the solid-state imaging device 1 according to the 3-10th embodiment of the present disclosure with reference to FIG. 75.

### [Configuration of Solid-State Imaging Device 1]

FIG. 75 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1.

As illustrated in FIG. 75, as with the solid-state imaging device 1 according to the 3-3rd embodiment, the solid-state imaging device 1 includes the first inter-pixel light-shielding wall 401 and the first inter-pixel light-shielding wall 402, and further includes the third inter-pixel light-shielding wall 403.

The first inter-pixel light-shielding wall 401 is disposed between four light-receiving pixels 3 adjacent in the arrow-X direction and the arrow-Y direction in the pixel block. In other words, the first inter-pixel light-shielding wall 401 is disposed between four light-receiving pixels 3 on which one lens 7 is disposed. The groove 41 of the first inter-pixel light-shielding wall 401 has the width Tw1.

The first inter-pixel light-shielding wall 402 is disposed each between four light-receiving pixels 3 and other four light-receiving pixels 3 adjacent in the arrow-X direction, and between four light-receiving pixels 3 and other four light-receiving pixels 3 adjacent in the arrow-Y direction in the pixel block. In other words, the first inter-pixel light-shielding wall 402 is disposed to surround the four light-receiving pixels on which one lens is disposed. The groove 41 of the first inter-pixel light-shielding wall 402 has the width Tw2. The width Tw2 is larger than the width Tw1.

The third inter-pixel light-shielding wall 403 is disposed between the light-receiving pixels 3 corresponding to a position between the pixel blocks on which the color filters 5 having different colors are disposed. In other words, the third inter-pixel light-shielding wall 403 is disposed to surround the pixel block. The groove 41 of the third inter-pixel light-shielding wall 403 has the width Tw3. The width Tw3 is larger than the width Tw2.

Components other than the above-described components are the same or substantially the same as the components of the solid-state imaging device 1 according to the 3-9th embodiment described above.

### Workings and Effects

In the solid-state imaging device 1 according to the 3-10th embodiment, it is possible to achieve workings and effects similar to the workings and effects achieved by the solid-state imaging device 1 according to the 3-9th embodiment.

### 32 3-11th Embodiment

Description is given of the solid-state imaging device 1 according to the 3-11th embodiment of the present disclosure with reference to FIG. 76.

### [Configuration of Solid-State Imaging Device 1]

FIG. 76 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1.

As illustrated in FIG. 76, as with the solid-state imaging device 1 according to the 3-6th embodiment, the solid-state imaging device 1 includes the inter-pixel light-shielding walls 4. The inter-pixel light-shielding walls 4 include the first inter-pixel light-shielding wall 401, the first inter-pixel light-shielding wall 407, and the second inter-pixel light-shielding wall 408.

The first inter-pixel light-shielding wall 401 is disposed each between four light-receiving pixels 3 and other four light-receiving pixels 3 adjacent in the arrow-X direction, and between four light-receiving pixels 3 and other four light-receiving pixels 3 adjacent in the arrow-Y direction in the pixel block. In other words, the first inter-pixel light-shielding wall 401 is disposed to surround four light-receiving pixels 3 on which one lens 7 is disposed.

The first inter-pixel light-shielding wall 407 is disposed between four light-receiving pixels 3 adjacent in the arrow-X direction and the arrow-Y direction in the pixel block. In other words, the first inter-pixel light-shielding wall 407 is disposed between four light-receiving pixels 3 on which one lens 7 is disposed. A high refractive index material is used for the separation material 43 of the first inter-pixel light-shielding wall 407.

The second inter-pixel light-shielding wall 408 is disposed between the light-receiving pixels 3 corresponding to a position between the pixel blocks on which the color filters 5 having different colors are disposed. In other words, the second inter-pixel light-shielding wall 408 is disposed to surround the pixel block. A low refractive index material or an absorbent is used for the separation material 43 of the second inter-pixel light-shielding wall 408.

Components other than the above-described components are the same or substantially the same as the components of the solid-state imaging device 1 according to the 3-1st embodiment described above.

### Workings and Effects

In the solid-state imaging device 1 according to the 3-11th embodiment, it is possible to achieve workings and effects similar to the workings and effects achieved by the solid-state imaging device 1 according to the 3-6th embodiment.

### 33. 3-12th Embodiment

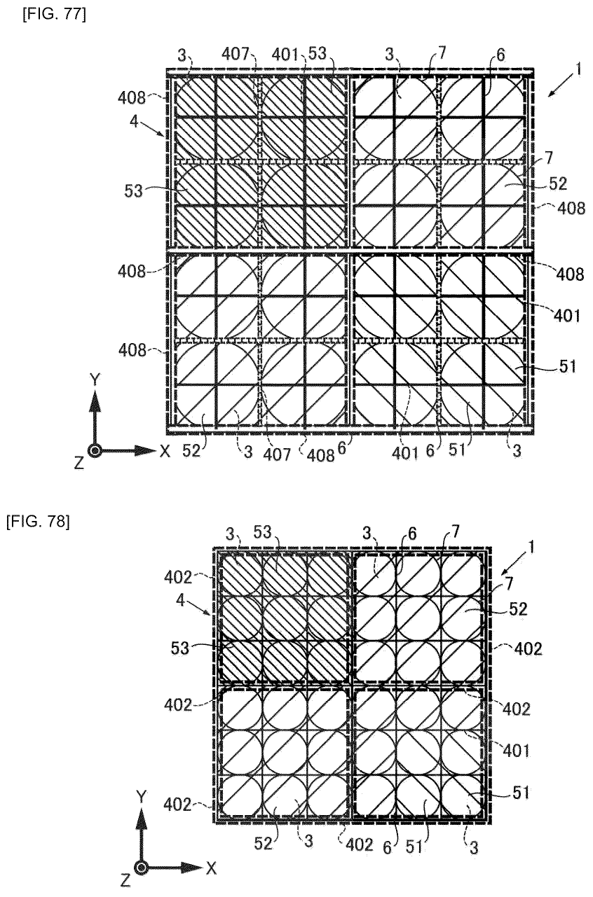

Description is given of the solid-state imaging device 1 according to the 3-12th embodiment of the present disclosure with reference to FIG. 77.

FIG. 77 illustrates an example of the arrangement configuration of the light-receiving pixels 3, the arrangement configuration of the color filters 5, and the layout configuration of the inter-pixel light-shielding walls 4 in the effective pixel region 10 in the solid-state imaging device 1.

As illustrated in FIG. 77, as with the solid-state imaging device 1 according to the 3-7th embodiment, the solid-state imaging device 1 includes the inter-pixel light-shielding walls 4. The inter-pixel light-shielding walls 4 include the first inter-pixel light-shielding wall 401, the first inter-pixel light-shielding wall 407, and the second inter-pixel light-shielding wall 408.

The first inter-pixel light-shielding wall 401 is disposed each between four light-receiving pixels 3 and other four light-receiving pixels 3 adjacent in the arrow-X direction and between four light-receiving pixels 3 and other four light-receiving pixels 3 adjacent in the arrow-Y direction. In other words, the first inter-pixel light-shielding wall 401 is disposed to surround four light-receiving pixels 3 on which one lens 7 is disposed. A high refractive index material or a low refractive index material is used for the separation material 43 of the first inter-pixel light-shielding wall 401.

The groove 41 of the first inter-pixel light-shielding wall 401 has the width Tw1.

The first inter-pixel light-shielding wall 407 is disposed between four light-receiving pixels 3 adjacent in the arrow-X direction and the arrow-Y direction in the pixel block. In other words, the first inter-pixel light-shielding wall 407 is disposed between four light-receiving pixels 3 on which one lens 7 is disposed. A high refractive index material is used for the separation material 43 of the first inter-pixel light-shielding wall 407.

The groove 41 of the first inter-pixel light-shielding wall 407 has the width Tw7. The width Tw7 is smaller than the width Tw1.

The second inter-pixel light-shielding wall 408 is disposed between the light-receiving pixels 3 corresponding to a position between the pixel blocks on which the color filters 5 having different colors are disposed. In other words, the second inter-pixel light-shielding wall 408 is disposed to surround the pixel block. A low refractive index material or an absorbent is used for the separation material 43 of the second inter-pixel light-shielding wall 408.

The groove 41 of the second inter-pixel light-shielding wall 408 has the width Tw8. The width Tw8 is larger than the width Tw1.

Components other than the above-described components are the same or substantially the same as the components of the solid-state imaging device 1 according to the 3-7th embodiment described above.

### Workings and Effects

In the solid-state imaging device 1 according to the 3-12th embodiment, it is possible to achieve workings and effects similar to the workings and effects achieved by the solid-state imaging device 1 according to the 3-7th embodiment.

### 34. 3-13th Embodiment

Description is given of the solid-state imaging device 1 according to the 3-13th embodiment of the present disclosure with reference to FIG. 78. The 3-13th embodiment and the 3-14th embodiment are examples in which the arrangement configuration of the light-receiving pixels 3, the arrangement configuration of the color filters 5, and the configuration of the lens 7 in the solid-state imaging device 1 according to the 3-1st embodiment are changed.

FIG. 78 illustrates an example of the arrangement configuration of the light-receiving pixels 3, the arrangement configuration of the color filters 5, the configuration of the lens 7, and the layout configuration of the inter-pixel light-shielding walls 4 in the effective pixel region 10 in the solid-state imaging device 1.

As illustrated in FIG. 78, in the solid-state imaging device 1, a pixel block is constructed that includes a total of nine light-receiving pixels 3 including three light-receiving pixels 3 arranged in the arrow-X direction and three light-receiving pixels 3 arranged in the arrow-Y direction. The color filters 5 are disposed on the light-receiving pixels 3 of this pixel block. The lenses 7 are disposed on the color filters 5. One lens 7 is disposed for each light-receiving pixel 3. That is, in one pixel block, a total of nine lenses 7 are disposed, three in the arrow-X direction and three in the arrow-Y direction. The lens 7 is formed in a circular shape in a plan view.

Furthermore, the pixel blocks are arranged in the arrow-X direction and the arrow-Y direction.

In the solid-state imaging device 1 configured in such a manner, as with the solid-state imaging device 1 according to the 3-1st embodiment, the inter-pixel light-shielding walls 4 include the first inter-pixel light-shielding wall 401 and the first inter-pixel light-shielding wall 402.

The first inter-pixel light-shielding wall 401 is disposed between the light-receiving pixels 3 adjacent in the arrow-X direction and the arrow-Y direction in the pixel block. The groove 41 of the first inter-pixel light-shielding wall 401 has the width Tw1.

The first inter-pixel light-shielding wall 402 is disposed between the light-receiving pixels 3 corresponding to a position between the pixel blocks on which the color filters 5 having different colors adjacent in the arrow-X direction and the arrow-Y direction are disposed. The groove 41 of the first inter-pixel light-shielding wall 402 has the width Tw2. The width Tw2 is larger than the width Tw1.

Components other than the above-described components are the same or substantially the same as the components of the solid-state imaging device 1 according to the 3-1st embodiment described above.

### Workings and Effects

In the solid-state imaging device 1 according to the 3-13th embodiment, it is possible to achieve workings and effects similar to the workings and effects achieved by the solid-state imaging device 1 according to the 3-1st embodiment.

### 35. 3-14th Embodiment

Description is given of the solid-state imaging device 1 according to the 3-14th embodiment of the present disclosure.

### [Configuration of Solid-State Imaging Device 1]

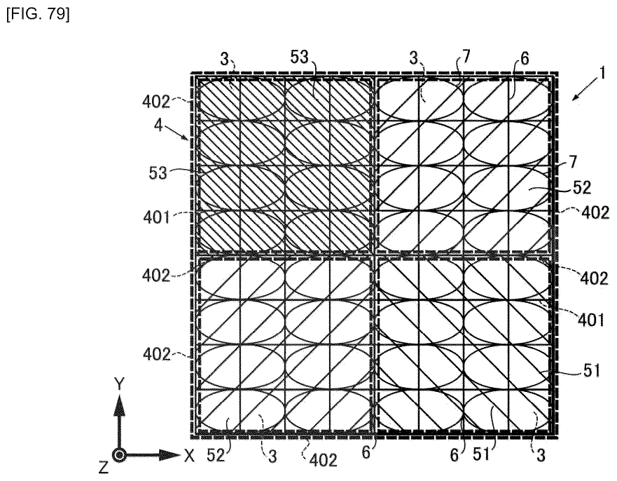

FIG. 79 illustrates an example of the arrangement configuration of the light-receiving pixels 3, the arrangement configuration of the color filters 5, the configuration of the lens 7, and the layout configuration of the inter-pixel light-shielding walls 4 in the effective pixel region 10 in the solid-state imaging device 1.

As illustrated in FIG. 79, in the solid-state imaging device 1, a pixel block is constructed that includes a total of sixteen light-receiving pixels 3 including four light-receiving pixels 3 arranged in the arrow-X direction and four light-receiving pixels 3 arranged in the arrow-Y direction. The color filter 5 is disposed over two light-receiving pixels 3 adjacent in the arrow-X direction in the pixel block. The lens 7 similar to the lens 7 of the solid-state imaging device 1 according to the 3-1st embodiment is disposed on the color filter 5. That is, the lens 7 having a different aspect ratio is disposed for two light-receiving pixels 3 adjacent in the arrow-X direction.

Furthermore, the pixel blocks are arranged in the arrow-X direction and the arrow-Y direction.

In the solid-state imaging device 1 configured in such a manner, as with the solid-state imaging device 1 according to the 3-1st embodiment, the inter-pixel light-shielding walls 4 include the first inter-pixel light-shielding wall 401 and the first inter-pixel light-shielding wall 402.

The first inter-pixel light-shielding wall 401 is disposed between the light-receiving pixels 3 adjacent in the arrow-X direction and the arrow-Y direction in the pixel block. The groove 41 of the first inter-pixel light-shielding wall 401 has the width Tw1.

The first inter-pixel light-shielding wall 402 is disposed between the light-receiving pixels 3 corresponding to a position between the pixel blocks on which the color filters having different colors adjacent in the arrow-X direction and the arrow-Y direction are disposed. The groove 41 of the first inter-pixel light-shielding wall 402 has the width Tw2. The width Tw2 is larger than the width Tw1.

Components other than the above-described components are the same or substantially the same as the components of the solid-state imaging device 1 according to the 3-1st embodiment described above.

### Workings and Effects

In the solid-state imaging device 1 according to the 3-14th embodiment, it is possible to achieve workings and effects similar to the workings and effects achieved by the solid-state imaging device 1 according to the 3-1st embodiment.

### 36. Application Example to Mobile Body

The technology according to the present disclosure (the present technology) is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, or a vessel, and a robot.

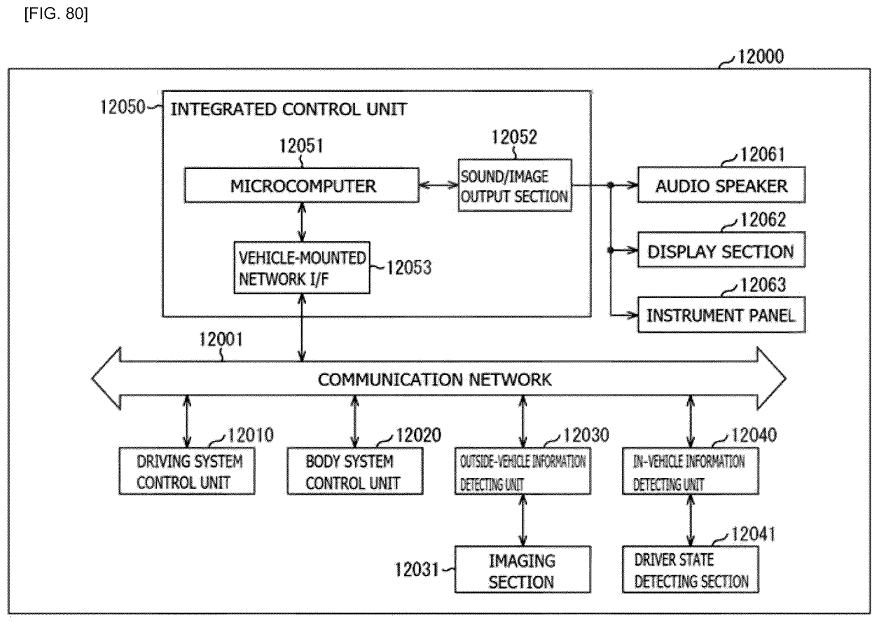

FIG. 80 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 80, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 80, an audio speaker 12061, a display section 12062, and an instrument panel 12063 are illustrated as the output device. The display section 12062 may, for example, include at least one of an on-board display and a head-up display.

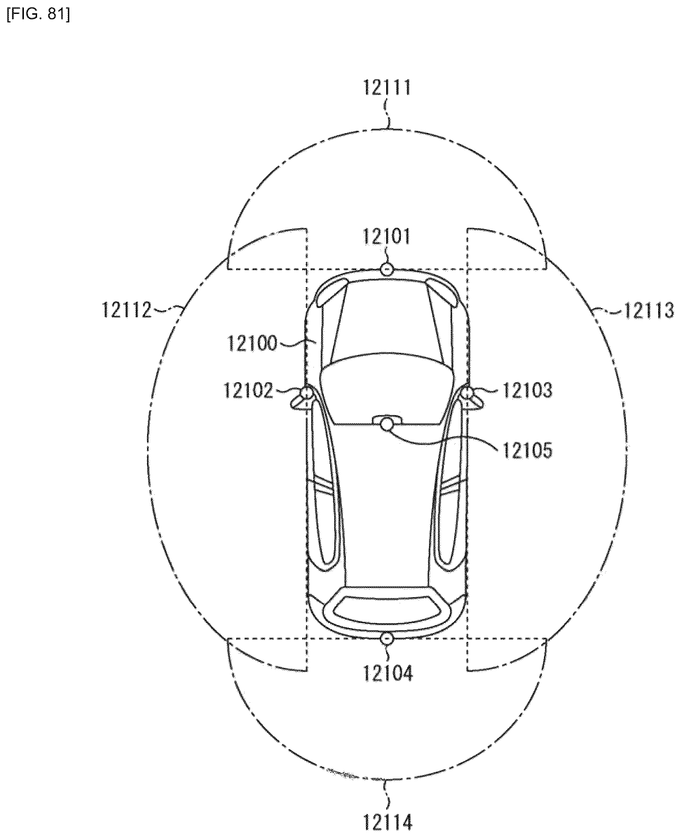

FIG. 81 is a diagram depicting an example of the installation position of the imaging section 12031.

In FIG. 81, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 81 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure may be applied has been described above. The technology according to the present disclosure is appliable to, for example, the imaging section 12031 among the configurations described above. Applying the technology according to the present disclosure to the imaging section 12031 makes it possible to implement the imaging section 12031 with a simpler configuration.

### 37. Other Embodiments

The present technology is not limited to the embodiments described above, and various modifications may be made without departing from the gist of the present technology.

For example, of the solid-state imaging devices according to the 1-1st embodiment to the 1-11th embodiment, the 2-1st embodiment to the 2-10th embodiment, and the 3-1st embodiment to the 3-14th embodiment described above, the solid-state imaging devices according to two or more embodiments may be combined.

Furthermore, the present technology is applicable to an imaging device including any of the solid-state imaging devices described above.

In the present disclosure, the solid-state imaging device includes light-receiving pixels, a first color filter, a second color filter, a first inter-waveguide light-shielding wall, and a second inter-waveguide light-shielding wall.

A plurality of light-receiving pixels are arranged in a first direction and a second direction intersecting with the first direction. The first color filter is disposed over a plurality of light-receiving pixels arranged in the first direction, and has a first color. The second color filter is disposed over a plurality of light-receiving pixels arranged in the first direction, and has a second color different from the first color.

Furthermore, the first inter-waveguide light-shielding wall is disposed between the first color filters adjacent in the first direction, and has a light-shielding property. The second inter-waveguide light-shielding wall is disposed between the first color filter and the second color filter adjacent in the first direction, has a light-shielding property, and has a length in the first direction that is longer than a length in the same direction of the first inter-waveguide light-shielding wall.

Accordingly, it is possible to effectively reduce or prevent incident light that enters a color mixture path between the first color filter and the second color filter having different colors by the second inter-waveguide light-shielding wall. This makes it possible to effectively suppress or prevent color mixture.

In addition, in the present disclosure, a solid-state imaging device includes light-receiving pixels, a first color filter, a second color filter, a fourth inter-waveguide light-shielding wall, a fifth inter-waveguide light-shielding wall, and at least one of a first inter-waveguide light-shielding wall or a second inter-waveguide light-shielding wall. A plurality of light-receiving pixels are arranged in the first direction and the second direction intersecting with the first direction. The first color filter is disposed over a plurality of light-receiving pixels arranged in the first direction, and has a first color. The second color filter is disposed over a plurality of light-receiving pixels arranged in the first direction, and has a second color different from the first color.

Furthermore, the fourth inter-waveguide light-shielding wall is disposed between the first color filters adjacent in the second direction, and has a light-shielding property. The fifth inter-waveguide light-shielding wall is disposed between the first color filter and the second color filter adjacent in the second direction, and has a light-shielding property.

The first inter-waveguide light-shielding wall is disposed between the first color filters adjacent in the first direction, has a light-shielding property, and has a length in the first direction that is longer than a length in the second direction of the fourth inter-waveguide light-shielding wall or the fifth inter-waveguide light-shielding wall. The second inter-waveguide light-shielding wall is disposed between the first color filter and the second color filter adjacent in the first direction, has a light-shielding property, and has a length in the first direction that is longer than the length in the second direction of the fourth inter-waveguide light-shielding wall or the fifth inter-waveguide light-shielding wall.

Accordingly, it is possible to effectively limit the light amount of incident light, which makes it possible to effectively reduce or prevent a sensitivity difference between the color filters 5 having different colors. This makes it possible to effectively suppress or prevent color mixture.

In addition, in the present disclosure, a solid-state imaging device includes light-receiving pixels, a first color filter, a second color filter, a lens, a sixth inter-waveguide light-shielding wall, and a seventh inter-waveguide light-shielding wall.

A plurality of light-receiving pixels is arranged in the first direction and the second direction intersecting with the first direction. The first color filter is disposed over a plurality of light-receiving pixels arranged in the first direction, and has a first color. The second color filter is disposed over a plurality of light-receiving pixels arranged in the first direction, and has a second color different from the first color. The lens is disposed on each of the first color filter and the second color filter, has a small aspect ratio in the second direction to the first direction, and protrudes and curves on side opposite to the light-receiving pixel.

Furthermore, the sixth inter-waveguide light-shielding wall is disposed each between the first color filters adjacent in the first direction and between the first color filter and the second color filter adjacent in the first direction, and has a light-shielding property. The seventh inter-waveguide light-shielding wall is disposed at least one of between the first color filters adjacent in the second direction or between the first color filter and the second color filter adjacent in the second direction, and has a light-shielding property higher than the light-shielding property of the sixth inter-waveguide light-shielding wall.

The seventh inter-waveguide light-shielding wall has the light-shielding property higher than that of the sixth inter-waveguide light-shielding wall, which makes it possible to effectively reduce or prevent leakage light. This makes it possible to effectively suppress or prevent color mixture.

Furthermore, in the present disclosure, a solid-state imaging device includes light-receiving pixels, a color filter, a first inter-pixel light-shielding wall, and a second inter-pixel light-shielding wall.

A plurality of light-receiving pixels is arranged in the first direction and the second direction intersecting with the first direction. The color filter is disposed on each of the light-receiving pixels.

Furthermore, the first inter-pixel light-shielding wall is disposed between the light-receiving pixels corresponding to between the color filters having the same color adjacent in the first direction or the second direction, and has a light-shielding property. The second inter-pixel light-shielding wall is disposed between the light-receiving pixels corresponding to between the color filters having different colors adjacent in the first direction or the second direction, and has a light-shielding property higher than the light-shielding property of the first inter-pixel light-shielding wall.

Accordingly, incident light that passes through the lenses and the color filters and enters the light-receiving pixels is physically limited by the second inter-pixel light-shielding wall. This makes it possible to effectively suppress or prevent color mixture.

### Configuration of Present Technology

The present technology has the following configurations. According to the present technology having the following configurations, it is possible to effectively suppress or prevent color mixture.
(1)
   A solid-state imaging device including:
   a plurality of light-receiving pixels arranged in a first direction and a second direction intersecting with the first direction;
   a first color filter that is disposed over a plurality of the light-receiving pixels arranged in the first direction, and has a first color;
   a second color filter that is disposed over a plurality of the light-receiving pixels arranged in the first direction, and has a second color different from the first color;
   a first inter-waveguide light-shielding wall that is disposed between the first color filters adjacent in the first direction, and has a light-shielding property; and
   a second inter-waveguide light-shielding wall that is disposed between the first color filter and the second color filter adjacent in the first direction, has a light-shielding property, and has a length in the first direction that is longer than a length in same direction of the first inter-waveguide light-shielding wall.
(2)
   The solid-state imaging device according to (1), in which another first color filter adjacent in the second direction to the first color filter, or another second color filter adjacent in the second direction to the first color filter is disposed to be displaced in the first direction by an arrangement interval of the light-receiving pixels.
(3)
   The solid-state imaging device according to (2), in which the length of the second inter-waveguide light-shielding wall becomes long with an increase in number of the second color filters adjacent in the first direction and the second direction to the first color filter disposed on the light-receiving pixel.
(4)
   The solid-state imaging device according to any one of (1) to (3), further including:
   a third color filter that is disposed over a plurality of the light-receiving pixels arranged in the first direction, and has a third color different from the first color and the second color; and
   a third inter-waveguide light-shielding wall that is disposed between the second color filter and the third color filter adjacent in the first direction, has a light-shielding property, and has a length in the first direction that is longer than a length in same direction of the first inter-waveguide light-shielding wall.
(5)
   The solid-state imaging device according to any one of (1) to (4), further including:
   a fourth inter-waveguide light-shielding wall that is disposed between the first color filters adjacent in the second direction, has a light-shielding property, and has a length in the second direction that is equal to the length in the first direction of the first inter-waveguide light-shielding wall; and
   a fifth inter-waveguide light-shielding wall that is disposed between the first color filter and the second color filter adjacent in the second direction, has a light-shielding property, and has a length in the second direction that is equal to the length in the first direction of the first inter-waveguide light-shielding wall.
(6)
   The solid-state imaging device according to any one of (1) to (4), further including:
   a fourth inter-waveguide light-shielding wall that is disposed between the first color filters adjacent in the second direction, has a light-shielding property, and has a length in the second direction that is equal to the length in the first direction of the first inter-waveguide light-shielding wall; and a fifth inter-waveguide light-shielding wall that is disposed between the first color filter and the second color filter adjacent in the second direction, has a light-shielding property, and has a length in the second direction that is longer than the length in the first direction of the first inter-waveguide light-shielding wall.
(7)
   The solid-state imaging device according to (4), in which the second inter-waveguide light-shielding wall or the third inter-waveguide light-shielding wall is formed to have a long length in the first direction on side of the light-receiving pixel in which, with respect to one output, another output is floated of the light-receiving pixels adjacent in the first direction with the second inter-waveguide light-shielding wall or the third inter-waveguide light-shielding wall interposed therebetween.
(8)
   The solid-state imaging device according to any one of (1) to (7), in which the length in the first direction of the second inter-waveguide light-shielding wall is adjusted in accordance with an increase in height.
(9)
   The solid-state imaging device according to (5), in which
   each of the first inter-waveguide light-shielding wall to the fifth inter-waveguide light-shielding wall includes
   a barrier metal film, and
   a light-shielding wall body that is formed including at least one selected from a high-melting-point metal film, a silicon oxide film, or a porous film of silica stacked on the barrier metal film, the silica having a refractive index lower than silicon oxide.
(10)
   A solid-state imaging device including:
   a plurality of light-receiving pixels arranged in a first direction and a second direction intersecting with the first direction;
   a first color filter that is disposed over a plurality of the light-receiving pixels arranged in the first direction, and has a first color;
   a second color filter that is disposed over a plurality of the light-receiving pixels arranged in the first direction, and has a second color different from the first color;
   a fourth inter-waveguide light-shielding wall that is disposed between the first color filters adjacent in the second direction, and has a light-shielding property;
   a fifth inter-waveguide light-shielding wall that is disposed between the first color filter and the second color filter adjacent in the second direction, and has a light-shielding property; and
   a first inter-waveguide light-shielding wall that is disposed between the first color filters adjacent in the first direction or between the second color filters adjacent in the first direction, has a light-shielding property, and has a length in the first direction that is longer than a length in the second direction of the fourth inter-waveguide light-shielding wall or the fifth inter-waveguide light-shielding wall.
(11)
   A solid-state imaging device including:
   a plurality of light-receiving pixels arranged in a first direction and a second direction intersecting with the first direction;
   a first color filter that is disposed over a plurality of the light-receiving pixels arranged in the first direction, and has a first color;
   a second color filter that is disposed over a plurality of the light-receiving pixels arranged in the first direction, and has a second color different from the first color;
   a lens that is disposed on each of the first color filter and the second color filter, has a small aspect ratio in the second direction to the first direction, and protrudes and curves on side opposite to the light-receiving pixel;
   a sixth inter-waveguide light-shielding wall that is disposed each between the first color filters adjacent in the first direction and between the first color filter and the second color filter adjacent in the first direction, and has a light-shielding property; and
   a seventh inter-waveguide light-shielding wall that is disposed at least one of between the first color filters adjacent in the second direction or between the first color filter and the second color filter adjacent in the second direction, and has a light-shielding property higher than the light-shielding property of the sixth inter-waveguide light-shielding wall.
(12)
   The solid-state imaging device according to (11), in which a length in the second direction of the seventh inter-waveguide light-shielding wall is longer than a length in the first direction of the sixth inter-waveguide light-shielding wall.
(13)
   The solid-state imaging device according to (11) or (12), in which a height from the light-receiving pixel of the seventh inter-waveguide light-shielding wall is higher than a height from the light-receiving pixel of the sixth inter-waveguide light-shielding wall.
(14)
   The solid-state imaging device according to any one of (11) to (13), in which
   a height from the light-receiving pixel of the seventh inter-waveguide light-shielding wall is higher than a height from the light-receiving pixel of the sixth inter-waveguide light-shielding wall, and
   a length in the second direction of a part higher than the sixth inter-waveguide light-shielding wall of the seventh inter-waveguide light-shielding wall is longer or shorter than a length in the second direction of a part lower than the sixth inter-waveguide light-shielding wall of the seventh inter-waveguide light-shielding wall.
(15)
   The solid-state imaging device according to any one of (11) to (14), in which a length in the second direction of the seventh inter-waveguide light-shielding wall is adjusted in accordance with a refractive index difference between the first color filter and the second color filter.
(16)
   The solid-state imaging device according to any one of (11) to (14), in which a length in the second direction of the seventh inter-pixel light-shielding wall is adjusted in accordance with an increase in height
(17)
   A solid-state imaging device including:
   a plurality of light-receiving pixels arranged in a first direction and a second direction intersecting with the first direction;
   a color filter that is disposed on each of the light-receiving pixels:
   a first inter-pixel light-shielding wall that is disposed between the light-receiving pixels corresponding to between the color filters having a same color adjacent in the first direction or the second direction, and has a light-shielding property; and
   a second inter-pixel light-shielding wall that is disposed between the light-receiving pixels corresponding to between the color filters having different colors adjacent in the first direction or the second direction, and has a light-shielding property higher than the light-shielding property of the first inter-pixel light-shielding wall.
(18)
   The solid-state imaging device according to (17), in which a length in the first direction or the second direction of the second inter-pixel light-shielding wall is longer than a length in the first direction or the second direction of the first inter-pixel light-shielding wall.
(19)
   The solid-state imaging device according to (17) or (18), in which
   each of the first inter-pixel light-shielding wall and the second inter-pixel light-shielding wall has a groove that is formed along the light-receiving pixels in a third direction intersecting with the first direction and the second direction, and
   a width of the groove of the second inter-pixel light-shielding wall is longer than a width of the groove of the first inter-pixel light-shielding wall.
(20)
   The solid-state imaging device according to (17), in which
   the first inter-pixel light-shielding wall is formed including a first separation material having a first refractive index or first light absorptance, and
   the second inter-pixel light-shielding wall is formed including a second separation material having a second refractive index higher than that of the first separation material or second light absorptance lower than that of the first separation material.
(21)
   The solid-state imaging device according to (20), in which
   each of the first inter-pixel light-shielding wall and the second inter-pixel light-shielding wall has a groove that is formed along the light-receiving pixels in a third direction intersecting with the first direction and the second direction,
   the first inter-pixel light-shielding wall is formed by embedding the first separation material in the groove, and
   the second inter-pixel light-shielding wall is formed by embedding the second separation material in the groove.
(22)
   The solid-state imaging device according to any one of (17) to (21), in which
   the color filters include
   a first color filter that is disposed over a plurality of the light-receiving pixels arranged in the first direction, and has a first color.
   a second color filter that is disposed over a plurality of the light-receiving pixels arranged in the first direction, and has a second color different from the first color, and
   a third color filter that is disposed over a plurality of the light-receiving pixels arranged in the first direction, and has a third color different from the first color and the second color.
(23)
   The solid-state imaging device according to any one of (17) to (22), further including a lens that is disposed on each of the first color filter, the second color filter, and the third filter, has a small aspect ratio in the second direction to the first direction, and protrudes and curves on side opposite to the light-receiving pixel.
(24)
   An imaging device provided with a solid-state imaging device, the solid-state imaging device including:
   a plurality of light-receiving pixels arranged in a first direction and a second direction intersecting with the first direction;
   a first color filter that is disposed over a plurality of the light-receiving pixels arranged in the first direction, and has a first color;
   a second color filter that is disposed over a plurality of the light-receiving pixels arranged in the first direction, and has a second color different from the first color;
   a first inter-waveguide light-shielding wall that is disposed between the first color filters adjacent in the first direction, and has a light-shielding property; and
   a second inter-waveguide light-shielding wall that is disposed between the first color filter and the second color filter adjacent in the first direction, has a light-shielding property, and has a length in the first direction that is longer than a length in same direction of the first inter-waveguide light-shielding wall.
(25)
   An imaging device provided with a solid-state imaging device, the solid-state imaging device including:
   a plurality of light-receiving pixels arranged in a first direction and a second direction intersecting with the first direction;
   a first color filter that is disposed over a plurality of the light-receiving pixels arranged in the first direction, and has a first color:
   a second color filter that is disposed over a plurality of the light-receiving pixels arranged in the first direction, and has a second color different from the first color:
   a fourth inter-waveguide light-shielding wall that is disposed between the first color filters adjacent in the second direction, and has a light-shielding property;
   a fifth inter-waveguide light-shielding wall that is disposed between the first color filter and the second color filter adjacent in the second direction, and has a light-shielding property; and
   at least one of a first inter-waveguide light-shielding wall that is disposed between the first color filters adjacent in the first direction and has a length in the first direction that is longer than a length in the second direction of the fourth inter-waveguide light-shielding wall or the fifth inter-waveguide light-shielding wall, or a second inter-waveguide light-shielding wall that is disposed between the first color filter and the second color filter adjacent in the first direction, has a light-shielding property, and has a length in the first direction that is longer than the length in the second direction of the fourth inter-waveguide light-shielding wall or the fifth inter-waveguide light-shielding wall.
(26)
   An imaging device provided with a solid-state imaging device, the solid-state imaging device including:
   a plurality of light-receiving pixels arranged in a first direction and a second direction intersecting with the first direction;
   a first color filter that is disposed over a plurality of the light-receiving pixels arranged in the first direction, and has a first color;
   a second color filter that is disposed over a plurality of the light-receiving pixels arranged in the first direction, and has a second color different from the first color:
   a lens that is disposed on each of the first color filter and the second color filter, has a small aspect ratio in the second direction to the first direction, and protrudes and curves on side opposite to the light-receiving pixel;
   a sixth inter-waveguide light-shielding wall that is disposed each between the first color filters adjacent in the first direction and between the first color filter and the second color filter adjacent in the first direction, and has a light-shielding property; and
   a seventh inter-waveguide light-shielding wall that is disposed at least one of between the first color filters adjacent in the second direction or between the first color filter and the second color filter adjacent in the second direction, and has a light-shielding property higher than the light-shielding property of the sixth inter-waveguide light-shielding wall.
(27)
   An imaging device provided with a solid-state imaging device, the solid-state imaging device including:
   a plurality of light-receiving pixels arranged in a first direction and a second direction intersecting with the first direction;
   a color filter that is disposed on each of the light-receiving pixels;
   a first inter-pixel light-shielding wall that is disposed between the light-receiving pixels corresponding to between the color filters having a same color adjacent in the first direction or the second direction, and has a light-shielding property; and
   a second inter-pixel light-shielding wall that is disposed between the light-receiving pixels corresponding to between the color filters having different colors adjacent in the first direction or the second direction, and has a light-shielding property higher than the light-shielding property of the first inter-pixel light-shielding wall.

The present application claims the benefit of Japanese Priority Patent Application JP 2021-207979 filed with the Japan Patent Office on Dec. 22, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A solid-state imaging device comprising:
a plurality of light-receiving pixels arranged in a first direction and a second direction intersecting with the first direction;
a first color filter that is disposed over a plurality of the light-receiving pixels arranged in the first direction, and has a first color;
a second color filter that is disposed over a plurality of the light-receiving pixels arranged in the first direction, and has a second color different from the first color;
a first inter-waveguide light-shielding wall that is disposed between the first color filters adjacent in the first direction, and has a light-shielding property; and
a second inter-waveguide light-shielding wall that is disposed between the first color filter and the second color filter adjacent in the first direction, has a light-shielding property, and has a length in the first direction that is longer than a length in same direction of the first inter-waveguide light-shielding wall.

2. The solid-state imaging device according to claim 1, wherein another first color filter adjacent in the second direction to the first color filter, or another second color filter adjacent in the second direction to the first color filter is disposed to be displaced in the first direction by an arrangement interval of the light-receiving pixels.

3. The solid-state imaging device according to claim 2, wherein the length of the second inter-waveguide light-shielding wall becomes long with an increase in number of the second color filters adjacent in the first direction and the second direction to the first color filter disposed on the light-receiving pixel.

4. The solid-state imaging device according to claim 1, further comprising:
a third color filter that is disposed over a plurality of the light-receiving pixels arranged in the first direction, and has a third color different from the first color and the second color; and
a third inter-waveguide light-shielding wall that is disposed between the second color filter and the third color filter adjacent in the first direction, has a light-shielding property, and has a length in the first direction that is longer than a length in same direction of the first inter-waveguide light-shielding wall.

5. The solid-state imaging device according to claim 1, further comprising:
a fourth inter-waveguide light-shielding wall that is disposed between the first color filters adjacent in the second direction, has a light-shielding property, and has a length in the second direction that is equal to the length in the first direction of the first inter-waveguide light-shielding wall; and
a fifth inter-waveguide light-shielding wall that is disposed between the first color filter and the second color filter adjacent in the second direction, has a light-shielding property, and has a length in the second direction that is equal to the length in the first direction of the first inter-waveguide light-shielding wall.

6. The solid-state imaging device according to claim 1, further comprising:
a fourth inter-waveguide light-shielding wall that is disposed between the first color filters adjacent in the second direction, has a light-shielding property, and has a length in the second direction that is equal to the length in the first direction of the first inter-waveguide light-shielding wall; and
a fifth inter-waveguide light-shielding wall that is disposed between the first color filter and the second color filter adjacent in the second direction, has a light-shielding property, and has a length in the second direction that is longer than the length in the first direction of the first inter-waveguide light-shielding wall.

7. The solid-state imaging device according to claim 4, wherein the second inter-waveguide light-shielding wall or the third inter-waveguide light-shielding wall is formed to have a long length in the first direction on side of the light-receiving pixel in which, with respect to one output, another output is floated of the light-receiving pixels adjacent in the first direction with the second inter-waveguide light-shielding wall or the third inter-waveguide light-shielding wall interposed therebetween.

8. The solid-state imaging device according to claim 1, wherein the length in the first direction of the second inter-waveguide light-shielding wall is adjusted in accordance with an increase in height.

9. The solid-state imaging device according to claim 5, wherein
each of the first inter-waveguide light-shielding wall to the fifth inter-waveguide light-shielding wall includes a barrier metal film, and
a light-shielding wall body that is formed including at least one selected from a high-melting-point metal film, a silicon oxide film, or a porous film of silica stacked on the barrier metal film, the silica having a refractive index lower than silicon oxide.

10. A solid-state imaging device comprising:
a plurality of light-receiving pixels arranged in a first direction and a second direction intersecting with the first direction;
a first color filter that is disposed over a plurality of the light-receiving pixels arranged in the first direction, and has a first color;
a second color filter that is disposed over a plurality of the light-receiving pixels arranged in the first direction, and has a second color different from the first color;
a fourth inter-waveguide light-shielding wall that is disposed between the first color filters adjacent in the second direction, and has a light-shielding property;
a fifth inter-waveguide light-shielding wall that is disposed between the first color filter and the second color filter adjacent in the second direction, and has a light-shielding property; and
a first inter-waveguide light-shielding wall that is disposed between the first color filters adjacent in the first direction or between the second color filters adjacent in the first direction, has a light-shielding property, and has a length in the first direction that is longer than a length in the second direction of the fourth inter-waveguide light-shielding wall or the fifth inter-waveguide light-shielding wall.

11. 1| A solid-state imaging device comprising:
a plurality of light-receiving pixels arranged in a first direction and a second direction intersecting with the first direction;
a first color filter that is disposed over a plurality of the light-receiving pixels arranged in the first direction, and has a first color;
a second color filter that is disposed over a plurality of the light-receiving pixels arranged in the first direction, and has a second color different from the first color;
a lens that is disposed on each of the first color filter and the second color filter, has a small aspect ratio in the second direction to the first direction, and protrudes and curves on side opposite to the light-receiving pixel;
a sixth inter-waveguide light-shielding wall that is disposed each between the first color filters adjacent in the first direction and between the first color filter and the second color filter adjacent in the first direction, and has a light-shielding property; and
a seventh inter-waveguide light-shielding wall that is disposed at least one of between the first color filters adjacent in the second direction or between the first color filter and the second color filter adjacent in the second direction, and has a light-shielding property higher than the light-shielding property of the sixth inter-waveguide light-shielding wall.

12. The solid-state imaging device according to claim 11, wherein a length in the second direction of the seventh inter-waveguide light-shielding wall is longer than a length in the first direction of the sixth inter-waveguide light-shielding wall.

13. The solid-state imaging device according to claim 11, wherein a height from the light-receiving pixel of the seventh inter-waveguide light-shielding wall is higher than a height from the light-receiving pixel of the sixth inter-waveguide light-shielding wall.

14. The solid-state imaging device according to claim 11, wherein
a height from the light-receiving pixel of the seventh inter-waveguide light-shielding wall is higher than a height from the light-receiving pixel of the sixth inter-waveguide light-shielding wall, and
a length in the second direction of a part higher than the sixth inter-waveguide light-shielding wall of the seventh inter-waveguide light-shielding wall is longer or shorter than a length in the second direction of a part lower than the sixth inter-waveguide light-shielding wall of the seventh inter-waveguide light-shielding wall.

15. The solid-state imaging device according to claim 11, wherein a length in the second direction of the seventh inter-waveguide light-shielding wall is adjusted in accordance with a refractive index difference between the first color filter and the second color filter.

16. The solid-state imaging device according to claim 11, wherein a length in the second direction of the seventh inter-pixel light-shielding wall is adjusted in accordance with an increase in height.

17. A solid-state imaging device comprising:
a plurality of light-receiving pixels arranged in a first direction and a second direction intersecting with the first direction;
a color filter that is disposed on each of the light-receiving pixels;
a first inter-pixel light-shielding wall that is disposed between the light-receiving pixels corresponding to between the color filters having a same color adjacent in the first direction or the second direction, and has a light-shielding property; and
a second inter-pixel light-shielding wall that is disposed between the light-receiving pixels corresponding to between the color filters having different colors adjacent in the first direction or the second direction, and has a light-shielding property higher than the light-shielding property of the first inter-pixel light-shielding wall.

18. The solid-state imaging device according to claim 17, wherein a length in the first direction or the second direction of the second inter-pixel light-shielding wall is longer than a length in the first direction or the second direction of the first inter-pixel light-shielding wall.

19. The solid-state imaging device according to claim 17, wherein
each of the first inter-pixel light-shielding wall and the second inter-pixel light-shielding wall has a groove that is formed along the light-receiving pixels in a third direction intersecting with the first direction and the second direction, and
a width of the groove of the second inter-pixel light-shielding wall is longer than a width of the groove of the first inter-pixel light-shielding wall.

20. The solid-state imaging device according to claim 17, wherein
the first inter-pixel light-shielding wall is formed including a first separation material having a first refractive index or first light absorptance, and
the second inter-pixel light-shielding wall is formed including a second separation material having a second refractive index higher than that of the first separation material or second light absorptance lower than that of the first separation material.

21. The solid-state imaging device according to claim 20, wherein
each of the first inter-pixel light-shielding wall and the second inter-pixel light-shielding wall has a groove that is formed along the light-receiving pixels in a third direction intersecting with the first direction and the second direction,
the first inter-pixel light-shielding wall is formed by embedding the first separation material in the groove, and
the second inter-pixel light-shielding wall is formed by embedding the second separation material in the groove.
